(19) United States
(12) Patent Application Publication
(10) Pub. No.: US 2026/0371655 A1
(43) Pub. Date: Nov. 19, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Ryota HODO, Atsugi (JP); Toshiya ENDO, Atsugi (JP); Akihiro KIKUCHI, Isehara (JP); Yuki IMOTO, Sagamihara (JP)

(21) Appl. No.: 19/156,566

(22) PCT Filed: Mar. 4, 2024
(86) PCT No.: PCT/IB2024/052047

§ 371 Date: Aug. 14, 2025

(30) Foreign Application Priority Data
Mar. 10, 2023 (JP) 2023-037381
Jun. 22, 2023 (JP) 2023-102367

(51) Int. Cl. H10D 30/67; H10D 30/01; H10K 59/121

(52) U.S. Cl. CPC H10D 30/6755; H10D 30/031; H10D 30/6757; H10K 59/1213

(57) ABSTRACT

A semiconductor device that can be scaled down or highly integrated is provided. The semiconductor device includes a transistor and first to third insulators. The transistor includes a first conductor over the second insulator, a second conductor over the third insulator, an oxide semiconductor, a fourth insulator, and a third conductor. An opening portion reaching the first conductor is provided in the third insulator and the second conductor. The oxide semiconductor is in contact with the top surface of the first conductor and the top surface and the side surface of the second conductor. The fourth insulator is placed over the oxide semiconductor to be at least partly positioned in the opening portion. The third conductor is placed over the fourth insulator to be at least partly positioned in the opening portion. The second insulator has a function of capturing or fixing hydrogen. The second conductor includes a first layer and a second layer over the first layer. The first layer has higher conductivity than the second layer. The second layer includes a metal oxide.

### TECHNICAL FIELD

One embodiment of the present invention relates to a semiconductor device, a memory device, and an electronic device. Another embodiment of the present invention relates to a method for fabricating the semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (e.g., a liquid crystal display device and a light-emitting display device), a projection device, a lighting device, an electro-optical device, a power storage device, a memory device, a semiconductor circuit, an imaging device, an electronic device, and the like include a semiconductor device.

### BACKGROUND ART

In recent years, the development of semiconductor devices has progressed, and LSIs (Large Scale Integrations), CPUs (Central Processing Units), memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor, and an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. For another example, Patent Document 2 discloses a memory device that can retain stored contents for a long time by utilizing a feature of a low leakage current of the transistor using an oxide semiconductor.

In recent years, demand for an integrated circuit with a higher density has risen with reductions in size and weight of electronic devices. Furthermore, the productivity of a semiconductor device including an integrated circuit is required to be improved. For example, Patent Document 3 and Non-Patent Document 1 disclose a technique to achieve an integrated circuit with a higher density by making a plurality of memory cells overlap with each other by stacking a first transistor using an oxide semiconductor film and a second transistor using an oxide semiconductor film. For another example, Patent Document 4 discloses a technique to achieve an integrated circuit with a higher density by placing a channel of a transistor using an oxide semiconductor film in the vertical direction.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota et al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be scaled down or highly integrated. Another object of one embodiment of the present invention is to provide a semiconductor device with a high on-state current. Another object of one embodiment of the present invention is to provide a semiconductor device that operates at high speed. Another object of one embodiment of the present invention is to provide a highly reliable semiconductor device. Another object of one embodiment of the present invention is to provide a semiconductor device with excellent electrical characteristics. Another object of one embodiment of the present invention is to provide a semiconductor device with a small variation in electrical characteristics of transistors. Another object of one embodiment of the present invention is to provide a semiconductor device with low power consumption. Another object of one embodiment of the present invention is to provide a novel semiconductor device. Another object of one embodiment of the present invention is to provide a method for fabricating a semiconductor device with high productivity. Another object of one embodiment of the present invention is to provide a method for fabricating a novel semiconductor device.

Another object of one embodiment of the present invention is to provide a memory device that can be scaled down or highly integrated. Another object of one embodiment of the present invention is to provide a memory device with a high memory capacity. Another object of one embodiment of the present invention is to provide a memory device that operates at high speed. Another object of one embodiment of the present invention is to provide a memory device with low power consumption. Another object of one embodiment of the present invention is to provide a novel memory device.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a transistor and first to third insulators. The second insulator is placed over the first insulator. The third insulator is placed over the second insulator. The transistor includes a first conductor over the second insulator, a second conductor over the third insulator, an oxide semiconductor, a fourth insulator, and a third conductor. An opening portion reaching the first conductor is provided in the third insulator and the second conductor. The oxide semiconductor is in contact with a top surface of the first conductor and a top surface and a side surface of the second conductor. The fourth insulator is placed over the oxide semiconductor to be at least partly positioned in the opening portion. The third conductor is placed over the fourth insulator to be at least partly positioned in the opening portion. The second insulator has a function of capturing or fixing hydrogen. The second conductor includes a first layer and a second layer over the first layer. The first layer has higher conductivity than the second layer. The second layer includes a metal oxide.

In the above, the first layer preferably contains ruthenium or tungsten.

In the above, the second layer preferably contains indium.

In the above, it is preferable that the second layer contain tin and silicon, and that the second layer have an amorphous structure.

In the above, the first insulator and the third insulator each preferably have a barrier property against hydrogen.

In the above, the second insulator preferably contains hafnium, silicon, and oxygen.

In the above, the first insulator and the third insulator each preferably contain silicon and nitrogen.

In the above, it is preferable that the first conductor include a third layer and a fourth layer over the third layer, that the third layer have higher conductivity than the fourth layer, and that the fourth layer include a metal oxide.

In the above, the third layer preferably contains tungsten.

In the above, the fourth layer preferably contains indium.

In the above, it is preferable that the fourth layer contain tin and silicon, and that the fourth layer have an amorphous structure.

Another embodiment of the present invention is a semiconductor device including a transistor, a first insulator, and a second insulator. The transistor includes a first conductor, a second conductor over the first conductor and the first insulator, an oxide semiconductor, a third insulator, and a third conductor. An opening portion reaching the first conductor is provided in the third insulator and the second conductor. The oxide semiconductor is in contact with a top surface of the first conductor and a top surface of the second conductor. The third insulator is placed over the oxide semiconductor to be at least partly positioned in the opening portion. The third conductor is placed over the third insulator to be at least partly positioned in the opening portion. The second insulator is placed between the oxide semiconductor and each of the first insulator and the second conductor in the opening portion. The second conductor includes a first layer and a second layer over the first layer. The first layer has higher conductivity than the second layer. The second layer includes a metal oxide. One side surface of the second insulator is in contact with at least a side surface of the first layer.

In the above, the first layer preferably contains ruthenium or tungsten.

In the above, the second layer preferably contains indium.

In the above, it is preferable that the second layer contain tin and silicon, and that the second layer have an amorphous structure.

In the above, a level of an upper end portion of the second insulator can be lower than a level of a top surface of the second layer.

In the above, it is preferable that the one side surface of the second insulator be in contact with the first insulator, and that the other side surface of the second insulator be in contact with the oxide semiconductor.

In the above, the second insulator preferably contains silicon and nitrogen.

### Effect of the Invention

One embodiment of the present invention can provide a semiconductor device that can be scaled down or highly integrated. Another embodiment of the present invention can provide a semiconductor device with a high on-state current. Another embodiment of the present invention can provide a semiconductor device that operates at high speed. Another embodiment of the present invention can provide a highly reliable semiconductor device. Another embodiment of the present invention can provide a semiconductor device with excellent electrical characteristics. Another embodiment of the present invention can provide a semiconductor device with a small variation in electrical characteristics of transistors. Another embodiment of the present invention can provide a semiconductor device with low power consumption. Another embodiment of the present invention can provide a novel semiconductor device. Another embodiment of the present invention can provide a method for fabricating a semiconductor device with high productivity. Another embodiment of the present invention can provide a method for fabricating a novel semiconductor device.

Another embodiment of the present invention can provide a memory device that can be scaled down or highly integrated. Another embodiment of the present invention can provide a memory device with a high memory capacity. Another embodiment of the present invention can provide a memory device that operates at high speed. Another embodiment of the present invention can provide a memory device with low power consumption. Another embodiment of the present invention can provide a novel memory device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a semiconductor device. FIG. 1B to FIG. 1D are cross-sectional views illustrating the example of the semiconductor device.

FIG. 2A and FIG. 2B are cross-sectional views illustrating an example of a semiconductor device.

FIG. 3A and FIG. 3B are cross-sectional views illustrating examples of a semiconductor device.

FIG. 4A to FIG. 4E are cross-sectional views illustrating an example of a method for fabricating a semiconductor device.

FIG. 5A to FIG. 5D are cross-sectional views illustrating an example of a method for fabricating a semiconductor device.

FIG. 6A is a cross-sectional view illustrating an example of a method for fabricating a semiconductor device. FIG. 6B is a cross-sectional view illustrating an example of the semiconductor device.

FIG. 7A to FIG. 7D are cross-sectional views illustrating an example of a method for fabricating a semiconductor device.

FIG. 8A is a plan view illustrating an example of a semiconductor device. FIG. 8B to FIG. 8D are cross-sectional views illustrating the example of the semiconductor device.

FIG. 9A is a plan view illustrating an example of a semiconductor device. FIG. 9B to FIG. 9D are cross-sectional views illustrating the example of the semiconductor device.

FIG. 10A and FIG. 10B are cross-sectional views illustrating examples of a semiconductor device.

FIG. 11A is a plan view illustrating an example of a semiconductor device. FIG. 11B to FIG. 11D are cross-sectional views illustrating the example of the semiconductor device.

FIG. 12A and FIG. 12B are cross-sectional views illustrating examples of a semiconductor device.

FIG. 13A is a plan view illustrating an example of a semiconductor device. FIG. 13B to FIG. 13D are cross-sectional views illustrating the example of the semiconductor device.

FIG. 14A and FIG. 14B are cross-sectional views illustrating an example of a method for fabricating a semiconductor device.

FIG. 15A is a plan view illustrating an example of a semiconductor device. FIG. 15B to FIG. 15D are cross-sectional views illustrating the example of the semiconductor device.

FIG. 16A is a plan view illustrating an example of a semiconductor device. FIG. 16B is a cross-sectional view illustrating the example of the semiconductor device.

FIG. 17 is a block diagram illustrating a structure example of a semiconductor device.

FIG. 18A to FIG. 18H are diagrams illustrating circuit structure examples of memory cells.

FIG. 19A and FIG. 19B are perspective views illustrating structure examples of a semiconductor device.

FIG. 20 is a block diagram illustrating a CPU.

FIG. 21A and FIG. 21B are perspective views of a semiconductor device.

FIG. 22A and FIG. 22B are perspective views of semiconductor devices.

FIG. 23A and FIG. 23B are diagrams each showing a hierarchy of a variety of memory devices.

FIG. 24A and FIG. 24B are diagrams illustrating examples of electronic devices, and FIG. 24C to FIG. 24E are diagrams illustrating an example of a large computer.

FIG. 25 is a diagram illustrating an example of space equipment.

FIG. 26 is a diagram illustrating an example of a storage system that can be used in a data center.

FIG. 27A and FIG. 27B are a structure example of a display device.

FIG. 28 is a structure example of a display device.

FIG. 29 is a structure example of a display device.

FIG. 30A to FIG. 30C are a structure example of a display device.

FIG. 31A and FIG. 31B are structure examples of display devices.

FIG. 32A to FIG. 32D are structure examples of electronic devices.

FIG. 33A to FIG. 33F are structure examples of electronic devices.

FIG. 34A to FIG. 34G are structure examples of electronic devices.

FIG. 35 is a diagram showing measurement results of contact resistance in this example.

FIG. 36A and FIG. 36B are cross-sectional SEM images of samples in this example.

FIG. 37 is a cross-sectional STEM image and FFT images in this example.

FIG. 38 is a cross-sectional STEM image and FFT images in this example.

FIG. 39 is a cross-sectional STEM image of a sample in this example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Thus, the disclosed invention is not necessarily limited to the position, size, range, or the like disclosed in the drawings.

Furthermore, especially in a plan view, a perspective view, or the like, the description of some components is omitted for easy understanding of the invention in some cases. The description of some hidden lines is also omitted in some cases.

In this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”. The term “conductor” can be interchanged with the term “conductive layer” or the term “conductive film” depending on the case or the circumstances. The term “insulator” can be interchanged with the term “insulating layer” or the term “insulating film” depending on the case or the circumstances. The term “oxide semiconductor” can be interchanged with the term “oxide semiconductor layer” or the term “oxide semiconductor film” depending on the case or the circumstances.

In this specification and the like, the expression “parallel” indicates a state where two straight lines are placed at an angle greater than or equal to −10° and less than or equal to 10°. Accordingly, the case where the angle is greater than or equal to −5° and less than or equal to 5° is also included. Furthermore, the expression “substantially parallel” indicates a state where two straight lines are placed at an angle greater than or equal to −30° and less than or equal to 30°. Moreover, the expression “perpendicular” indicates a state where two straight lines are placed at an angle greater than or equal to 80° and less than or equal to 100°. Accordingly, the case where the angle is greater than or equal to 85° and less than or equal to 95° is also included. Furthermore, the expression “substantially perpendicular” indicates a state where two straight lines are placed at an angle greater than or equal to 60° and less than or equal to 120°.

The term “opening” includes a groove, a slit, and a depressed portion, for example. A region where an opening is formed is referred to as an opening portion in some cases.

In the drawings used in this specification and the like, a sidewall of an insulator in an opening portion in the insulator is illustrated as being perpendicular or substantially perpendicular to a substrate surface or a formation surface, but the sidewall may have a tapered shape.

In this specification and the like, a tapered shape refers to a shape such that at least part of a side surface of a component is inclined to a substrate surface or a formation surface. For example, a tapered shape structure includes a region where the angle formed by the inclined side surface and the substrate surface or the formation surface (hereinafter, such an angle is also referred to as a taper angle in some cases) is less than 90°. Note that the side surface of the component and the substrate surface are not necessarily completely flat and may be substantially flat with a slight curvature or substantially flat with slight unevenness. In this specification and the like, an inverse tapered shape refers to a shape in which a side portion or an upper portion extends beyond a bottom portion in the direction parallel to a substrate.

In this specification and the like, the expression “level” indicates a structure in which levels from a reference surface (e.g., a flat surface such as a substrate surface) are the same in a cross-sectional view. For example, in a manufacturing process of a memory device, planarization treatment (typically, chemical mechanical polishing (CMP) treatment) is performed, whereby the surface of a single layer or the surfaces of a plurality of layers is/are exposed in some cases. In that case, the surfaces on which the CMP treatment is performed are at the same level from a reference surface. Note that a plurality of layers may be at different levels depending on a treatment apparatus, a treatment method, or a material of the treated surfaces, used for the CMP treatment. This case is also regarded as being “level” in this specification and the like. For example, the expression “level” includes the case where two layers (here, a first layer and a second layer) having different levels with respect to a reference surface are included and the difference between the top-surface level of the first layer and the top-surface level of the second layer is less than or equal to 20 nm.

In this specification and the like, the expression “side end portions are aligned” means that outlines of stacked layers at least partly overlap with each other in a plan view. For example, the case of processing an upper layer and a lower layer with the use of the same mask pattern or mask patterns that are partly the same is included. However, in some cases, the outlines do not exactly overlap with each other and the outline of the upper layer is positioned inward from the outline of the lower layer or the outline of the upper layer is positioned outward from the outline of the lower layer; such a case is also represented by the expression “side end portions are aligned”.

In general, it is difficult to clearly differentiate “completely aligned” from “substantially aligned”. Thus, in this specification and the like, the expression “aligned” includes both “completely aligned” and “substantially aligned”.

In this specification and the like, the expression “a first thickness and a second thickness are equal to each other” means that a value obtained by dividing the absolute value of the difference between the first thickness and the second thickness by the first thickness is less than or equal to 0.1. Alternatively, the expression means that a value obtained by dividing the absolute value of the difference between the first thickness and the second thickness by the second thickness is less than or equal to 0.1.

In this specification and the like, the expression “a distance A and a distance B are equal to each other” means that a value obtained by dividing the absolute value of the difference between the distance A and the distance B by the distance A is less than or equal to 0.1. Alternatively, the expression means that a value obtained by dividing the absolute value of the difference between the distance A and the distance B by the distance B is less than or equal to 0.1.

### Embodiment 1

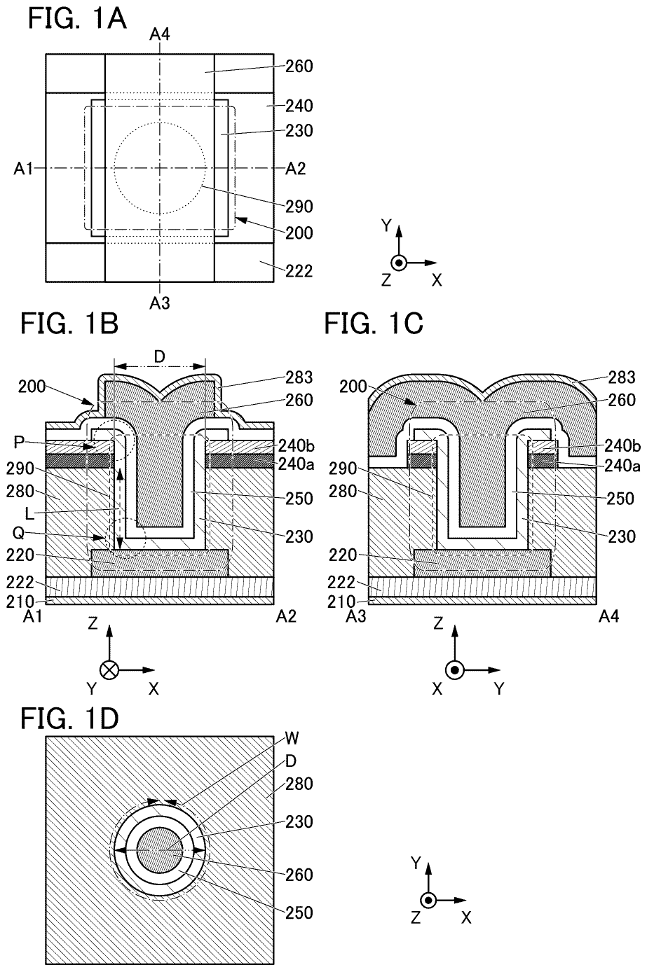

In this embodiment, examples of a semiconductor device of one embodiment of the present invention will be described with reference to FIG. 1A to FIG. 16B.

### <Structure Example of Semiconductor Device>

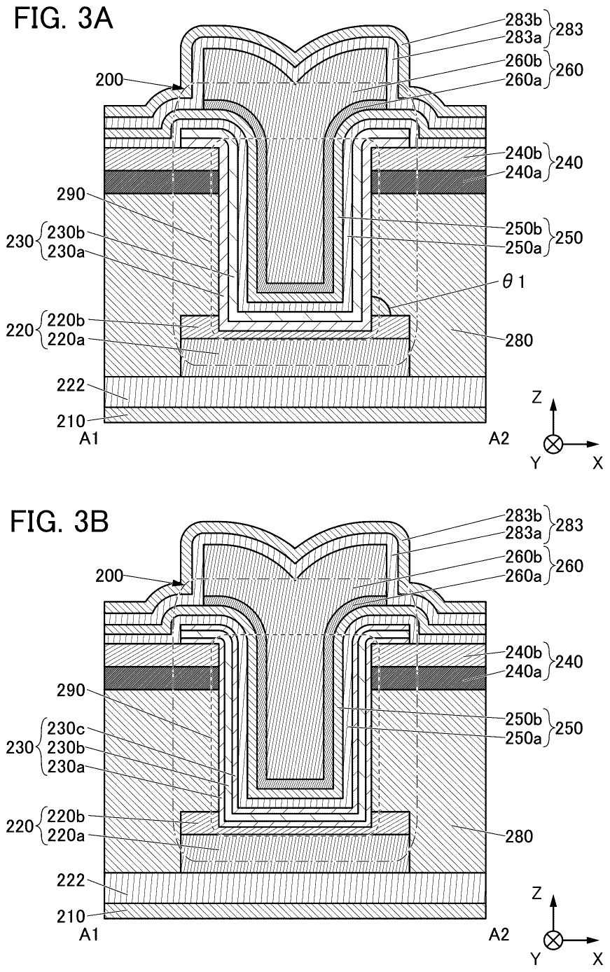

A structure example of the semiconductor device of one embodiment of the present invention is described with reference to FIG. 1A to FIG. 1D. FIG. 1A to FIG. 1D are a plan view and cross-sectional views of the semiconductor device including a transistor 200. FIG. 1A is the plan view of the semiconductor device. FIG. 1B to FIG. 1D are the cross-sectional views of the semiconductor device. Here, FIG. 1B is a cross-sectional view of a portion indicated by the dashed-dotted line A1-A2 in FIG. 1A. FIG. 1C is a cross-sectional view of a portion indicated by the dashed-dotted line A3-A4 in FIG. 1A. Note that for clarity of the drawing, some components are not illustrated in the plan view of FIG. 1A. FIG. 3A and FIG. 3B are enlarged views corresponding to FIG. 1B.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The semiconductor device illustrated in FIG. 1A to FIG. 1D includes an insulator 210 over a substrate (not illustrated), an insulator 222 over the insulator 210, the transistor 200 over the insulator 222, an insulator 280 over the insulator 222, and an insulator 283 over the transistor 200. The insulator 210, the insulator 222, and the insulator 280 each function as an interlayer film.

The transistor 200 includes a conductor 220 over the insulator 222, a conductor 240 over the insulator 280, an oxide semiconductor 230 in contact with at least part of the top surface of the conductor 220, an insulator 250 over the oxide semiconductor 230, and a conductor 260 over the insulator 250. The conductor 240 includes a conductor 240a and a conductor 240b over the conductor 240a.

As illustrated in FIG. 1B and FIG. 1C, an opening portion 290 reaching the conductor 220 is provided in the insulator 280 and the conductor 240. Here, the bottom portion of the opening portion 290 is the top surface of the conductor 220, and the sidewall of the opening portion 290 is the side surface of the insulator 280 and the side surface of the conductor 240. The opening portion 290 includes an opening portion of the insulator 280 and an opening portion of the conductor 240. In other words, the opening portion of the insulator 280 in a region overlapping with the conductor 220 is part of the opening portion 290, and the opening portion of the conductor 240 in a region overlapping with the conductor 220 is another part of the opening portion 290.

At least parts of the components of the transistor 200 are positioned in the opening portion 290. Specifically, at least part of each of the oxide semiconductor 230, the insulator 250, and the conductor 260 is positioned in the opening portion 290.

Portions of the oxide semiconductor 230 and the insulator 250 that are positioned in the opening portion 290 reflect the shape of the opening portion 290. Thus, the oxide semiconductor 230 is provided to cover the bottom portion and the sidewall of the opening portion 290, and the insulator 250 is provided to cover the oxide semiconductor 230. Furthermore, the conductor 260 is provided to fill a depressed portion of the insulator 250 that reflects the shape of the opening portion 290.

In the transistor 200, the oxide semiconductor 230 functions as a semiconductor layer, the conductor 260 functions as a gate electrode, the insulator 250 functions as a gate insulator, the conductor 220 functions as one of a source electrode and a drain electrode, and the conductor 240 functions as the other of the source electrode and the drain electrode.

As described above, the oxide semiconductor 230 is provided in the opening portion of the insulator 280. The transistor 200 has a structure in which current flows in the vertical direction since one of the source electrode and the drain electrode (here, the conductor 220) is positioned on the lower side and the other of the source electrode and the drain electrode (here, the conductor 240) is positioned on the upper side. That is, a channel is formed along the side surface of the opening portion of the insulator 280.

In the transistor 200, a metal oxide functioning as a semiconductor (also referred to as an oxide semiconductor) is preferably used as the oxide semiconductor 230 including a channel formation region. In that case, the transistor 200 is an OS transistor.

When oxygen vacancies (Vo) and impurities exist in a channel formation region in an oxide semiconductor in an OS transistor, the electrical characteristics of the OS transistor may easily vary and the reliability thereof may worsen. In some cases, a defect that is an oxygen vacancy into which hydrogen in the vicinity of the oxygen vacancy has entered (hereinafter, sometimes referred to as VoH) is formed, leading to generation of an electron serving as a carrier. Thus, when the channel formation region in the oxide semiconductor includes oxygen vacancies, the OS transistor is likely to have normally-on characteristics. Accordingly, oxygen vacancies and hydrogen, which is an example of impurities, are preferably reduced as much as possible in the channel formation region in the oxide semiconductor. In other words, the oxide semiconductor preferably includes an i-type (intrinsic) or substantially i-type channel formation region with a reduced carrier concentration. However, when an excess amount of oxygen is supplied to the oxide semiconductor, an electron trap due to excess oxygen is formed in a gate insulating film. Hence, the OS transistor might have normally-off characteristics excessively.

In this specification and the like, normally-on characteristics mean a state where a channel exists without application of voltage to a gate and current flows between a source and a drain of a transistor. Furthermore, normally-off characteristics mean a state where current does not flow between a source and a drain of a transistor when a potential is not applied to a gate or a ground potential is applied to a gate.

Meanwhile, it is preferable that the source region and the drain region of the OS transistor include more oxygen vacancies, include more VoH, or have a higher concentration of an impurity such as hydrogen, nitrogen, or a metal element than the channel formation region, and thus be low-resistance regions with high carrier concentrations. That is, the source region and the drain region of the OS transistor are preferably n-type regions having higher carrier concentrations and lower resistances than the channel formation region.

In order to improve the electrical characteristics and reliability of the OS transistor, it is important to sufficiently reduce the hydrogen concentration in the channel formation region in the oxide semiconductor and optimize the amount of oxygen supplied to the oxide semiconductor. For example, the hydrogen concentration in the channel formation region of the oxide semiconductor, which is obtained by secondary ion mass spectrometry (SIMS), is preferably lower than 1×10²⁰ atoms/cm³, further preferably lower than 5×10¹⁹ atoms/cm³, still further preferably lower than 1×10¹⁹ atoms/cm³, yet further preferably lower than 5×10¹⁸ atoms/cm³, yet still further preferably lower than 1×10¹⁸ atoms/cm³, yet still further preferably lower than 1×10¹⁷ atoms/cm³.

In view of this, in one embodiment of the present invention, a barrier insulator against hydrogen is preferably used as each of the insulator 210 and the insulator 283. The insulator 210 and the insulator 283 are provided such that the transistor 200 including the oxide semiconductor 230 is sandwiched therebetween. When the insulator 210 and the insulator 283 located outward from the oxide semiconductor 230 each have a barrier property against hydrogen, diffusion of hydrogen into the oxide semiconductor 230 can be inhibited.

In this specification and the like, a barrier insulator refers to an insulator having a barrier property. A barrier property refers to a property that does not easily allow diffusion of a target substance (also referred to as a property that does not easily allow passage of a target substance, a property with low permeability to a target substance, or a function of inhibiting diffusion of a target substance). Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

Examples of the barrier insulator against hydrogen include aluminum oxide, magnesium oxide, hafnium oxide, gallium oxide, silicon nitride, and silicon nitride oxide.

Silicon nitride is preferably used for the insulator 210 and the insulator 283, for example. In that case, the insulator 210 and the insulator 283 each contain silicon and nitrogen.

Silicon nitride that can be used for the insulator 210 and the insulator 283 has a barrier property against hydrogen when having a thickness of 2 nm or more, for example. In order to enhance a barrier property against hydrogen, the thickness of silicon nitride is preferably greater than or equal to 3 nm, further preferably greater than or equal to 5 nm. Note that silicon nitride has a barrier property against oxygen when having a thickness of 1 nm or more, for example. In order to enhance a barrier property against oxygen, the thickness of silicon nitride is preferably greater than or equal to 2 nm. That is, silicon nitride formed to have such a thickness that it has a barrier property against hydrogen also has a barrier property against oxygen.

As the insulator 222, an insulator having a function of capturing or fixing hydrogen is preferably used. When the insulator 222 has a function of capturing or fixing hydrogen, the hydrogen concentration in the oxide semiconductor 230 positioned inward from the insulator 210 and the insulator 283 can be reduced. Since hydrogen in the oxide semiconductor 230 is captured or fixed by the insulator 222 in that case, the hydrogen concentration in the insulator 222 increases. For example, the hydrogen concentration, which is obtained by SIMS, in at least part of the insulator 222 may be higher than or equal to 1×10¹⁹ atoms/cm³ or higher than or equal to 1×10²⁰ atoms/cm³. In that case, the hydrogen concentration in at least part of the insulator 222 is higher than the hydrogen concentration in the oxide semiconductor 230. In other words, the oxide semiconductor 230 includes a region having a lower hydrogen concentration than the insulator 222.

Note that a function of capturing or fixing a target substance can also be referred to as a property that does not easily allow diffusion of a target substance. Thus, a function of capturing or fixing a target substance can be rephrased as a barrier property.

As the insulator having a function of capturing or fixing hydrogen, a metal oxide containing hafnium or the like (e.g., hafnium oxide) is preferable. The metal oxide preferably contains an oxygen atom having a dangling bond. Such a metal oxide has a property of capturing or fixing hydrogen with the dangling bond in some cases. For example, the metal oxide preferably has an amorphous structure because some oxygen atoms in a metal oxide having an amorphous structure have dangling bonds. Although the metal oxide preferably has an amorphous structure, a crystal region is partly formed in some cases. The metal oxide partly has a crystal grain boundary in some cases.

Here, when silicon is added to hafnium oxide, the crystallization of hafnium oxide can be inhibited. That is, an oxide containing hafnium and silicon (hereinafter, sometimes referred to as hafnium silicate) is likely to have an amorphous structure. Thus, hafnium silicate has a property of capturing or fixing hydrogen and is suitable as the insulator 222. In that case, the insulator 222 contains hafnium, silicon, and oxygen.

The proportion of silicon to hafnium and silicon in the insulator 222 in composition is higher than or equal to 0.1 atomic % and lower than 100 atomic %, preferably higher than or equal to 0.1 atomic % and lower than or equal to 70 atomic %, further preferably higher than or equal to 0.1 atomic % and lower than or equal to 50 atomic %, still further preferably higher than or equal to 0.1 atomic % and lower than or equal to 30 atomic %, yet further preferably higher than or equal to 1 atomic % and lower than or equal to 10 atomic %, yet still further preferably higher than or equal to 3 atomic % and lower than or equal to 8 atomic %. The proportion of silicon in the composition of the hafnium silicate can be quantified by X-ray photoelectron spectroscopy (XPS) measurement, for example. Note that a metal such as zirconium is contained in hafnium silicate in some cases, and the metal may be included as a measurement target. In that case, normalization may be performed such that the sum of the proportions of hafnium, silicon, and zirconium in the composition is 100 atomic %.

Although an oxide containing hafnium is given above as an example of the insulator having a function of capturing or fixing hydrogen, the present invention is not limited thereto. Examples of the insulator include an oxide containing magnesium, an oxide containing aluminum, and an oxide containing aluminum and hafnium (hafnium aluminate). Alternatively, the above-described metal oxide further containing zirconium may be used. For example, an oxide containing hafnium and zirconium can be given. These metal oxides preferably have an amorphous structure by addition of silicon.

The insulator 222 can capture or fix hydrogen released from the oxide semiconductor 230 by heat treatment. Here, the insulator 222 and the oxide semiconductor 230 are preferably provided in a closed system formed of the insulator 210 and the insulator 283 each having a barrier property against hydrogen. Accordingly, the frequency of hydrogen transfer between the inside and the outside of the closed system becomes extremely low; thus, diffusion of hydrogen from the outside to the inside of the closed system or from the inside to the outside during the heat treatment can be prevented. Thus, hydrogen inside the closed system is captured or fixed by the insulator 222, so that the hydrogen concentration in the oxide semiconductor 230 can be reduced. Here, the closed system refers to a barrier insulator against hydrogen that covers at least part of the oxide semiconductor and inhibits hydrogen from diffusing from the outside to the inside of the closed system or from the inside to the outside. Here, in the closed system, a portion of the oxide semiconductor that functions as the channel formation region is preferably positioned inside the barrier insulators against hydrogen. For example, in the closed system, it is preferable that the barrier insulators against hydrogen be provided to extend in the channel length direction of the oxide semiconductor, and that the oxide semiconductor be surrounded by or sandwiched between the barrier insulators against hydrogen. Note that the closed system does not completely block hydrogen transfer but lowers the frequency of hydrogen transfer. Therefore, in some cases, the closed system is not completely closed but is opened at a position or a plurality of positions.

With the above structure, an oxide semiconductor with few oxygen vacancies and impurities can be provided. Thus, the transistor can have excellent electrical characteristics and higher reliability. Moreover, the semiconductor device can have a small variation in electrical characteristics of the transistor.

With the above structure, formation of oxygen vacancies in a channel formation region and diffusion of hydrogen into the channel formation region can be inhibited. This can inhibit variations in the amount of oxygen vacancies and the hydrogen concentration in the channel formation region between transistors. Thus, variations in the electrical characteristics of the transistors can be reduced.

The barrier insulator against hydrogen is preferably used also as the insulator 280. For example, silicon nitride is preferably used for the insulator 280. Such a structure can inhibit diffusion of hydrogen into the oxide semiconductor 230. The concentration of impurities such as water and hydrogen in the insulator 280 is preferably reduced. This can inhibit entry of impurities such as water and hydrogen into the channel formation region of the oxide semiconductor 230. Furthermore, when silicon nitride is used for the insulator 280, excess oxygen can be prevented from being supplied to the oxide semiconductor 230. Thus, the channel formation region of the oxide semiconductor 230 can be prevented from containing excess oxygen, whereby the reliability of the transistor 200 can be improved. As the insulator 280, a single layer or stacked layers of any of insulators described later in a section [Insulator] may be used.

The sidewall of the opening portion 290 is preferably perpendicular to the top surface of the insulator 210. With such a structure, the semiconductor device can be scaled down or highly integrated.

Although the opening portion 290 is provided such that the sidewall of the opening portion 290 is perpendicular to the top surface of the conductor 220 in FIG. 1B and FIG. 1C, the present invention is not limited thereto. For example, the sidewall of the opening portion 290 is not strictly perpendicular and has a tapered shape in some cases. Here, as illustrated in FIG. 3A, a taper angle formed by the side surface of the insulator 280, which is part of the sidewall of the opening portion 290, and the top surface of the conductor 220 (which may be the top surface of the insulator 222 or the top surface of the insulator 210) is an angle θ1. The angle θ1 is preferably 90° or an angle in the vicinity of 90°. For example, the angle θ1 is preferably greater than or equal to 75° and less than or equal to 90°.

The angle θ1 is sometimes less than 75°, less than 70°, less than 65°, or less than 60°.

The oxide semiconductor 230 includes a region in contact with the side surface of the conductor 240 in the opening portion 290 and a region in contact with at least part of the top surface of the conductor 240. When the oxide semiconductor 230 is in contact with not only the side surface but also the top surface of the conductor 240 in this manner, the area where the oxide semiconductor 230 and the conductor 240 are in contact with each other can be increased. The oxide semiconductor 230 also includes a region in contact with the top surface of the conductor 220 that is exposed in the opening portion 290 and a region in contact with the side surface of the insulator 280 in the opening portion 290.

As illustrated in FIG. 1B and FIG. 1C, part of the oxide semiconductor 230 is positioned outside the opening portion 290, that is, over the conductor 240. Although FIG. 1B illustrates the structure in which the oxide semiconductor 230 is divided in the X direction, the present invention is not limited thereto. For example, the oxide semiconductor 230 may be provided to extend in the X direction. Also in this case, the oxide semiconductor 230 is divided in the Y direction.

FIG. 1C illustrates a structure in which the side end portion of the oxide semiconductor 230 is positioned inward from the side end portion of the conductor 240. Note that the present invention is not limited thereto. For example, the side end portion of the oxide semiconductor 230 and the side end portion of the conductor 240 may be aligned with each other in the Y direction. Alternatively, the side end portion of the oxide semiconductor 230 may be positioned outward from the side end portion of the conductor 240.

The insulator 250 is provided in contact with the top surface of the oxide semiconductor 230. The insulator 250 includes a region in contact with the top surface of the conductor 240, a region in contact with the side surface of the conductor 240, and a region in contact with the insulator 280.

As illustrated in FIG. 1B and FIG. 1C, part of the insulator 250 is positioned outside the opening portion 290, that is, over the conductor 240 and the insulator 280. In that case, the insulator 250 preferably covers the side end portion of the oxide semiconductor 230. This can prevent a short circuit between the conductor 260 and the oxide semiconductor 230. The insulator 250 preferably covers the side end portion of the conductor 240. This can prevent a short circuit between the conductor 260 and the conductor 240.

The conductor 260 is provided in contact with the top surface of the insulator 250.

As illustrated in FIG. 1B and FIG. 1C, part of the conductor 260 is positioned outside the opening portion 290, that is, over the conductor 240 and the insulator 280. In that case, the side end portion of the conductor 260 is preferably positioned inward from the side end portion of the oxide semiconductor 230 as illustrated in FIG. 1B. This can prevent a short circuit between the conductor 260 and the oxide semiconductor 230. The side end portion of the conductor 260 may be aligned with the side end portion of the oxide semiconductor 230 or positioned outward from the side end portion of the oxide semiconductor 230.

Although the conductor 260 is provided to fill the opening portion 290 in FIG. 1B and FIG. 1C, the present invention is not limited thereto. For example, a depressed portion reflecting the shape of the opening portion 290 is formed in the conductor 260 and part of the depressed portion is positioned in the opening portion 290 in some cases. In that case, the depressed portion may be filled with an inorganic insulating material or the like.

The conductor 240 has the opening portion in a region overlapping with the conductor 220. It is preferable that the conductor 240 not be provided in the opening portion of the insulator 280. That is, it is preferable that the conductor 240 not include a region in contact with the side surface of the insulator 280 in the opening portion 290. With such a structure, the opening portion of the conductor 240 and the opening portion of the insulator 280 can be collectively formed. When the side surface of the conductor 240 in the opening portion 290 is aligned with the side surface of the insulator 280 in the opening portion 290, the thickness distribution of the oxide semiconductor 230 provided in the opening portion 290 can be uniform. In addition, the oxide semiconductor 230 can be inhibited from being divided by a step between the conductor 240 and the insulator 280.

Although FIG. 1B and FIG. 1C illustrate the structure in which the side surface of the conductor 240 in the opening portion 290 is aligned with the side surface of the insulator 280 in the opening portion 290, the present invention is not limited thereto. For example, the side surface of the conductor 240 in the opening portion 290 and the side surface of the insulator 280 in the opening portion 290 may be discontinuous. The inclination of the side surface of the conductor 240 in the opening portion 290 and the inclination of the side surface of the insulator 280 in the opening portion 290 may be different from each other. In that case, for example, the angle between the side surface of the conductor 240 in the opening portion 290 and the top surface of the insulator 210 is preferably smaller than the angle between the side surface of the insulator 280 in the opening portion 290 and the top surface of the insulator 210. With such a structure, the coverage of the side surface of the conductor 240 with the oxide semiconductor 230 in the opening portion 290 is improved, so that the number of defects such as voids can be reduced.

The conductor 240 preferably has a stacked-layer structure. For example, the conductor 240 preferably has a stacked-layer structure of the conductor 240a and the conductor 240b in contact with the top surface of the conductor 240a.

The bottom surface of the conductor 240a is in contact with the insulator 280, one side surface thereof is in contact with the oxide semiconductor 230, and the other side surface thereof is in contact with the insulator 250. For the conductor 240a, a metal having higher conductivity than that for the conductor 240b is preferably used. In addition, for the conductor 240a, a metal having lower sheet resistance than that for the conductor 240b is preferably used. With such a structure, the conductor 240 including the conductor 240a can function as a wiring electrically connected to one of the source electrode and the drain electrode.

For the conductor 240a, one or more of ruthenium, tantalum, nickel, titanium, molybdenum, tungsten, hafnium, vanadium, niobium, aluminum, chromium, copper, silver, gold, platinum, zinc, manganese, iron, cobalt, magnesium, zirconium, beryllium, indium, iridium, strontium, and lanthanum, an alloy including one or more of these metals as its components, or the like can be used.

The conductor 240a may partly include a metal oxide of the above metal. In that case, a layer of the metal oxide is sometimes formed in the vicinity of an interface between the conductor 240a and the conductor 240b and in the vicinity of an interface between the conductor 240a and the oxide semiconductor 230. Ruthenium and an alloy of ruthenium are preferable because they are each a material that maintains relatively low electric resistance even when oxidized.

One side surface and part of the top surface of the conductor 240b are in contact with the oxide semiconductor 230. The other side surface and another part of the top surface of the conductor 240b are in contact with the insulator 250. It is preferable that the conductor 240b have an ohmic contact with the oxide semiconductor 230 and have a low contact resistance with the oxide semiconductor 230. For example, the contact resistance between the conductor 240b and the oxide semiconductor 230 is preferably lower than the contact resistance between the oxide semiconductor 230 and the metal layer used for the conductor 240a. Thus, as the conductor 240b, a metal oxide having conductivity (sometimes referred to as a conductive oxide) is preferably used. The conductor 240b having the above structure allows the on-state current, field-effect mobility, and frequency characteristics of the transistor 200 to be improved.

As the conductive oxide (also referred to as OC: Oxide Conductor or a conductive material containing oxygen) used for the conductor 240b, a conductive oxide containing indium is preferable. As the conductive oxide containing indium, indium oxide, indium tin oxide (sometimes referred to as ITO), indium zinc oxide, indium tin oxide to which silicon is added (also referred to as ITSO), or the like is preferably used. Indium oxide may contain tungsten, titanium, or the like; for example, an In—W oxide, an In—W—Zn oxide, an In—Ti oxide, an In—Ti—Sn oxide, or the like may be used. A conductive oxide containing zinc may be used; for example, zinc oxide, zinc oxide to which gallium is added, an In—Ga—Zn oxide, or the like can be used. As the conductive oxide, ruthenium oxide, an oxide containing strontium and ruthenium, an oxide containing lanthanum and nickel, or the like can also be used. A conductive oxide containing indium is particularly preferable because of its high conductivity.

For example, indium tin oxide to which silicon is added is used for the conductor 240b. In that case, the conductor 240b contains indium, tin, silicon, and oxygen. Here, addition of silicon to indium tin oxide can inhibit polycrystallization of the indium tin oxide. That is, indium tin oxide to which silicon is added is likely to have an nc structure (nanocrystal structure) or an amorphous structure. Note that the present invention is not limited to the above. Polycrystallized indium tin oxide can also be used for the conductor 240b. In that case, the conductor 240b contains indium, tin, and oxygen.

As described above, heat treatment is performed on a structure in which the conductor 240a includes a metal and the conductor 240b includes a conductive oxide, so that oxygen in the conductor 240b diffuses to the vicinity of the interface with the conductor 240a and an oxygen vacancy (Vo) is formed in the conductor 240b. Furthermore, oxygen in the oxide semiconductor 230 in the vicinity of the conductor 240 diffuses to the vicinity of the interface with each of the conductor 240a and the conductor 240b in which the oxygen vacancy (Vo) is formed, so that an oxygen vacancy (Vo) is formed in a region of the oxide semiconductor 230 that is in the vicinity of the conductor 240. When hydrogen enters the oxygen vacancy (Vo) and VoH is formed, the resistance of the region of the oxide semiconductor 230 that is in the vicinity of the conductor 240 is lowered in a self-aligned manner. The region having lowered resistance functions as one of a source region and a drain region of the transistor 200. With the use of silicon nitride for the insulator 280, the region of the oxide semiconductor 230 where VoH is formed can be prevented from excessively expanding to a region below the conductor 240a. That is, the one of the source region and the drain region can be prevented from excessively expanding to the region below the conductor 240a.

Although the example in which the conductor 240 has a stacked-layer structure of two layers of the conductor 240a and the conductor 240b is described above, the present invention is not limited thereto. The conductor 240 may have a stacked-layer structure of three or more layers.

As the conductor 220, a single layer or stacked layers of any of conductors described later in a section [Conductor] can be used. A conductive material that is less likely to be oxidized, a conductive material having a function of inhibiting diffusion of oxygen, or the like is preferably used for the conductor 220. For example, titanium nitride, tantalum nitride, or the like can be used.

As illustrated in FIG. 3A, the conductor 220 may have a stacked-layer structure of a conductor 220a and a conductor 220b over the conductor 220a. Here, the conductor 220a is preferably formed using a metal having high conductivity, like the conductor 240a. Thus, the conductor 220a is formed using any of the metals that can be used for the conductor 240a. For example, tungsten is used for the conductor 220a. With such a structure, the conductor 220 including the conductor 220a can function as a wiring electrically connected to the other of the source electrode and the drain electrode.

The conductor 220b is preferably formed using a conductive oxide, like the conductor 240b. Thus, the conductor 220b is formed using any of the conductive oxides that can be used for the conductor 240b. For example, indium tin oxide to which silicon is added is used for the conductor 220b. In that case, the conductor 220b contains indium, tin, silicon, and oxygen. Such a structure allows the on-state current, field-effect mobility, and frequency characteristics of the transistor 200 to be improved.

As described above, heat treatment is performed on a structure in which the conductor 220a includes a metal and the conductor 220b includes a conductive oxide, so that oxygen in the conductor 220b diffuses to the vicinity of the interface with the conductor 220a and an oxygen vacancy (Vo) is formed in the conductor 220b. Furthermore, oxygen in the oxide semiconductor 230 in the vicinity of the conductor 220 diffuses to the vicinity of the interface with each of the conductor 220a and the conductor 220b in which the oxygen vacancy (Vo) is formed, so that an oxygen vacancy (Vo) is formed in a region of the oxide semiconductor 230 that is in the vicinity of the conductor 220. When hydrogen enters the oxygen vacancy (Vo) and VoH is formed, the resistance of the region of the oxide semiconductor 230 that is in the vicinity of the conductor 220 is lowered in a self-aligned manner. The region having lowered resistance functions as the other of the source region and the drain region of the transistor 200. As described above, the insulator 222 placed below the conductor 220 captures hydrogen in the oxide semiconductor 230 through the conductor 220 by the heat treatment. At this time, hydrogen in the channel formation region of the oxide semiconductor 230 diffuses to the other of the source region and the drain region; thus, VoH can be formed more efficiently in the other of the source region and the drain region. With the use of silicon nitride for the insulator 280, the region of the oxide semiconductor 230 where VoH is formed can be prevented from excessively expanding to a region above the conductor 220b. That is, the other of the source region and the drain region can be prevented from excessively expanding to the region above the conductor 220b.

Although FIG. 1B and FIG. 1C illustrate the structure in which the top surface of the conductor 220 is flat, the present invention is not limited thereto. For example, as illustrated in FIG. 3A, the top surface of the conductor 220 may have a depressed portion overlapping with the opening portion 290. When at least parts of the oxide semiconductor 230, the insulator 250, and the conductor 260 are formed to fill the depressed portion, the gate electric field of the conductor 260 can be easily applied to a portion of the oxide semiconductor 230 close to the conductor 220. In addition, the contact area between the oxide semiconductor 230 and the conductor 220 can be increased and the contact resistance between the oxide semiconductor 230 and the conductor 220 can be reduced. Thus, the on-state current of the transistor 200 can be increased.

The oxide semiconductor 230 includes the channel formation region between the source region and the drain region. Here, one of the source region and the drain region includes at least part of a region of the oxide semiconductor 230 that is in contact with the conductor 240. The other of the source region and the drain region includes at least part of a region of the oxide semiconductor 230 that is in contact with the conductor 220. That is, the channel formation region of the transistor 200 is positioned in a region of the oxide semiconductor 230 that is between the conductor 220 and the conductor 240. It can be said that the channel formation region of the transistor 200 is positioned in a region of the oxide semiconductor 230 that is in contact with the insulator 280 or a region in the vicinity thereof.

Here, a cross-sectional view along the XY plane including the insulator 280 is shown in FIG. 1D. As illustrated in FIG. 1D, the insulator 280 is in contact with the entire outer circumference of the oxide semiconductor 230. Thus, the channel formation region of the transistor 200 can be formed in the entire outer circumference of a portion of the oxide semiconductor 230 that is formed in the same layer as the insulator 280. Note that FIG. 1D can be regarded as a cross-sectional view along the XY plane including the channel formation region of the oxide semiconductor 230.

The channel length of the transistor 200 is a distance between the source region and the drain region. That is, it can be said that the channel length of the transistor 200 is determined by the thickness of the insulator 280 over the conductor 220. In FIG. 1B, the channel length L of the transistor 200 is indicated by a dashed double-headed arrow. In a cross-sectional view, the channel length L is a distance between an end portion of a region where the oxide semiconductor 230 is in contact with the conductor 220 and an end portion of a region where the oxide semiconductor 230 is in contact with the conductor 240. That is, the channel length L corresponds to the length of the side surface of the insulator 280 on the opening portion 290 side in a cross-sectional view.

The channel length of a planar transistor is limited by the light exposure limit of photolithography, and further scaling down is difficult. By contrast, in the present invention, the channel length can be determined by the thickness of the insulator 280. Thus, the transistor 200 can have an extremely small channel length L less than or equal to the light exposure limit of photolithography (e.g., less than or equal to 500 nm, less than or equal to 100 nm, less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 200 can have a higher on-state current and improved frequency characteristics.

As described above, the channel formation region, the source region, and the drain region can be formed in the opening portion 290. Thus, the area occupied by the transistor 200 can be smaller than the area occupied by a planar transistor in which a channel formation region, a source region, and a drain region are provided separately on the XY plane. Accordingly, high integration of the semiconductor device can be achieved. In the case where the semiconductor device of one embodiment of the present invention is used for a memory device, the memory capacity per unit area can be increased.

As illustrated in FIG. 1D, the oxide semiconductor 230, the insulator 250, and the conductor 260 are provided concentrically. Thus, the side surface of the conductor 260 provided at the center faces the side surface of the oxide semiconductor 230 with the insulator 250 therebetween. That is, in a plan view, the entire circumference of the oxide semiconductor 230 serves as the channel formation region. In that case, for example, the channel width of the transistor 200 is determined by the length of the outer circumference of the oxide semiconductor 230. That is, it can be said that the channel width of the transistor 200 is determined by the maximum width of the opening portion 290 (the diameter in the case where the opening portion 290 is circular in a plan view). In FIG. 1B and FIG. 1D, a maximum width D of the opening portion 290 is indicated by a dashed double-dotted double-headed arrow. In FIG. 1D, the channel width W of the transistor 200 is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is limited by the light exposure limit of photolithography. In addition, the maximum width D of the opening portion 290 is determined by the thicknesses of the oxide semiconductor 230, the insulator 250, and the conductor 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in a plan view, the maximum width D of the opening portion 290 corresponds to the diameter of the opening portion 290, and the channel width W can be calculated to be “D×π”.

In the semiconductor device of one embodiment of the present invention, the channel length L of the transistor 200 is preferably smaller than at least the channel width W of the transistor 200. The channel length L of the transistor 200 of one embodiment of the present invention is greater than or equal to 0.1 times and less than or equal to 0.99 times, preferably greater than or equal to 0.5 times and less than or equal to 0.8 times the channel width W of the transistor 200. This structure enables the transistor to have excellent electrical characteristics and high reliability.

In the case where the opening portion 290 is formed to be circular in a plan view, the oxide semiconductor 230, the insulator 250, and the conductor 260 are provided concentrically. This makes the distance between the conductor 260 and the oxide semiconductor 230 substantially uniform, so that a gate electric field can be substantially uniformly applied to the oxide semiconductor 230.

Although this embodiment describes the example in which the opening portion 290 is circular in a plan view, the present invention is not limited thereto. For example, the opening portion 290 in a plan view may have an almost circular shape such as an elliptical shape, a polygonal shape such as a quadrangular shape, or a polygonal shape with rounded corners such as a quadrangular shape with rounded corners. In that case, the maximum width of the opening portion 290 can be calculated as appropriate in accordance with the shape of the uppermost portion of the opening portion 290. For example, in the case where the opening portion is quadrangular in a plan view, the maximum width of the opening portion 290 can be the length of a diagonal line of the uppermost portion of the opening portion 290.

As the oxide semiconductor 230, a single layer or stacked layers of any of metal oxides described later in a section [Metal oxide] can be used.

As the oxide semiconductor 230, specifically, a metal oxide with a composition of In:M:Zn=1:3:2 [atomic ratio] or in the neighborhood thereof, a metal oxide with a composition of In:M:Zn=1:3:4 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:2 [atomic ratio] or in the neighborhood thereof, or a metal oxide with a composition of In:M:Zn=4:2:3 [atomic ratio] or in the neighborhood thereof may be used. Note that a composition in the neighborhood includes the range of ±30% of an intended atomic ratio. It is preferable to use one or more of gallium, aluminum, and tin as an element M.

The oxide semiconductor 230 may have a structure not containing the element M. For example, a metal oxide used as the oxide semiconductor 230 may be an In—Zn oxide. Specifically, the oxide semiconductor 230 can have a composition of In:Zn=1:1 [atomic ratio] or in the neighborhood thereof or a composition of In:Zn=4:1 [atomic ratio] or in the neighborhood thereof. Alternatively, an indium oxide may be used as the oxide semiconductor 230. The oxide semiconductor 230 may contain a slight amount of the element M. Specifically, the oxide semiconductor 230 can have a composition of In:Sn:Zn=4:0.1:1 [atomic ratio] or in the neighborhood thereof, for example.

For analysis of the composition of a metal oxide used as the oxide semiconductor 230, for example, energy dispersive X-ray spectroscopy (EDX), X-ray photoelectron spectroscopy (XPS), inductively coupled plasma-mass spectrometry (ICP-MS), or inductively coupled plasma-atomic emission spectrometry (ICP-AES) can be used. Alternatively, some of these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used for forming the metal oxide. In the case where the metal oxide is formed by a sputtering method, the composition of the formed metal oxide may be different from the composition of a sputtering target. In particular, the content percentage of zinc in the formed metal oxide may be reduced to approximately 50% of that in the sputtering target.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method enables atomic layers to be deposited one by one, and has advantages such as formation of an extremely thin film, formation of a film on a component with a high aspect ratio or on a surface with a large step, formation of a film with few defects such as pinholes, formation of a film with excellent coverage, and low-temperature film formation. The use of plasma in a PEALD method is sometimes preferable because it enables film formation at a lower temperature. Note that a precursor used in an ALD method sometimes contains an element such as carbon or chlorine. Thus, in some cases, a film provided by an ALD method contains a larger amount of an element such as carbon or chlorine than a film provided by another film formation method. Note that these elements can be quantified by XPS or SIMS. The film formation method of a metal oxide of one embodiment of the present invention, which employs an ALD method and one or both of a film formation condition with a high substrate temperature and impurity removal treatment, can sometimes form a film with smaller amounts of carbon and chlorine than a method employing an ALD method without the film formation condition with a high substrate temperature or the impurity removal treatment.

Unlike a film formation method in which particles ejected from a target or the like are deposited, an ALD method is a film formation method in which a film is formed by reaction at a surface of an object. Thus, an ALD method is a film formation method that enables good step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a sputtering method or a CVD method, in some cases. In the case where a metal oxide has a stacked-layer structure of a first metal oxide and a second metal oxide, a method in which the first metal oxide is formed by a sputtering method and the second metal oxide is formed by an ALD method over the first metal oxide can be given as an example. For example, in the case where the first metal oxide has a crystal part, crystal growth occurs in the second metal oxide with the use of the crystal part as a nucleus.

When an ALD method is employed, the composition of a film to be formed can be controlled with the amount of introduced source gases. For example, a film with a certain composition can be formed by adjusting the amount of introduced source gases, the number of times of introduction (also referred to as the number of pulses), and the time required for one pulse (also referred to as the pulse time) in an ALD method. Moreover, for example, when the source gas is changed during the film formation in an ALD method, a film having a continuously-changed composition can be formed. In the case where the film is formed while the source gas is changed, as compared to the case where a film is formed using a plurality of film formation chambers, the time taken for the film formation can be shortened because the time taken for transfer and pressure adjustment is omitted. Thus, the productivity of the semiconductor device can be increased in some cases.

Note that there is no particular limitation on a method for forming an oxide semiconductor film to be the oxide semiconductor 230. For example, the oxide semiconductor film may be formed by a CVD method, an MBE method, a PLD method, or the like.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide semiconductor 230, the CAAC-OS or the nc-OS is preferably used, and the CAAC-OS is particularly preferably used.

It is preferable that the CAAC-OS include a plurality of layered crystal regions and that a c-axis be aligned in a normal direction of a formation surface. For example, the oxide semiconductor 230 preferably includes a layered crystal that is substantially parallel to the sidewall of the opening portion 290, particularly the side surface of the insulator 280. With this structure, the layered crystals of the oxide semiconductor 230 are formed substantially in parallel with the channel length direction of the transistor, so that the on-state current of the transistor can be increased.

The CAAC-OS is a metal oxide having a dense structure with high crystallinity and small numbers of impurities and defects (e.g., oxygen vacancies). In particular, after the formation of a metal oxide, heat treatment is performed at a temperature at which the metal oxide does not become a polycrystal (e.g., higher than or equal to 400 ° C and lower than or equal to 600 ° C), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as a CAAC-OS, is used as the oxide semiconductor 230, oxygen extraction from the oxide semiconductor 230 by the source electrode or the drain electrode can be inhibited. This can inhibit oxygen extraction from the oxide semiconductor 230 even when heat treatment is performed; thus, the transistor is stable with respect to high temperatures in a manufacturing process (what is called thermal budget).

The crystallinity of the oxide semiconductor 230 can be analyzed with X-ray diffraction (XRD), a transmission electron microscope (TEM), or electron diffraction (ED), for example. Alternatively, some of these methods may be combined for the analysis.

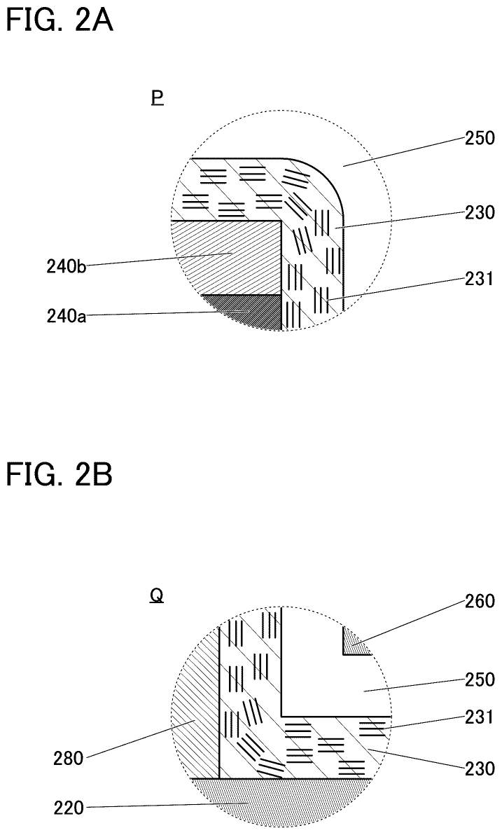

In the case where the oxide semiconductor 230 is a CAAC-OS, the oxide semiconductor 230 preferably includes layered crystal parts. In that case, the crystal parts are preferably aligned such that the c-axes are parallel to the normal direction of the formation surface. FIG. 2A and FIG. 2B are enlarged views of a region P and a region Q, respectively, in FIG. 1B. FIG. 2A and FIG. 2B schematically illustrate crystal parts 231 each having a layered structure. Each of the c-axes of the crystal parts 231 is in the direction orthogonal to a line segment representing the layered structure. In a typical crystal having a layered structure, carrier transfer and current flow occur more easily in the in-plane direction than in the layer-stacking direction in many cases. Thus, when the oxide semiconductor 230 including the crystal parts 231 with such alignment is used, the direction in which current flows in the oxide semiconductor 230 is always parallel to the in-plane direction of the crystal, so that a large amount of current can flow.

When a conductive oxide having an amorphous structure is used as each of the conductor 240b and the conductor 220b as described above, the oxide semiconductor 230 in contact with the top surfaces of the conductor 240b and the conductor 220b can become a CAAC-OS relatively easily. Thus, indium tin oxide to which silicon is added is preferably used for each of the conductor 240b and the conductor 220b.

Note that the present invention is not limited to the above. For example, the oxide semiconductor 230 can be polycrystallized by using polycrystallized indium tin oxide for the conductor 240b.

Although FIG. 1B and FIG. 1C illustrate the oxide semiconductor 230 being a single layer, the present invention is not limited thereto. The oxide semiconductor 230 may have a stacked-layer structure of a plurality of oxide layers with different chemical compositions. For example, a structure may be employed in which a plurality of kinds of metal oxides selected from the metal oxides described later in the section [Metal oxide] are stacked as appropriate.

For example, as illustrated in FIG. 3A, the oxide semiconductor 230 may have a stacked-layer structure of an oxide semiconductor 230a and an oxide semiconductor 230b over the oxide semiconductor 230a.

The conductivity of a material used for the oxide semiconductor 230a is preferably different from the conductivity of a material used for the oxide semiconductor 230b.

For example, a material having higher conductivity than a material for the oxide semiconductor 230b can be used for the oxide semiconductor 230a. The use of the material having high conductivity for the oxide semiconductor 230a, which is in contact with the conductor 220 and the conductor 240 functioning as the source electrode and the drain electrode, can reduce the contact resistance between the oxide semiconductor 230 and the conductor 220 and the contact resistance between the oxide semiconductor 230 and the conductor 240, and thus the transistor can have a high on-state current.

Here, in the case where a material having high conductivity is used for the oxide semiconductor 230b provided on the side of the conductor 260 functioning as the gate electrode, the threshold voltage of the transistor shifts and a drain current flowing when the gate voltage is 0 V (hereinafter, also referred to as cutoff current) increases in some cases. Specifically, the threshold voltage may be low when the transistor 200 is an n-channel transistor. Thus, a material having lower conductivity than a material for the oxide semiconductor 230a is preferably used for the oxide semiconductor 230b. Accordingly, the transistor 200 can have a high threshold voltage in the case where the transistor 200 is an n-channel transistor, in which case the transistor 200 can have a low cutoff current. Note that a low cutoff current is sometimes referred to as normally-off.

When the oxide semiconductor 230 has the stacked-layer structure and the material having higher conductivity than the material for the oxide semiconductor 230b is used for the oxide semiconductor 230a as described above, the transistor can have normally-off characteristics and a high on-state current. Consequently, the semiconductor device can have both low power consumption and high performance.

The carrier concentration of the oxide semiconductor 230a is preferably higher than the carrier concentration of the oxide semiconductor 230b. Increasing the carrier concentration of the oxide semiconductor 230a results in higher conductivity thereof, which can reduce the contact resistance between the oxide semiconductor 230 and the conductor 220 and the contact resistance between the oxide semiconductor 230 and the conductor 240, and thus the transistor can have a high on-state current. When the carrier concentration of the oxide semiconductor 230b is reduced, the conductivity is reduced, and thus the transistor can have normally-off characteristics.

Although the example in which a material having higher conductivity than a material for the oxide semiconductor 230b is used for the oxide semiconductor 230a is described here, the present invention is not limited thereto. A material having lower conductivity than a material for the oxide semiconductor 230b may be used for the oxide semiconductor 230a. The carrier concentration of the oxide semiconductor 230a can be lower than the carrier concentration of the oxide semiconductor 230b.

The band gap of a first metal oxide used for the oxide semiconductor 230a and the band gap of a second metal oxide used for the oxide semiconductor 230b are preferably different from each other. For example, the difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide semiconductor 230a can be smaller than the band gap of the second metal oxide used for the oxide semiconductor 230b. Thus, the contact resistance between the oxide semiconductor 230 and the conductor 220 and the contact resistance between the oxide semiconductor 230 and the conductor 240 can be reduced, and thus the transistor can have a high on-state current. Furthermore, the transistor 200 can have a high threshold voltage in the case where the transistor 200 is an n-channel transistor; accordingly, the transistor 200 can be a normally-off transistor.

Although the example in which the band gap of the first metal oxide is smaller than the band gap of the second metal oxide is described here, the present invention is not limited thereto. The band gap of the first metal oxide can be larger than the band gap of the second metal oxide.

As described above, the band gap of the first metal oxide used for the oxide semiconductor 230a can be smaller than the band gap of the second metal oxide used for the oxide semiconductor 230b. The composition of the first metal oxide is preferably different from the composition of the second metal oxide. When the compositions of the first metal oxide and the second metal oxide are different from each other, the band gap can be controlled. For example, the content percentage of the element M in the first metal oxide is preferably lower than the content percentage of the element M in the second metal oxide. Specifically, in the case where the first metal oxide and the second metal oxide are each an In-M-Zn oxide, the first metal oxide can have a composition of In:M:Zn=1:1:1 [atomic ratio] or in the neighborhood thereof, and the second metal oxide can have a composition of In:M:Zn=1:3:2 [atomic ratio] or in the neighborhood thereof. It is particularly preferable to use one or more of gallium, aluminum, and tin as the element M.

The first metal oxide may have a composition not including the element M. For example, the first metal oxide used for the oxide semiconductor 230a can be an In—Zn oxide, and the second metal oxide used for the oxide semiconductor 230b can be an In-M-Zn oxide. Specifically, the first metal oxide can be an In—Zn oxide, and the second metal oxide can be an In—Ga—Zn oxide. More specifically, the first metal oxide can have a composition of In:Zn=1:1 [atomic ratio] or in the neighborhood thereof or a composition of In:Zn=4:1 [atomic ratio] or in the neighborhood thereof, and the second metal oxide can have a composition of In:Ga:Zn=1:1:1 [atomic ratio] or in the neighborhood thereof. The first metal oxide may contain a slight amount of the element M. For example, the first metal oxide can have a composition of In:Sn:Zn=4:0.1:1 [atomic ratio] or in the neighborhood thereof.

Although the example in which the content percentage of the element M in the first metal oxide is lower than the content percentage of the element M in the second metal oxide is described here, one embodiment of the present invention is not limited thereto. The content percentage of the element M in the first metal oxide may be higher than the content percentage of the element M in the second metal oxide. As long as the compositions of the first metal oxide and the second metal oxide are different from each other, the content percentages of elements other than the element M may be different from each other.

The thickness of the oxide semiconductor 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thicknesses of the layers included in the oxide semiconductor 230 (here, the oxide semiconductor 230a and the oxide semiconductor 230b) are determined such that the thickness of the oxide semiconductor 230 is within the above-described range. The thickness of the oxide semiconductor 230a can be determined such that the contact resistance between the oxide semiconductor 230a and the conductor 220 and the contact resistance between the oxide semiconductor 230a and the conductor 240 are within required ranges. The thickness of the oxide semiconductor 230b can be determined such that the threshold voltage of the transistor is within a required range. Note that the thickness of the oxide semiconductor 230a may be the same as or different from the thickness of the oxide semiconductor 230b.

The oxide semiconductor 230a and the oxide semiconductor 230b differ in the ratio between the thickness of a portion formed over the top surface of the conductor 240 and the thickness of a portion formed along the side surface of the conductor 240 and the side surface of the insulator 280 in some cases.

Although FIG. 3A illustrates the structure in which the oxide semiconductor 230 has the stacked-layer structure of the two layers of the oxide semiconductor 230a and the oxide semiconductor 230b, the present invention is not limited thereto. The oxide semiconductor 230 may have a stacked-layer structure of three or more layers.

For example, as illustrated in FIG. 3B, the oxide semiconductor 230 may have a stacked-layer structure of the oxide semiconductor 230a, the oxide semiconductor 230b over the oxide semiconductor 230a, and an oxide semiconductor 230c over the oxide semiconductor 230b. In other words, in the structure illustrated in FIG. 3A, the oxide semiconductor 230c may be provided between the conductor 260 and the oxide semiconductor 230b.

The atomic ratio of the element M to In in the metal oxide used for the oxide semiconductor 230a is preferably greater than the atomic ratio of the element M to In in the metal oxide used for the oxide semiconductor 230b. With such a structure, impurities and oxygen can be inhibited from diffusing into the oxide semiconductor 230b from the components formed outside the oxide semiconductor 230a. In addition, diffusion of the element contained in the insulator 280, the conductor 220, or the conductor 240 into the oxide semiconductor 230b can be inhibited.

Since the insulator 280 has a function of inhibiting diffusion of hydrogen and oxygen, the oxide semiconductor 230a is not necessarily provided. In that case, the oxide semiconductor 230 may have a stacked-layer structure of the oxide semiconductor 230b and the oxide semiconductor 230c over the oxide semiconductor 230b.

For example, in the case where an oxide semiconductor film is formed by a formation method that causes less damage to the insulator 280, the oxide semiconductor 230a is not necessarily provided. For example, in the case where an oxide semiconductor film to be the oxide semiconductor 230b is formed by an ALD method or a CVD method, the oxide semiconductor 230a is not necessarily provided. In the case where the oxide semiconductor film is formed by an ALD method or a CVD method, damage to the insulator 280 is reduced, so that diffusion of the element contained in the insulator 280 into the oxide semiconductor film can be inhibited.

In the case where a material having high conductivity is used for the oxide semiconductor 230c provided on the side of the conductor 260 functioning as the gate electrode, the threshold voltage of the transistor 200 shifts and cutoff current increases in some cases. Specifically, the threshold voltage may be low when the transistor 200 is an n-channel transistor. Thus, a material having lower conductivity than a material for the oxide semiconductor 230b is preferably used for the oxide semiconductor 230c. Accordingly, the transistor 200 can have a high threshold voltage in the case where the transistor 200 is an n-channel transistor, in which case the transistor 200 can have a low cutoff current.

As described above, when the material having higher conductivity than the material for the oxide semiconductor 230c is used for the oxide semiconductor 230b, the transistor can have normally-off characteristics and a high on-state current. Consequently, the semiconductor device can have both low power consumption and high performance.

The carrier concentration of the oxide semiconductor 230b is preferably higher than the carrier concentration of the oxide semiconductor 230c. Increasing the carrier concentration of the oxide semiconductor 230b results in higher conductivity thereof, which enables the transistor to have a high on-state current. When the carrier concentration of the oxide semiconductor 230c is reduced, the conductivity is reduced, and thus the transistor can have normally-off characteristics.

Although the example in which a material having higher conductivity than a material for the oxide semiconductor 230c is used for the oxide semiconductor 230b is described here, one embodiment of the present invention is not limited thereto. A material having lower conductivity than a material for the oxide semiconductor 230c may be used for the oxide semiconductor 230b. The carrier concentration of the oxide semiconductor 230b may be lower than the carrier concentration of the oxide semiconductor 230c.

The band gap of the second metal oxide used for the oxide semiconductor 230b and the band gap of a third metal oxide used for the oxide semiconductor 230c are preferably different from each other. For example, the difference between the band gap of the second metal oxide and the band gap of the third metal oxide is preferably greater than or equal to 0.1 eV, further preferably greater than or equal to 0.2 eV, still further preferably greater than or equal to 0.3 eV.

The band gap of the second metal oxide used for the oxide semiconductor 230b can be smaller than the band gap of the third metal oxide used for the oxide semiconductor 230c. This enables the transistor to have a high on-state current. Furthermore, the transistor 200 can have a high threshold voltage in the case where the transistor 200 is an n-channel transistor; accordingly, the transistor 200 can be a normally-off transistor.

Although the example in which the band gap of the second metal oxide is smaller than the band gap of the third metal oxide is described here, one embodiment of the present invention is not limited thereto. The band gap of the second metal oxide can be larger than the band gap of the third metal oxide.

The first metal oxide used for the oxide semiconductor 230a and the third metal oxide used for the oxide semiconductor 230c may have the same composition or different compositions.

For example, a metal oxide with a composition of In:Ga:Zn=1:1:1 [atomic ratio] or in the neighborhood thereof may be used for the oxide semiconductor 230a, a metal oxide with a composition of In:Zn=1:1 [atomic ratio] or in the neighborhood thereof, a metal oxide with a composition of In:Zn=4:1 [atomic ratio] or in the neighborhood thereof, a metal oxide with a composition of In:Sn:Zn=4:0.1:1 [atomic ratio] or in the neighborhood thereof, or indium oxide may be used for the oxide semiconductor 230b, and a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof may be used for the oxide semiconductor 230c. With this structure, the transistor 200 can have a high on-state current and high reliability with small variations.

As described above, a metal oxide having conductivity is preferably used for each of the conductor 240b and the conductor 220b. Thus, an ohmic contact can be made between the conductor 240b and the oxide semiconductor 230a and between the conductor 220b and the oxide semiconductor 230a. For example, it is preferable that indium tin oxide to which silicon is added be used for each of the conductor 240b and the conductor 220b, and that a metal oxide having a composition of In:Ga:Zn=1:1:1 [atomic ratio] or in the neighborhood thereof, which has relatively high conductivity, be used for the oxide semiconductor 230a. Accordingly, the on-state current, field-effect mobility, and frequency characteristics of the transistor 200 can be improved.

As illustrated in FIG. 3A, the insulator 250 may have a stacked-layer structure of an insulator 250a and an insulator 250b over the insulator 250a. The insulator 250a is provided in contact with the top surface of the oxide semiconductor 230. The insulator 250a includes a region in contact with the top surface of the conductor 240, a region in contact with the side surface of the conductor 240, and a region in contact with the insulator 280. The insulator 250b is provided in contact with the top surface of the insulator 250a.

As the insulator 250a, an insulator having a function of capturing or fixing hydrogen is preferably used. By providing the insulator 250a, hydrogen contained in the oxide semiconductor 230 can be captured or fixed more effectively. Thus, the hydrogen concentration in the oxide semiconductor 230 can be reduced. As the insulator 250a, any of the insulators that can be used as the insulator 222 can be used. For the insulator 250a, for example, hafnium silicate or the like is preferably used. The insulator 250a in that case contains at least hafnium, silicon, and oxygen. The insulator 250a preferably has an amorphous structure. As the insulator 250a, a single layer or stacked layers of any of the insulators described later in the section [Insulator] may be used.

The insulator 250a having an amorphous structure can inhibit formation of a crystal grain boundary. Inhibiting the formation of a crystal grain boundary results in higher film planarity of the insulator 250a. This makes the thickness distribution of the insulator 250a uniform and eliminates an extremely thin portion, so that the withstand voltage of the insulator 250a can be improved. In addition, the thickness distribution of a film provided over the insulator 250a can be uniform.

Moreover, inhibiting the formation of a crystal grain boundary in the insulator 250a can reduce leakage current due to the defect states in the crystal grain boundary. Thus, the insulator 250a can function as an insulating film with little leakage current.

Since hafnium oxide is a high dielectric constant (high-k) material, hafnium silicate becomes a high dielectric constant (high-k) material depending on the silicon content. Accordingly, in the case where the insulator 250a is used as a gate insulator, a gate potential applied during the operation of the transistor can be reduced while the physical thickness of the gate insulator is maintained. In addition, the equivalent oxide thickness (EOT) of the insulator functioning as the gate insulator can be reduced.

The thickness of the insulator 250 a is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. The insulator 250a at least partly includes a region with the above-described thickness. Here, since the insulator 250a has an amorphous structure, formation of a crystal grain boundary is inhibited and the planarity is high. Thus, the insulator 250a can be a thin film with a high withstand voltage and a lowered leakage current. Accordingly, the insulator 250a is suitable as a gate insulator.

As the insulator 250b, a barrier insulator against hydrogen is preferably used. Thus, diffusion of impurities contained in the conductor 260 into the oxide semiconductor 230 can be inhibited. As the insulator 250b, any of the insulators that can be used as the insulator 210 and the insulator 283 can be used. For example, silicon nitride is suitable for the insulator 250b because of its high barrier property against hydrogen. The insulator 250b in that case contains at least nitrogen and silicon. As the insulator 250b, a single layer or stacked layers of any of the insulators described later in the section [Insulator] may be used.

In the case where silicon nitride is used for the insulator 250b, the thickness of the insulator 250 b is preferably greater than or equal to 2 nm, further preferably greater than or equal to 3 nm. Although there is no particular limitation on the upper limit of the thickness of the insulator 250b, for scaling down or high integration of the semiconductor device, increased productivity of the semiconductor device, and the like, the thickness of the insulator 250b is preferably less than or equal to 20 nm, less than or equal to 10 nm, or less than or equal to 5 nm. Thus, the insulator 250b preferably includes a region where the thickness is greater than or equal to 2 nm and less than or equal to 10 nm, further preferably includes a region where the thickness is greater than or equal to 2 nm and less than or equal to 5 nm. The insulator 250 b preferably includes a region where the thickness is greater than or equal to 3 nm and less than or equal to 10 nm, further preferably includes a region where the thickness is greater than or equal to 3 nm and less than or equal to 5 nm.

In the case where the insulator 250b has a barrier property against hydrogen, the insulator 250b also has a barrier property against oxygen. Furthermore, the insulator 250b includes a region in contact with the conductor 260. Thus, the insulator 250b having a barrier property against oxygen can inhibit diffusion of oxygen contained in the oxide semiconductor 230 or the insulator 250a into the conductor 260, and accordingly can inhibit oxidation of the conductor 260. In addition, formation of oxygen vacancies in the oxide semiconductor 230, which is due to diffusion of oxygen contained in the oxide semiconductor 230 into the conductor 260, can be inhibited.

As the conductor 260, a single layer or stacked layers of any of the conductors described later in the section [Conductor] can be used. For example, a conductive material with high conductivity such as tungsten can be used for the conductor 260.

In addition, a conductive material that is less likely to be oxidized, a conductive material having a function of inhibiting diffusion of oxygen, or the like is preferably used for the conductor 260. Examples of the conductive material include a conductive material containing nitrogen (e.g., titanium nitride or tantalum nitride) and a conductive material containing oxygen (e.g., ruthenium oxide). Thus, a decrease in the conductivity of the conductor 260 can be inhibited.

Although FIG. 1B and FIG. 1C illustrate the conductor 260 being a single layer, the present invention is not limited thereto. The conductor 260 may have a stacked-layer structure. For example, as illustrated in FIG. 3A, the conductor 260 may have a stacked-layer structure of a conductor 260a and a conductor 260b over the conductor 260a. In that case, titanium nitride may be used for the conductor 260a, and tungsten may be used for the conductor 260b, for example. When a layer containing tungsten is provided in this manner, the conductor 260 can have improved conductivity and can serve well as a wiring.

Although FIG. 3A illustrates the structure in which the conductor 260 has the stacked-layer structure of the two layers of the conductor 260a and the conductor 260b, the present invention is not limited thereto. The conductor 260 may have a stacked-layer structure of three or more layers.

As the insulator 283, a barrier insulator against hydrogen is preferably used. This can inhibit diffusion of hydrogen from above the insulator 283 into the oxide semiconductor 230. A silicon nitride film and a silicon nitride oxide film can be suitably used for the insulator 283 because they release fewer impurities (e.g., water and hydrogen) and are less likely to transmit oxygen and hydrogen.

Silicon nitride formed by a sputtering method is particularly preferably used for the insulator 283. In that case, the insulator 283 contains silicon and nitrogen. Since a sputtering method does not need to use a molecule containing hydrogen in a film formation gas, the hydrogen concentration in the insulator 283 can be reduced. When the insulator 283 is formed by a sputtering method, high-density silicon nitride can be formed.

As illustrated in FIG. 3A, the insulator 283 may have a stacked-layer structure of an insulator 283a and an insulator 283b over the insulator 283a. An insulator having a function of capturing hydrogen or fixing hydrogen is preferably used as the insulator 283a, and any of the insulators that can be used as the insulator 222 is used as appropriate. For example, hafnium silicate is used for the insulator 283a. As the insulator 283b, the above-described barrier insulator against hydrogen is preferably used. That is, the insulator 283 has a stacked-layer structure of the insulator 283a having a function of capturing hydrogen or fixing hydrogen and the insulator 283b that is the barrier insulator against hydrogen.

This structure can inhibit diffusion of hydrogen into the oxide semiconductor 230 from above the insulator 283. The insulator 283a and the insulator 222 each having a function of capturing hydrogen or fixing hydrogen are provided in a closed system formed of the insulator 283b and the insulator 210 each having a barrier property against hydrogen; thus, the hydrogen concentration in the oxide semiconductor 230 can be reduced.

### <Example of Method for Fabricating Semiconductor Device>

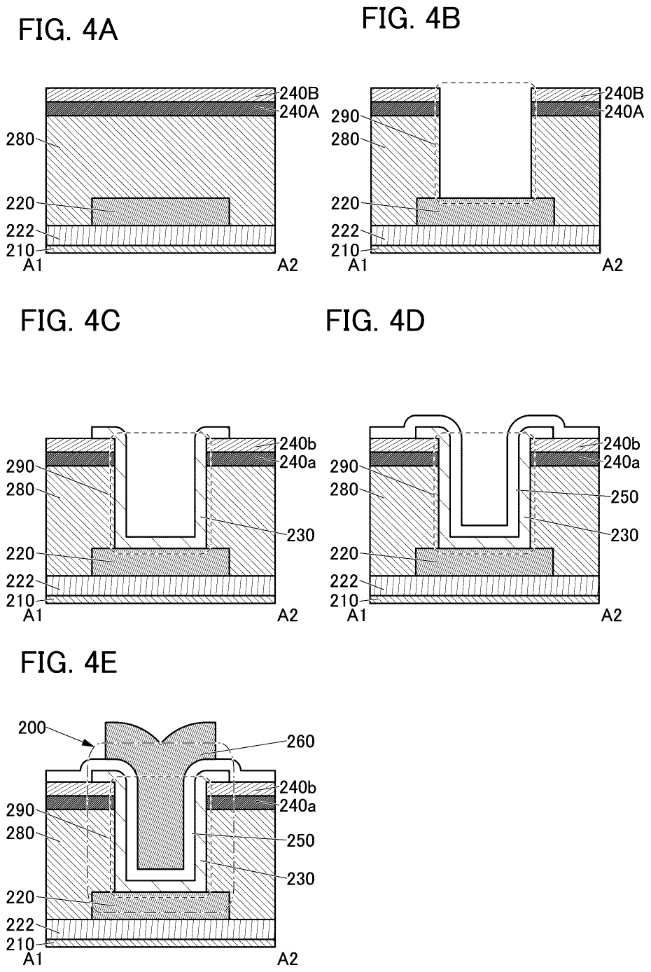

Next, a method for fabricating the transistor 200 illustrated in FIG. 1A to FIG. 1D and the like will be described with reference to FIG. 4A to FIG. 4E. Note that FIG. 4A to FIG. 4E correspond to FIG. 1B.

Hereinafter, a film of an insulating material for forming an insulator, a film of a conductive material for forming a conductor, or a film of a semiconductor material for forming a semiconductor can be formed by a sputtering method, a chemical vapor deposition (CVD) method, a molecular beam epitaxy (MBE) method, a pulsed laser deposition (PLD) method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which voltage applied to an electrode is changed in a pulsed manner. An RF sputtering method is mainly used in the case where an insulating film is formed, and a DC sputtering method is mainly used in the case where a metal conductive film is formed. A pulsed DC sputtering method is mainly used in the case where a film of a compound such as an oxide, a nitride, or a carbide is formed by a reactive sputtering method.

Note that CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving charge from plasma. In that case, accumulated charge may break the wiring, the electrode, the element, or the like included in the semiconductor device. By contrast, such plasma damage is not caused in the case of a thermal CVD method, which does not use plasma, and thus the yield of the semiconductor device can be increased. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, a CVD method and an ALD method are film formation methods that enable good step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a CVD method, in some cases.

By a CVD method, a film with a certain composition can be formed depending on the flow rate ratio of the source gases. For example, by a CVD method, a film whose composition is continuously changed can be formed by changing the flow rate ratio of the source gases during film formation. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By an ALD method, a film with a certain composition can be formed by introducing different kinds of precursors. For example, in the case where different kinds of precursors are introduced, a film with a certain composition can be formed by controlling the number of cycles for each of the precursors.

In the case where a plurality of different kinds of precursors are introduced in an ALD method, the kind of oxidizer may be changed depending on the precursors. For example, in the case where at least a first precursor and a second precursor are introduced, ozone (O₃) may be used as an oxidizer for the first precursor and oxygen (O₂) may be used as an oxidizer for the second precursor.

Heat treatment may be performed before formation of a film. This heat treatment may be performed under reduced pressure, and the film may be successively formed without exposure to the air. Such treatment can remove moisture and hydrogen adsorbed onto the surface over which the film is to be formed, and further can reduce the moisture concentration and the hydrogen concentration in a structure body that serves as the surface over which the film is to be formed. The heat treatment temperature is preferably higher than or equal to 100 ° C and lower than or equal to 600 ° C.

First, a substrate (not illustrated) is prepared, and the insulator 210 is formed over the substrate (see FIG. 4A). The insulator 210 is formed by a sputtering method, a CVD method, an MBE method, a PLD method, an ALD method, or the like as appropriate. For example, a silicon nitride film can be formed by a sputtering method as the insulator 210.

Next, the insulator 222 is formed over the insulator 210 (see FIG. 4A). The insulator 222 is formed by a sputtering method, a CVD method, an MBE method, a PLD method, an ALD method, or the like as appropriate. For example, a hafnium silicate film can be formed by a sputtering method as the insulator 222. In that case, a film formation target containing hafnium and silicon, or the like is used. For example, a co-sputtering method using a silicon oxide target and a hafnium oxide target is employed. The insulator 222 may be formed by a thermal ALD method. For example, hafnium tetrachloride and silicon tetrachloride are used as precursors. For another example, a hafnium silicate film may be formed in the following manner: a hafnium oxide film is formed and then silicon is added to the hafnium oxide film. As a method for adding silicon, for example, an ion implantation method in which a source gas is ionized and the ion is subjected to mass separation and then added, an ion doping method in which a source gas is ionized and the ion is added without mass separation, or the like can be employed.

Next, the conductor 220 is formed over the insulator 222 (see FIG. 4A). The conductor 220 can be formed in the following manner: a conductive film is formed over the insulator 222 and the conductive film is patterned by a lithography method. The conductive film is formed by a sputtering method, a CVD method, an MBE method, a PLD method, an ALD method, or the like as appropriate. As the conductive film, for example, a tungsten film can be formed by a sputtering method and an ITSO film can be formed thereover by a sputtering method.

Next, the insulator 280 is formed over the insulator 222 and the conductor 220 (see FIG. 4A). Any of the above-described insulating materials is used for the insulator 280 as appropriate. The insulator 280 is formed by a sputtering method, a CVD method, an MBE method, a PLD method, an ALD method, or the like as appropriate. A silicon nitride film can be formed by a sputtering method as the insulator 280, for example. The top surface of the formed insulator 280 is preferably planarized by chemical mechanical polishing (CMP) treatment. The planarization treatment for the insulator 280 enables favorable formation of the conductor 240 functioning as a wiring.

The CMP treatment may be skipped in some cases. In that case, the top surface of the insulator 280 has an upward-convex curved shape. By not performing planarization treatment, manufacturing cost can be reduced and production yield can be increased.

By using a sputtering method that does not necessarily use a molecule containing hydrogen in a film formation gas for formation of the insulator 280, the hydrogen concentration in the insulator 280 can be reduced. When the insulator 280 is formed in this manner, diffusion of hydrogen from the insulator 280 into the oxide semiconductor 230 can be reduced, and oxygen vacancies and VoH in the channel formation region can be reduced.

Next, a conductive film 240A is formed over the insulator 280, and a conductive film 240B is formed over the conductive film 240A (see FIG. 4A). Any of the above-described conductive materials is used as appropriate for the conductive film 240A and the conductive film 240B. The conductive film 240A and the conductive film 240B are each formed by a sputtering method, a CVD method, an MBE method, a PLD method, an ALD method, or the like as appropriate. As the conductive film 240A, for example, a ruthenium film can be formed by a sputtering method. As the conductive film 240B, an ITSO film can be formed by a sputtering method.

Then, part of the conductive film 240A, part of the conductive film 240B, and part of the insulator 280 are processed to form the opening portion 290 reaching the conductor 220 (see FIG. 4B). The opening portion 290 is formed by a lithography method.

### [Example of Method for Forming Opening Portion]

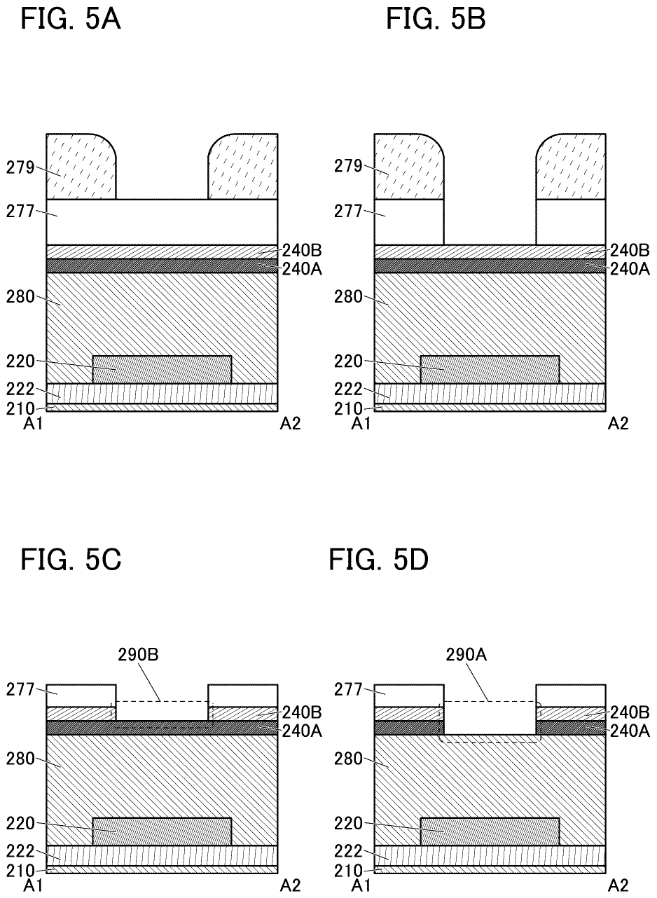

An example of a method for forming the opening portion 290 will be described below with reference to FIG. 5A to FIG. 5D.

First, a coating film 277 is formed over the conductive film 240B (see FIG. 5A). The coating film 277 is formed by a spin coating method or the like, for example. For the coating film 277, a non-photosensitive organic resin is used. The coating film 277 preferably contains silicon. In this embodiment, an SOG (Spin On Glass) film is formed as the coating film 277.

Note that the coating film 277 contains an organic solvent such as alcohol at the time of coating, but such an organic substance contained may be reduced or removed in later steps or at the time of completion of a semiconductor device. The coating film is provided as necessary, and coating films may be stacked. For example, an SOG film may be stacked over an SOC (Spin On Carbon) film. Furthermore, a coating film for improving the adhesion between the SOC film and the formation surface may be provided below the SOC film. A coating film is not necessarily provided in the case where a resist mask described later sufficiently works.

Subsequently, a resist mask 279 is formed over the coating film 277 by a lithography method (see FIG. 5A). A photosensitive organic resin, which is also called a photoresist, is used for the resist mask 279. An organic resin having photosensitivity to an electron beam can also be used. For example, a positive photoresist or a negative photoresist can be used. The photoresist to be the resist mask 279 can be formed by a spin coating method or the like, for example, to have a uniform thickness.

In the lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask can be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that the use of a mask may be unnecessary in the case of using an electron beam or an ion beam.

In the following steps, etching treatment for forming the opening portion 290 is performed by a dry etching method. A dry etching method enables anisotropic etching and thus is suitable for forming the opening portion 290 with a high aspect ratio.

Here, as an etching gas for the dry etching treatment, an etching gas containing a halogen can be used, and specifically, an etching gas containing one or more of fluorine, chlorine, and bromine can be used. As the etching gas, for example, a C₄F₆ gas, a CsF₆ gas, a C₄F₈ gas, a CF₄ gas, a SF₆ gas, a CHF₃ gas, a CH₂F₂ gas, a CH₃F gas, a Cl₂ gas, a BCl₃ gas, a SiCl₄ gas, a CCl₄ gas, a HBr gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. Depending on an object to be subjected to the dry etching treatment, a gas that contains a hydrocarbon gas or a hydrogen gas and does not contain a halogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (c₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes can have a structure in which a high-frequency voltage is applied to one of the parallel plate electrodes. Alternatively, a structure can be employed in which high-frequency voltages with the same frequency are applied to the parallel plate electrodes. Alternatively, a structure can be employed in which different high-frequency voltages are applied to the parallel plate electrodes. Such a CCP etching apparatus is referred to as a dual frequency capacitively coupled plasma (DF-CCP) etching apparatus. In the DF-CCP etching apparatus, a structure can be employed in which high-frequency voltages with different frequencies are applied to the parallel plate electrodes. Alternatively, a structure can be employed in which different high-frequency voltages are applied to one of the parallel plate electrodes. Alternatively, a dry etching apparatus including a high-density plasma source can be used. As the dry etching apparatus including a high-density plasma source, an inductively coupled plasma (ICP) etching apparatus or the like can be used, for example. The etching apparatus can be set as appropriate depending on an object to be etched. Note that in the above dry etching apparatus, a high-frequency voltage is applied to the electrode on the substrate side to generate a self-bias potential, whereby reactive ion etching can be performed. In reactive ion etching, ion species in plasma are accelerated to collide with an object to be processed, whereby etching with high anisotropy can be performed.

Note that the following steps of forming the opening portion 290 are preferably performed successively without exposure to the air. For example, processing is performed without exposure to the air by using a multi-chamber etching apparatus.

First, the coating film 277 is processed using the resist mask 279, so that an opening corresponding to the opening portion 290 is formed in the coating film 277 (see FIG. 5B). In the case where an SOG film is used as the coating film 277, for example, the processing can be performed with a DF-CCP etching apparatus using CHF₃ and an oxygen gas as etching gases.

The resist mask 279 is preferably removed after the processing of the coating film 277. The resist mask 279 can be removed by dry etching treatment such as ashing, wet etching treatment, wet etching treatment after dry etching treatment, or dry etching treatment after wet etching treatment, for example.

Next, the conductive film 240B is processed using the coating film 277 as a mask, so that an opening portion 290B corresponding to the opening portion 290 is formed in the conductive film 240B (see FIG. 5C). In the case where an ITSO film is used as the conductive film 240B, for example, the processing can be performed with a DF-CCP etching apparatus using CH₄ and an argon gas as etching gases.

Next, the conductive film 240A is processed using the coating film 277 as a mask, so that an opening portion 290A corresponding to the opening portion 290 is formed in the conductive film 240A and the conductive film 240B (see FIG. 5D). In the case where a ruthenium film is used as the conductive film 240A, for example, the processing can be performed with an ICP etching apparatus using Cl₂ and an oxygen gas as etching gases.

Next, the insulator 280 is processed using the coating film 277 as a mask, so that the opening portion 290 is formed in the insulator 280, the conductive film 240A, and the conductive film 240B (see FIG. 4B). In the case where a silicon nitride film is used as the insulator 280, for example, the processing can be performed with a DF-CCP etching apparatus using CH₂F₂, CHF₃, CF₄, an oxygen gas, and an argon gas as etching gases.

Here, the coating film 277 is sometimes also removed during the processing of the insulator 280. In that case, the conductive film 240A and the conductive film 240B are exposed to dry etching treatment. Thus, at least one of the conductive film 240A and the conductive film 240B, e.g., the conductive film 240A, preferably functions as a hard mask during the processing of the insulator 280. In this embodiment, the use of ruthenium for the conductive film 240A enables the conductive film 240A to function as a hard mask during the processing of the insulator 280.

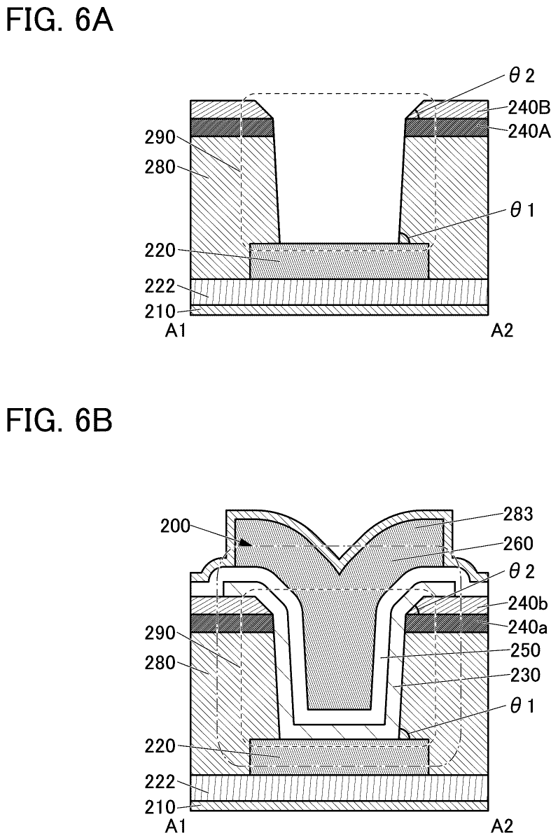

In the above manner, the side surface of the insulator 280 that is part of the sidewall of the opening portion 290 can be perpendicular or substantially perpendicular to the top surface of the insulator 222 as illustrated in FIG. 6A. The angle θ1 corresponding to the taper angle of the insulator 280 can be greater than or equal to 75° and less than or equal to 90°. Such a structure can prevent the opening portion 290 of the transistor 200 from being excessively large, leading to a reduction in the occupation area. Thus, scaling down and high integration of the semiconductor device can be achieved.

At this time, the side surface of the conductive film 240B may have a tapered shape as illustrated in FIG. 6A. When a taper angle formed by the side surface of the conductive film 240B and the top surface of the conductive film 240A (which may be the top surface of the insulator 222 or the top surface of the insulator 210) is an angle θ2, the angle θ2 is smaller than the angle θ1. The transistor 200 having the opening portion 290 with the shape in FIG. 6A is as illustrated in FIG. 6B. In that case, the oxide semiconductor 230, the insulator 250, and the conductor 260 reflect the angle θ2 corresponding to the taper angle of the side surface of the conductor 240b.

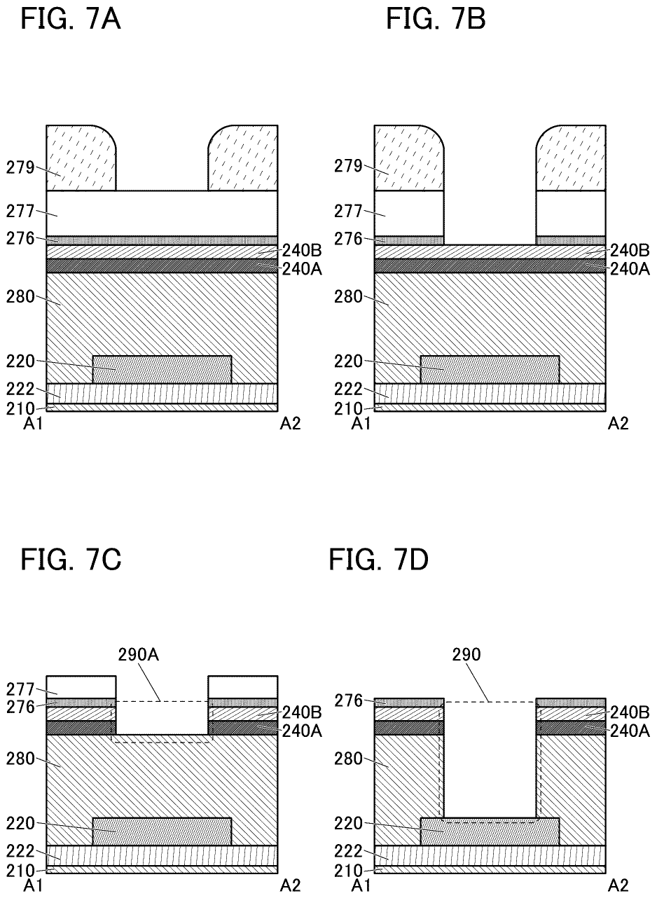

The method for forming the opening portion 290 is not limited to the above-described method. For example, a method illustrated in FIG. 7A to FIG. 7D may be employed. The method illustrated in FIG. 7A to FIG. 7D is different from the method illustrated in FIG. 5A to FIG. 5D in that an inorganic film functioning as a hard mask is provided between the conductive film 240B and the coating film 277. Another example of the method for forming the opening portion 290 will be described below with reference to FIG. 7A to FIG. 7D.

First, an inorganic film 276 is formed over the conductive film 240B (see FIG. 7A). The inorganic film 276 can be formed by a sputtering method, a CVD method, an MBE method, a PLD method, an ALD method, or the like. The inorganic film 276 functions as a hard mask for forming the opening portion 290 in the insulator 280, the conductive film 240A, and the conductive film 240B in a later step. For the inorganic film 276, a metal material, an inorganic insulating material, or the like that can have etching selectivity at the time of processing the insulator 280, the conductive film 240A, and the conductive film 240B is used. For example, a tungsten film formed by a sputtering method is used as the inorganic film 276. After the formation of the conductive film 240A and the conductive film 240B, the inorganic film 276 may be successively formed without exposure to the air.

Next, the coating film 277 is formed over the inorganic film 276, and the resist mask 279 is formed over the coating film 277. Note that the method for forming the coating film 277 and the resist mask 279 is similar to the method in FIG. 5A; thus, the above description can be referred to.

Next, etching treatment for forming the opening portion 290 is performed by a dry etching method. A dry etching method enables anisotropic etching and thus is suitable for forming the opening portion 290 with a high aspect ratio.

First, the coating film 277 is processed using the resist mask 279, so that an opening corresponding to the opening portion 290 is formed in the coating film 277 (see FIG. 7B). The coating film 277 is processed by a method similar to the method in FIG. 5B.

Next, the inorganic film 276 is processed using the resist mask 279, so that an opening corresponding to the opening portion 290 is formed in the inorganic film 276 (see FIG. 7B). In the case where a tungsten film is used as the inorganic film 276, for example, the processing can be performed with a DF-CCP etching apparatus using Cl₂, CF₄, and an oxygen gas as etching gases.

Then, the conductive film 240B is processed using the inorganic film 276 as a mask, so that an opening corresponding to the opening portion 290 is formed in the conductive film 240B (see FIG. 7C). The conductive film 240B is processed by a method similar to the method in FIG. 5C.

Next, the conductive film 240A is processed using the inorganic film 276 as a mask, so that the opening portion 290A corresponding to the opening portion 290 is formed in the conductive film 240A and the conductive film 240B (see FIG. 7C). The conductive film 240A is processed by a method similar to the method in FIG. 5D.

Next, the insulator 280 is processed using the inorganic film 276 as a mask, so that the opening portion 290 is formed in the insulator 280, the conductive film 240A, and the conductive film 240B (see FIG. 7D). The insulator 280 is processed by a method similar to the above-described method.

Since the inorganic film 276 contains tungsten, the inorganic film 276 is hardly etched in the processing of the conductive film 240B containing ITSO, the processing of the conductive film 240A containing ruthenium, and the processing of the insulator 280 containing silicon nitride, and thus can function as a hard mask.

In the above manner, the side surface of the insulator 280, the side surface of the conductive film 240A, and the side surface of the conductive film 240B each of which is part of the sidewall of the opening portion 290 can be perpendicular or substantially perpendicular to the top surface of the insulator 222 as illustrated in FIG. 7D. Such a structure can prevent the opening portion 290 of the transistor 200 from being excessively large, leading to a reduction in the occupation area. Thus, scaling down and high integration of the semiconductor device can be achieved.

Next, the inorganic film 276 is removed by dry etching treatment (see FIG. 4B). In the case where a tungsten film is used as the inorganic film 276, for example, the processing can be performed with a DF-CCP etching apparatus using Cl₂, CF₄, and an oxygen gas as etching gases. The conductive film 240B contains ITSO and thus is hardly etched in the dry etching treatment of the inorganic film 276 containing tungsten. Note that the inorganic film 276 is not necessarily removed when the material of the inorganic film 276 does not affect later steps or can be utilized in later steps.

Note that the opening portion 290 is not necessarily formed such that the top surface of the conductor 220 is flat. In that case, a depressed portion overlapping with the opening portion 290 is formed on the top surface of the conductor 220, whereby the transistor 200 illustrated in FIG. 3A or FIG. 3B can be formed.

In order to remove impurities and the like attached to the opening portion 290 in the etching step, cleaning treatment is preferably performed. As a cleaning method, wet cleaning using a cleaning solution or the like (which can also be referred to as wet etching treatment) can be employed. Furthermore, the top surface of the conductor 220 can be etched by the wet cleaning to form a depressed portion, which overlaps with the opening portion 290, on the top surface of the conductor 220. In that case, the depressed portion can be included in the opening portion 290. Note that the wet cleaning can be performed not only after the formation of the opening portion 290 but also in the middle of the formation of the opening portion 290.

The wet cleaning may be performed using an aqueous solution in which one or more of oxalic acid, phosphoric acid, and hydrofluoric acid are diluted with carbonated water or pure water. The wet cleaning may be performed using an aqueous solution in which ammonia water is diluted with carbonated water or pure water. The wet cleaning may be performed using pure water, carbonated water, or the like. Alternatively, ultrasonic cleaning using such an aqueous solution, pure water, or carbonated water may be performed. Alternatively, these cleanings may be performed in combination as appropriate. The cleaning treatment may be performed a plurality of times, and the cleaning solution may be changed in every cleaning treatment. For example, the wet cleaning is performed using diluted hydrofluoric acid obtained by diluting hydrofluoric acid with pure water.

Next, microwave treatment may be performed in an oxygen-containing atmosphere to reduce the impurity concentration in the insulator 280. Here, the microwave treatment refers to, for example, treatment using an apparatus including a power source that generates high-density plasma with use of a microwave. In this specification and the like, a microwave refers to an electromagnetic wave having a frequency greater than or equal to 300 MHz and less than or equal to 300 GHz. Specific examples of an impurity include hydrogen and carbon. When the microwave treatment is performed in an oxygen-containing atmosphere, hydrogen contained in the insulator 280 can be released as H₂O to the outside. Release of hydrogen from the insulator 280 positioned in the vicinity of the oxide semiconductor 230 can offer a highly reliable semiconductor device.

The microwave treatment in an oxygen-containing atmosphere can convert an oxygen gas into plasma using a high-frequency wave such as a microwave or RF and can activate the oxygen plasma. When the oxygen plasma acts on the insulator 280 in this manner, hydrogen contained in the insulator 280 can be released as H₂O to the outside. The side surface of the insulator 280 in the opening portion 290 is sometimes oxidized by the oxygen plasma treatment. In that case, the insulator 280 is formed in contact with the oxide semiconductor 230, so that oxygen can be supplied from the insulator 280 to the channel formation region of the oxide semiconductor 230 by heat treatment or the like. Thus, oxygen vacancies and VoH in the channel formation region of the oxide semiconductor 230 can be reduced. Accordingly, the transistor 200 can have stable electrical characteristics and higher reliability. Oxygen that acts on the insulator 280 has a variety of forms such as an oxygen atom, an oxygen molecule, an oxygen ion, and an oxygen radical (also referred to as an O radical, which is an atom, a molecule, or an ion having an unpaired electron). Oxygen that acts on the insulator 280 preferably has any one or more of the above forms, and is particularly suitably an oxygen radical.

The above-described microwave treatment in an oxygen-containing atmosphere is preferably performed while the substrate is heated, in which case the impurity concentration in the insulator 280 can be further reduced. The substrate heating temperature is higher than or equal to 100 ° C and lower than or equal to 650 ° C, preferably higher than or equal to 200 ° C and lower than or equal to 600 ° C, further preferably higher than or equal to 300 ° C and lower than or equal to 450 ° C. The microwave treatment is preferably performed under reduced pressure, and the pressure is preferably higher than or equal to 10 Pa and lower than or equal to 1000 Pa, further preferably higher than or equal to 300 Pa and lower than or equal to 700 Pa.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The impurity concentration in the insulator 280 can be reduced by thus performing the microwave treatment in an oxygen-containing atmosphere. In addition, the carrier concentration in the oxide semiconductor 230 can be prevented from being excessively reduced by preventing an excess amount of oxygen from being introduced into the insulator 280 in the microwave treatment.

Here, the frequency of the microwave treatment apparatus is preferably higher than or equal to 300 MHz and lower than or equal to 300 GHz, further preferably higher than or equal to 2.4 GHz and lower than or equal to 2.5 GHz, and can be set to 2.45 GHz, for example. Oxygen radicals at a high density can be generated with high-density plasma. The electric power of the power source that applies microwaves of the microwave treatment apparatus is preferably set higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the insulator 280 efficiently.

Next, heat treatment may be performed. After the microwave treatment is performed, the heat treatment may be successively performed without exposure to the air. The heat treatment is performed at higher than or equal to 250 ° C and lower than or equal to 650 ° C, preferably higher than or equal to 300 ° C and lower than or equal to 500 ° C, further preferably higher than or equal to 320 ° C and lower than or equal to 450 ° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas can be approximately 20%. The heat treatment may be performed under reduced pressure. Alternatively, heat treatment may be performed in an atmosphere containing an oxidizing gas at 10 ppm or more, 1% or more, or 10% or more after heat treatment is performed in a nitrogen gas or inert gas atmosphere. By the above-described heat treatment, impurities such as water contained in the insulator 280 or the like can be reduced before formation of the later-described oxide semiconductor film to be the oxide semiconductor 230. Note that the heat treatment is preferably performed under the condition where the conductor 220 and the conductor 240 are not excessively oxidized.

The gas used in the above heat treatment is preferably highly purified. For example, the amount of moisture contained in the gas used in the above heat treatment can be less than or equal to 1 ppb, preferably less than or equal to 0.1 ppb, further preferably less than or equal to 0.05 ppb. The heat treatment using a highly purified gas can prevent entry of moisture or the like into the insulator 280 and the like as much as possible.

Although the heat treatment is performed after the microwave treatment in the above description, the present invention is not limited thereto. The microwave treatment may be performed after the heat treatment.

Next, the oxide semiconductor film to be the oxide semiconductor 230 is formed in contact with the top surface of the conductor 220, the side surface of the insulator 280, the side surface of the conductive film 240A, and the top surface and the side surface of the conductive film 240B. For the oxide semiconductor film, any of the metal oxides that can be used for the oxide semiconductor 230 is used as appropriate. The oxide semiconductor film is formed by a sputtering method, a CVD method, an MBE method, a PLD method, an ALD method, or the like as appropriate. Here, the oxide semiconductor film is preferably formed in contact with the top surface of the conductor 220 and the side surface of the insulator 280. Thus, the oxide semiconductor film is preferably formed by a film formation method providing good coverage, and is further preferably formed by a CVD method, an ALD method, or the like. For example, an In—Ga—Zn oxide can be formed by an ALD method as the oxide semiconductor film.

Note that the method for forming the oxide semiconductor film to be the oxide semiconductor 230 is not limited to a CVD method or an ALD method. For example, a sputtering method may be employed. In the case where the oxide semiconductor 230 has a stacked-layer structure as illustrated in FIG. 3A or FIG. 3B, the layers included in the oxide semiconductor 230 may be formed by the same method or different methods.

Here, the oxide semiconductor film to be the oxide semiconductor 230 is preferably formed in contact with the top surface of the conductor 220 in the opening portion 290, the side surface of the insulator 280 in the opening portion 290, the side surface of the conductive film 240A, and the top surface and the side surface of the conductive film 240B. When the oxide semiconductor film is formed in contact with the conductor 220, the conductor 220 functions as one of a source electrode and a drain electrode of the transistor 200. When the oxide semiconductor film is formed in contact with the conductive film 240A and the conductive film 240B, the conductor 240 functions as the other of the source electrode and the drain electrode of the transistor 200.

The microwave treatment and the heat treatment may be performed after the formation of the oxide semiconductor film.

Next, the oxide semiconductor film to be the oxide semiconductor 230 is processed by a lithography method to form the oxide semiconductor 230 (see FIG. 4C). Accordingly, part of the oxide semiconductor 230 is formed in the opening portion 290. For the processing of the oxide semiconductor 230, a dry etching method or a wet etching method can be employed. Processing by a dry etching method is suitable for microfabrication.

Next, the conductive film 240A and the conductive film 240B are processed to form the conductor 240a and the conductor 240b (see FIG. 4C). The conductor 240a and the conductor 240b are formed by a lithography method. For the processing of the conductive film 240A and the conductive film 240B, a dry etching method or a wet etching method can be employed. Processing by a dry etching method is suitable for microfabrication.

Next, the insulator 250 is formed over the oxide semiconductor 230, the conductor 240a, the conductor 240b, and the insulator 280 (see FIG. 4D). Any of the above-described insulating materials is used for the insulator 250 as appropriate. The insulator 250 is formed by a sputtering method, a CVD method, an MBE method, a PLD method, an ALD method, or the like as appropriate. The insulator 250 is preferably formed in contact with the oxide semiconductor 230 provided in the opening portion 290. Thus, the insulator 250 is preferably formed by a film formation method providing good coverage, and is further preferably formed by a CVD method, an ALD method, or the like. For example, a silicon oxide film can be formed as the insulator 250 by a PEALD method. Note that the method for forming the insulator 250 is not limited to a CVD method or an ALD method. For example, a sputtering method may be employed.

As illustrated in FIG. 3A and FIG. 3B, the insulator 250 can have a stacked-layer structure of the insulator 250a and the insulator 250b. As the insulator 250a, for example, a hafnium silicate film can be formed by a thermal ALD method. As the insulator 250b, for example, a silicon nitride film can be formed by a PEALD method.

When the insulator 250 is formed after the formation of the oxide semiconductor 230, the side end portion of the oxide semiconductor 230 is covered with the insulator 250. Thus, a short circuit between the oxide semiconductor 230 and the conductor 260 can be prevented. Furthermore, in the above-described structure, the side end portion of the conductor 240 is covered with the insulator 250. Thus, a short circuit between the conductor 240 and the conductor 260 can be prevented.

The microwave treatment and the heat treatment may be performed after the formation of the insulator 250. In the case where silicon nitride is used for the insulator 210 and the insulator 250b and hafnium silicate is used for the insulator 222 and the insulator 250a, the heat treatment can be performed in a state where the insulator 222 and the insulator 250a are provided in a closed system formed of the insulator 210 and the insulator 250b. This enables the insulator 222 and the insulator 250a to capture or fix hydrogen in the closed system. Thus, the hydrogen concentration in the channel formation region of the oxide semiconductor 230 can be reduced. Accordingly, the transistor can have excellent electrical characteristics and higher reliability. Moreover, the semiconductor device can have a small variation in electrical characteristics of transistors.

Furthermore, the microwave treatment can remove impurities such as carbon in the oxide semiconductor 230. With the removal of carbon, which is an impurity in the oxide semiconductor 230, the crystallinity of the oxide semiconductor 230 can be improved. Accordingly, the oxide semiconductor 230 can be a CAAC-OS. Particularly in the case where the oxide semiconductor 230 is formed by an ALD method, carbon included in a precursor is sometimes taken into the oxide semiconductor 230; thus, carbon is preferably removed by the microwave treatment.

In the case where the insulator 250 has a stacked-layer structure, the microwave treatment is not always performed after all the insulators included in the insulator 250 are formed. For example, in the case of the structure illustrated in FIG. 3A or FIG. 3B, microwave treatment may be performed after the insulator 250a is formed, and then the insulator 250b may be formed. For another example, the steps may be performed in the following order: formation of the insulator 250a, microwave treatment, formation of the insulator 250b, and microwave treatment. In this manner, the microwave treatment in an oxygen-containing atmosphere may be performed multiple times.

Next, a conductive film to be the conductor 260 is formed to fill the depressed portion of the insulator 250. Any of the above-described conductive materials is used for the conductive film as appropriate. The conductive film is formed by a sputtering method, a CVD method, an MBE method, a PLD method, an ALD method, or the like as appropriate. Here, the conductive film is preferably formed in contact with the insulator 250 provided in the opening portion 290. Thus, the conductive film is preferably formed by a film formation method providing good coverage or a good filling property, and is further preferably formed by a CVD method, an ALD method, or the like. For example, as the conductive film, a titanium nitride film can be formed by a CVD method or an ALD method and a tungsten film can be formed over the titanium nitride film by a CVD method.

Although the conductive film to be the conductor 260 is provided to fill the opening portion 290 in the above description, the present invention is not limited thereto. For example, a depressed portion reflecting the shape of the opening portion 290 is formed in a center portion of the conductive film in some cases. The depressed portion may be filled with an inorganic insulating material or the like.

Next, the conductive film to be the conductor 260 is processed to form the conductor 260 (see FIG. 4E). The conductor 260 is formed by a lithography method. A dry etching method or a wet etching method can be used for the processing. Processing by a dry etching method is suitable for microfabrication.

Next, the insulator 283 is formed to cover the conductor 260 and the insulator 250. Any of the above-described insulating materials is used for the insulator 283 as appropriate. The insulator 283 is formed by a sputtering method, a CVD method, an MBE method, a PLD method, an ALD method, or the like as appropriate. As illustrated in FIG. 3B, the insulator 283 may have a stacked-layer structure of the insulator 283a and the insulator 283b.

The microwave treatment and the heat treatment may be performed after the formation of the insulator 283. In the case where silicon nitride is used for the insulator 210 and the insulator 283b and hafnium silicate is used for the insulator 222 and the insulator 283a, the heat treatment can be performed in a state where the insulator 222 and the insulator 283a are provided in a closed system formed of the insulator 210 and the insulator 283b. This enables the insulator 222 and the insulator 283a to capture or fix hydrogen in the closed system. Thus, the hydrogen concentration in the channel formation region of the oxide semiconductor 230 can be reduced. Accordingly, the transistor can have excellent electrical characteristics and higher reliability. Moreover, the semiconductor device can have a small variation in electrical characteristics of transistors.

Through the above process, the transistor 200 illustrated in FIG. 1A to FIG. 1D and the like can be fabricated.

### <Variation Example of Semiconductor Device>

Although FIG. 1 illustrates the structure in which the insulator 280 and the oxide semiconductor 230 are in contact with each other in the opening portion 290, the present invention is not limited thereto. For example, an insulator having a function of capturing or fixing hydrogen may be provided between the insulator 280 and the oxide semiconductor 230.

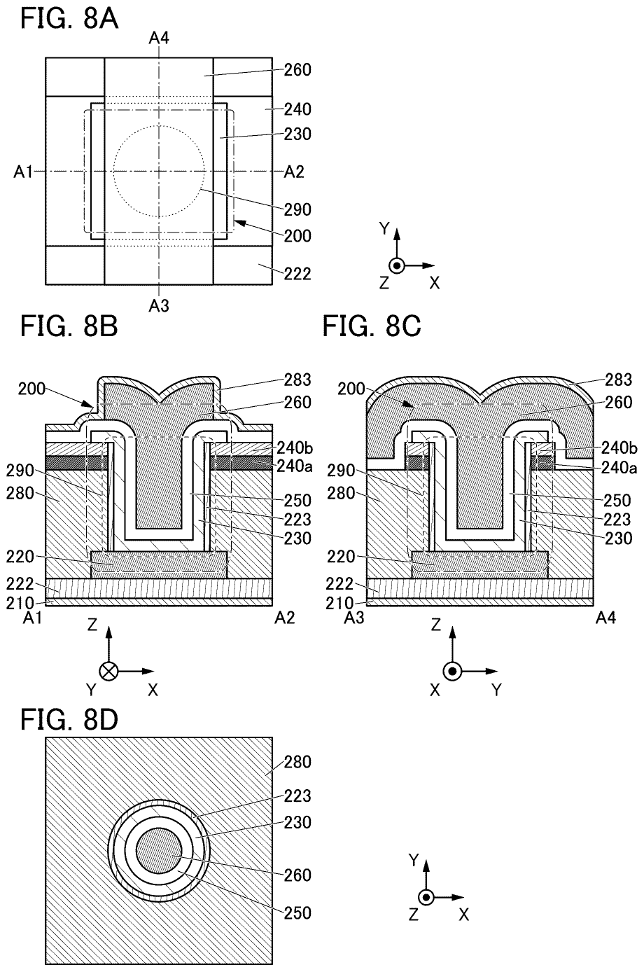

FIG. 8A to FIG. 8D illustrate another example of the semiconductor device of one embodiment of the present invention. FIG. 8A is a plan view of the semiconductor device. FIG. 8B to FIG. 8D are cross-sectional views of the semiconductor device. Here, FIG. 8B is a cross-sectional view of a portion indicated by the dashed-dotted line A1-A2 in FIG. 8A. FIG. 8C is a cross-sectional view of a portion indicated by the dashed-dotted line A3-A4 in FIG. 8A. FIG. 8D is a cross-sectional view along the XY plane including the insulator 280. Note that for clarity of the drawing, some components are not illustrated in the plan view of FIG. 8A.

The semiconductor device illustrated in FIG. 8A to FIG. 8D is different from the semiconductor device illustrated in FIG. 1A to FIG. 1D in including an insulator 223. Differences from the description with reference to FIG. 1A to FIG. 1D are mainly described below; the description is referred to for the same portions, and the description of the same portions is omitted in some cases.

As illustrated in FIG. 8B to FIG. 8D, the insulator 223 is provided between the insulator 280 and the oxide semiconductor 230. Portions of the insulator 223, the oxide semiconductor 230, the insulator 250, and the conductor 260 that are positioned in the opening portion 290 reflect the shape of the opening portion 290. Thus, the insulator 223 is provided to cover the sidewall of the opening portion 290, the oxide semiconductor 230 is provided to cover the side surface of the insulator 223 and the bottom portion of the opening portion 290, the insulator 250 is provided to cover the oxide semiconductor 230, and the conductor 260 is provided to fill the depressed portion of the insulator 250 that reflects the shape of the opening portion 290.

The semiconductor device illustrated in FIG. 8A to FIG. 8D has a structure in which the insulator 223, the oxide semiconductor 230, the insulator 250, and the conductor 260 are provided in this order in the opening portion of the insulator 280.

As the insulator 223, an insulator having a function of capturing or fixing hydrogen is preferably used. As the insulator 223, any of the insulators that can be used as the insulator 222 can be used. For example, hafnium silicate is used. Thus, the oxide semiconductor 230 can be sandwiched between insulators having a function of capturing or fixing hydrogen (here, the insulator 250a and the insulator 223), and a barrier insulator against hydrogen (here, the insulator 280) can be located outward from these components. With this structure, diffusion of hydrogen into the oxide semiconductor 230 can be inhibited and the hydrogen concentration in the oxide semiconductor 230 can be further reduced.

The thickness of the insulator 223 (e.g., the width of the insulator 223 in the A1-A2 direction) is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulator 223 includes a region with the above-described width.

FIG. 8A to FIG. 8D illustrate a structure in which the insulator 223 is provided between the insulator 280 and the oxide semiconductor 230. However, without limitation to this structure, the insulator 223 can be provided in contact with the oxide semiconductor 230 or can be provided in the vicinity of the oxide semiconductor 230.

Although FIG. 8A to FIG. 8D illustrate the structure in which the insulator 223 is provided between the insulator 280 and the oxide semiconductor 230, the present invention is not limited thereto. For example, an insulator having a function of capturing or fixing hydrogen and a barrier insulator against hydrogen may be provided between the insulator 280 and the oxide semiconductor 230.

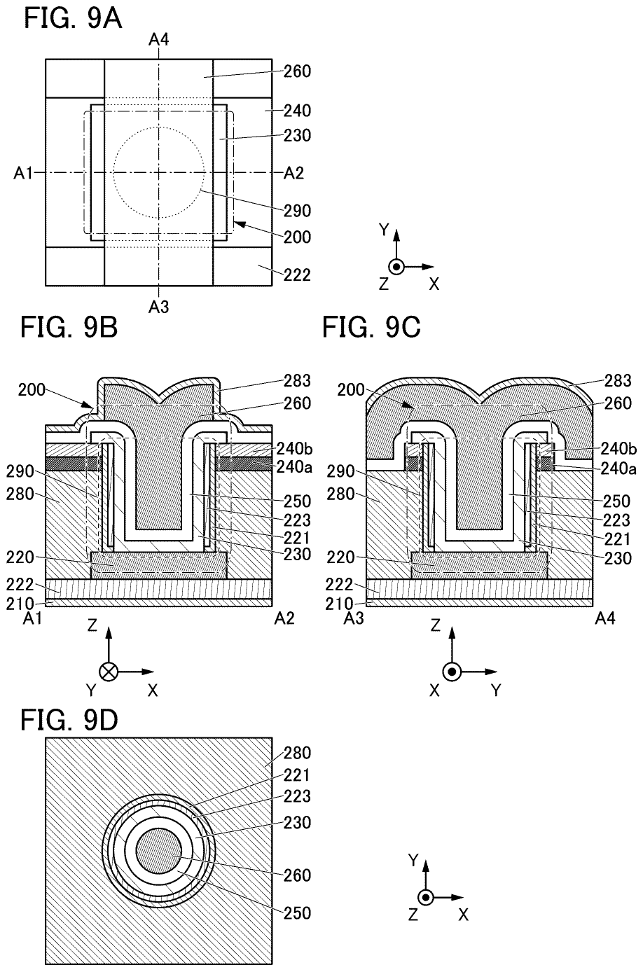

FIG. 9A to FIG. 9D illustrate another example of the semiconductor device of one embodiment of the present invention. FIG. 9A is a plan view of the semiconductor device. FIG. 9B to FIG. 9D are cross-sectional views of the semiconductor device. Here, FIG. 9B is a cross-sectional view of a portion indicated by the dashed-dotted line A1-A2 in FIG. 9A. FIG. 9C is a cross-sectional view of a portion indicated by the dashed-dotted line A3-A4 in FIG. 9A. FIG. 9D is a cross-sectional view along the XY plane including the insulator 280. Note that for clarity of the drawing, some components are not illustrated in the plan view of FIG. 9A.

The semiconductor device illustrated in FIG. 9A to FIG. 9D is different from the semiconductor device illustrated in FIG. 8A to FIG. 8D in including an insulator 221. The semiconductor device illustrated in FIG. 9A to FIG. 9D is different from the semiconductor device illustrated in FIG. 1A to FIG. 1D in including the insulator 221 and the insulator 223. Differences from the description with reference to FIG. 1A to FIG. 1D or FIG. 8A to FIG. 8D are mainly described below; the description is referred to for the same portions, and the description of the same portions is omitted in some cases.

As illustrated in FIG. 9B to FIG. 9D, the insulator 221 is provided between the insulator 280 and the insulator 223. Portions of the insulator 221, the insulator 223, the oxide semiconductor 230, the insulator 250, and the conductor 260 that are positioned in the opening portion 290 reflect the shape of the opening portion 290. Thus, the insulator 221 is provided to cover the sidewall of the opening portion 290, the insulator 223 is provided to cover the side surface of the insulator 221, the oxide semiconductor 230 is provided to cover the side surface of the insulator 223 and the bottom portion of the opening portion 290, the insulator 250 is provided to cover the oxide semiconductor 230, and the conductor 260 is provided to fill the depressed portion of the insulator 250 that reflects the shape of the opening portion 290.

As the insulator 221, a barrier insulator against hydrogen is preferably used. As the insulator 221, any of the insulators that can be used as the insulator 210 can be used. For example, silicon nitride is used. Thus, the oxide semiconductor 230 can be sandwiched between insulators having a function of capturing or fixing hydrogen (here, the insulator 250a and the insulator 223), and a barrier insulator against hydrogen (here, the insulator 221) can be located outward from these components. With this structure, diffusion of hydrogen into the oxide semiconductor 230 can be inhibited and the hydrogen concentration in the oxide semiconductor 230 can be further reduced.

In the case where silicon nitride is used for the insulator 221, the thickness of the insulator 221 (e.g., the width of the insulator 221 in the A1-A2 direction) is preferably greater than or equal to 2 nm, further preferably greater than or equal to 3 nm. Although there is no particular limitation on the upper limit of the thickness of the insulator 221, for scaling down or high integration of the semiconductor device, increased productivity of the semiconductor device, and the like, the thickness of the insulator 221 is preferably less than or equal to 20 nm, less than or equal to 10 nm, or less than or equal to 5 nm. Thus, the insulator 221 preferably includes a region where the thickness is greater than or equal to 2 nm and less than or equal to 10 nm, further preferably includes a region where the thickness is greater than or equal to 2 nm and less than or equal to 5 nm. The insulator 221 preferably includes a region where the thickness is greater than or equal to 3 nm and less than or equal to 10 nm, further preferably includes a region where the thickness is greater than or equal to 3 nm and less than or equal to 5 nm.

Note that the insulator 221 has a barrier property against hydrogen in the structure illustrated in FIG. 9A to FIG. 9D; thus, a material used for the insulator 280 is not limited to a material that has a barrier property against hydrogen. For example, the insulator 280 may be formed using a material with a low relative dielectric constant. The insulator 280 formed using a material with a low relative dielectric constant can function as an interlayer film. Thus, the parasitic capacitance generated between wirings can be reduced.

Although FIG. 9B to FIG. 9D illustrate the insulator 280 being a single layer, the present invention is not limited thereto. The insulator 280 may have a stacked-layer structure.

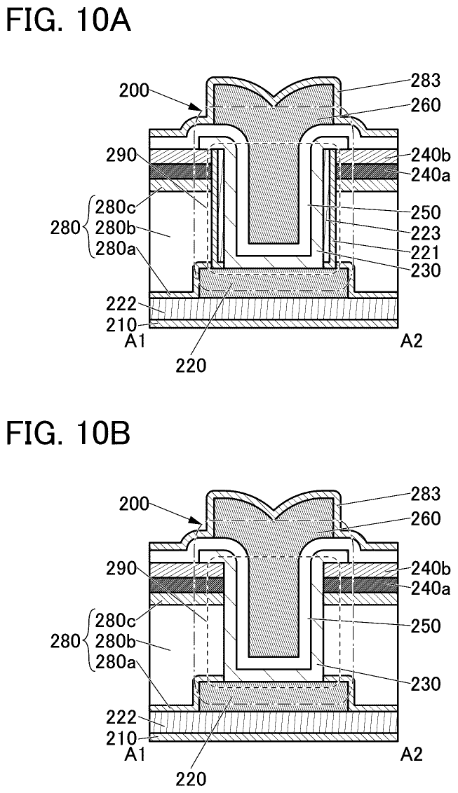

For example, as illustrated in FIG. 10A, the insulator 280 may have a stacked-layer structure of an insulator 280a, an insulator 280b over the insulator 280a, and an insulator 280c over the insulator 280b.

The insulator 280a includes a region in contact with the top surface of the insulator 222, a region in contact with the side surface of the conductor 220, and a region in contact with the top surface of the conductor 220. The insulator 280c includes a region in contact with the bottom surface of the conductor 240.

The insulator 221 having a barrier property against hydrogen is provided between the insulator 280 and the insulator 223 in FIG. 10A; thus, the insulator 280b may be formed using a material with a low relative dielectric constant, for example. When the insulator 280b is formed using a material with a low relative dielectric constant, the parasitic capacitance generated between wirings can be reduced. As the insulator 280b, a single layer or stacked layers of any of the insulators each including a material with a low relative dielectric constant described later in the section [Insulator] can be used. Specifically, silicon oxide or silicon oxynitride can be used for the insulator 280b. The concentration of impurities such as water and hydrogen in the insulator 280b is preferably reduced. This can inhibit entry of impurities such as water and hydrogen into the channel formation region of the oxide semiconductor 230.

In the case where an insulator containing oxygen is used as the insulator 280b, any of barrier insulators against oxygen described later in the section [Insulator] is preferably used as each of the insulator 280a and the insulator 280c. The insulator 280a provided between the insulator 280b and the conductor 220 can inhibit oxidation of the conductor 220 and an increase in the resistance of the conductor 220. The insulator 280c provided between the insulator 280b and the conductor 240 can inhibit oxidation of the conductor 240 and an increase in the resistance of the conductor 240.

As each of the insulator 280a and the insulator 280c, a barrier insulator against hydrogen may be used. Thus, the insulator 280b can be surrounded by barrier insulators against hydrogen (here, the insulator 280a, the insulator 280c, and the insulator 221). This can inhibit diffusion of hydrogen into the insulator 280b from the outside and diffusion of the hydrogen into the oxide semiconductor 230. A silicon nitride film and a silicon nitride oxide film can be suitably used for the insulator 280a and the insulator 280c because they release fewer impurities (e.g., water and hydrogen) and are less likely to transmit oxygen and hydrogen. For the insulator 280a and the insulator 280c, the same material or different materials may be used.

As the insulator 280a, an insulator having a function of capturing or fixing hydrogen may be used. With such a structure, diffusion of hydrogen from below the insulator 280a into the oxide semiconductor 230 can be inhibited, and hydrogen contained in the oxide semiconductor 230 can be captured or fixed. Thus, the hydrogen concentration in the oxide semiconductor 230 can be reduced. For the insulator 280a, magnesium oxide, aluminum oxide, hafnium oxide, an oxide containing hafnium and silicon, or the like can be used. For another example, a stacked-layer film of aluminum oxide and silicon nitride over the aluminum oxide may be used as the insulator 280a. Note that an insulator having a function of capturing or fixing hydrogen may be used as the insulator 280c.

For example, silicon nitride can be used for the insulator 280a and the insulator 280c, and silicon oxide can be used for the insulator 280b. In that case, each of the insulator 280a and the insulator 280c contains at least silicon and nitrogen. The insulator 280b contains at least silicon and oxygen.

Although FIG. 10A illustrates the structure in which the insulator 280c is provided over the planarized insulator 280b, the present invention is not limited thereto. For example, the insulator 280c may be formed without performing planarization treatment on the insulator 280b. When planarization treatment is not performed, the manufacturing cost can be reduced and the production yield can be increased. In addition, the insulator 280a, the insulator 280b, and the insulator 280c can be successively formed without exposure to the atmospheric environment. By the formation without exposure to the air, impurities or moisture from the atmospheric environment can be prevented from being attached onto the insulator 280a to the insulator 280c, so that the vicinity of the interface between the insulator 280a and the insulator 280b and the vicinity of the interface between the insulator 280b and the insulator 280c can be kept clean.

Although FIG. 10A illustrates the structure in which the insulator 280 has a stacked-layer structure of three layers, the present invention is not limited thereto. The insulator 280 may have a stacked-layer structure of two layers or four or more layers.

Note that the insulator 250a having a function of capturing or fixing hydrogen can be provided in contact with the oxide semiconductor 230 in FIG. 10A. Thus, in the case where the insulator 280a, the insulator 280c, and the insulator 250b each have a barrier property against hydrogen and the hydrogen concentration in the insulator 280b is sufficiently reduced, the insulator 221 and the insulator 223 are not necessarily provided as illustrated in FIG. 10B.

In that case, the insulator 280b is in contact with at least part of the oxide semiconductor 230. As the insulator 280b, an insulator containing oxygen is preferably used. The insulator 280b preferably includes a region having a higher oxygen content than at least one of the insulator 280a and the insulator 280c. In particular, the insulator 280b preferably includes a region having a higher oxygen content than each of the insulator 280a and the insulator 280c. When the insulator 280b has a high oxygen content, an i-type region can be easily formed in the oxide semiconductor 230 in the vicinity of the insulator 280b.

It is further preferable that a film from which oxygen is released by heating be used as the insulator 280b. When the insulator 280b releases oxygen by being heated during the fabrication process of the transistor 200, the oxygen can be supplied to the oxide semiconductor 230. Supply of oxygen from the insulator 280b to the oxide semiconductor 230, particularly to the channel formation region of the oxide semiconductor 230, can reduce oxygen vacancies and VoH in the oxide semiconductor 230, so that the transistor can have excellent electrical characteristics and high reliability.

In order to improve the electrical characteristics and reliability of the OS transistor, it is important to sufficiently reduce the hydrogen concentration in the oxide semiconductor and optimize the amount of oxygen supplied to the oxide semiconductor.

For example, the amount of oxygen molecules released from the insulator 280b is preferably greater than or equal to 1.0×10¹⁴ molecules/cm² and less than 1.0×10¹⁵molecules/cm². Note that the amount of released oxygen molecules can be measured by thermal desorption spectrometry.

Particularly in the case where the channel length of the transistor 200 is short, oxygen vacancies and VoH in the channel formation region significantly affect the electrical characteristics and reliability. Accordingly, when the hydrogen concentration in the oxide semiconductor 230 is sufficiently reduced and the amount of oxygen supplied to the oxide semiconductor 230 is optimized, a transistor with a short channel length, excellent electrical characteristics, and high reliability can be provided.

The insulator 280b is preferably formed by a film formation method such as a sputtering method or a plasma-enhanced chemical vapor deposition (PECVD) method. In particular, when a sputtering method is employed, a hydrogen gas does not need to be used as a film formation gas, so that a film with an extremely low hydrogen content can be formed. Thus, supply of hydrogen to the oxide semiconductor 230 can be inhibited and the electrical characteristics of the transistor 200 can be stabilized.

In the case where the amount of oxygen supplied to the oxide semiconductor 230 is increased, heat treatment in an oxygen-containing atmosphere or plasma treatment in an oxygen-containing atmosphere is preferably performed after formation of the insulator 280b, for example. Alternatively, an oxide film may be formed over the top surface of the insulator 280b by a sputtering method in an oxygen atmosphere to supply oxygen. After that, the oxide film may be removed. Such treatment can supply oxygen to the insulator 280b and increase the amount of oxygen supplied to the oxide semiconductor 230.

By contrast, in the case where the amount of oxygen supplied to the oxide semiconductor 230 is reduced, it is preferable to provide one or both of the insulator 221 and the insulator 223. Such a structure can inhibit supply of an excess amount of oxygen to the oxide semiconductor 230 even in the case where a large amount of oxygen is released from the insulator 280b.

A region of the oxide semiconductor 230 that is in contact with the insulator 280a and a region of the oxide semiconductor 230 that is in contact with the insulator 280c are supplied with a smaller amount of oxygen than a region of the oxide semiconductor 230 that is in contact with the insulator 280b. Thus, the region of the oxide semiconductor 230 that is in contact with the insulator 280a and the region of the oxide semiconductor 230 that is in contact with the insulator 280c each have a low resistance in some cases. That is, by adjusting the thickness of the insulator 280a, the range of a region functioning as one of the source region and the drain region can be controlled. Similarly, by adjusting the thickness of the insulator 280c, the range of a region functioning as the other of the source region and the drain region can be controlled. Accordingly, the thicknesses of the insulator 280a and the insulator 280c are set as appropriate in accordance with the characteristics required for the transistor 200.

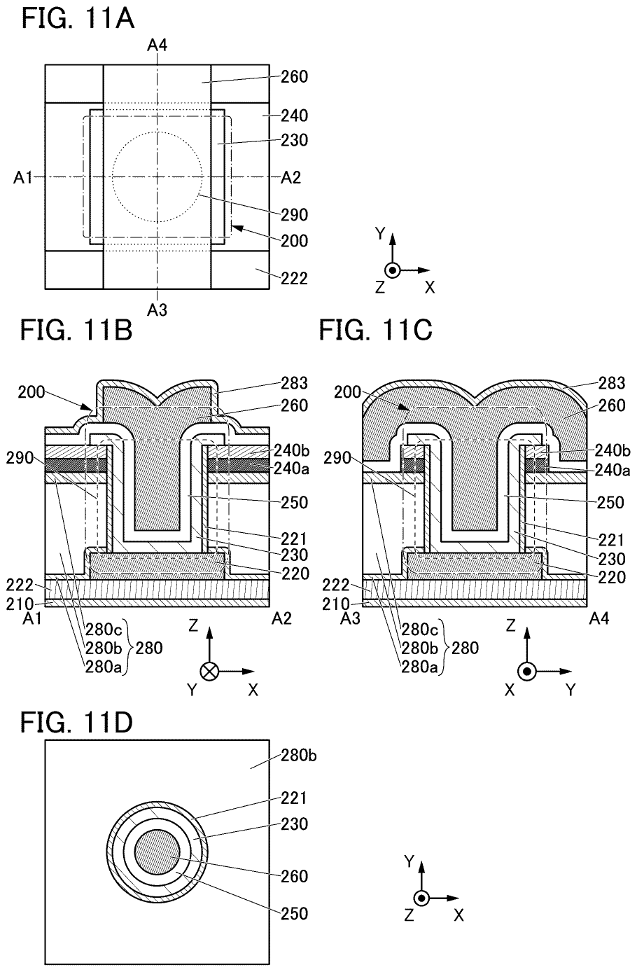

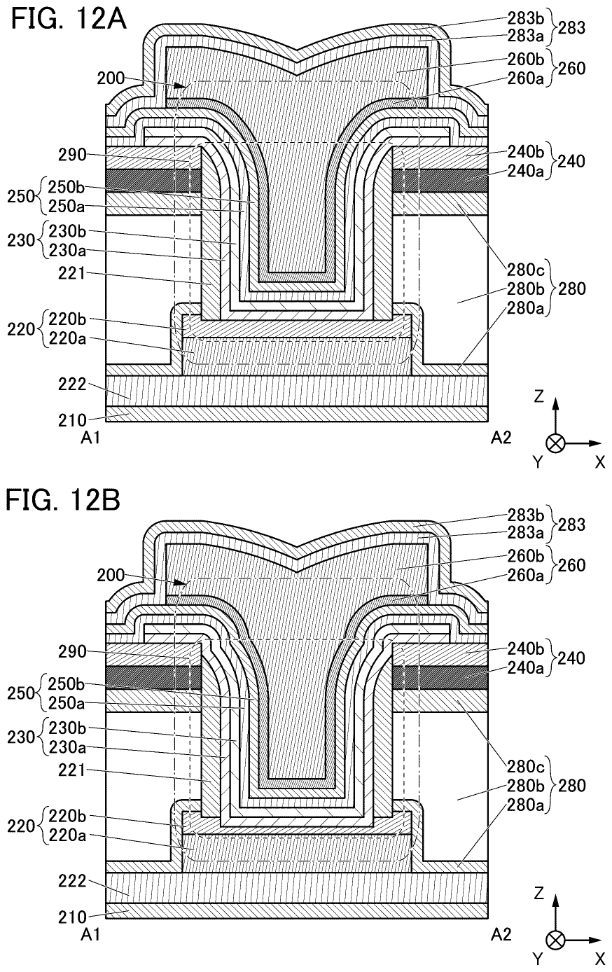

Another example of the semiconductor device of one embodiment of the present invention is described with reference to FIG. 11A to FIG. 11D. FIG. 12A and FIG. 12B are enlarged views corresponding to FIG. 11B. FIG. 11A is a plan view of the semiconductor device. FIG. 11B to FIG. 11D are cross-sectional views of the semiconductor device. Here, FIG. 11B is a cross-sectional view of a portion indicated by the dashed-dotted line A1-A2 in FIG. 11A. FIG. 11C is a cross-sectional view of a portion indicated by the dashed-dotted line A3-A4 in FIG. 11A. FIG. 11D is a cross-sectional view along the XY plane including the insulator 280. Note that for clarity of the drawing, some components are not illustrated in the plan view of FIG. 11A.

The semiconductor device illustrated in FIG. 11A to FIG. 11D is different from the semiconductor device illustrated in FIG. 9A to FIG. 9D in not including the insulator 223. Differences from the description with reference to FIG. 9A to FIG. 9D are mainly described below; the description is referred to for the same portions, and the description of the same portions is omitted in some cases. The structures in FIG. 12A and FIG. 12B are the same as the structure in FIG. 3A except that the insulator 221 is provided and the insulator 280 has a stacked-layer structure of the insulator 280a to the insulator 280c. Thus, the description of the structure in FIG. 3A is omitted in some cases.

As illustrated in FIG. 11B to FIG. 11D, the insulator 221 is provided between the oxide semiconductor 230 and each of the insulator 280 and the conductor 240 (the conductor 240a and the conductor 240b) in the opening portion 290. It is preferable that the side surface, which is closer to the center of the opening portion 290, and the upper end portion of the insulator 221 be in contact with the oxide semiconductor 230, that the side surface of the insulator 221 on the outer side of the opening portion 290 be in contact with the side surface of the insulator 280, the side surface of the conductor 240a, and the side surface of the conductor 240b, and that the lower end portion of the insulator 221 be in contact with the top surface of the conductor 220. The insulator 221 can also be regarded as being formed in a sidewall shape to be in contact with the sidewall of the opening portion 290. Portions of the insulator 221, the oxide semiconductor 230, the insulator 250, and the conductor 260 that are positioned in the opening portion 290 reflect the shape of the opening portion 290. Thus, the insulator 221 is provided to cover the sidewall of the opening portion 290, the oxide semiconductor 230 is provided to cover the side surface of the insulator 221 and the bottom portion of the opening portion 290, the insulator 250 is provided to cover the oxide semiconductor 230, and the conductor 260 is provided to fill the depressed portion of the insulator 250 that reflects the shape of the opening portion 290.

As the insulator 221, a barrier insulator against oxygen is preferably used. As the insulator 221, any of the insulators that can be used as the insulator 210 can be used. For example, silicon nitride is used. In that case, the insulator 221 contains silicon and nitrogen. When the insulator 221 described here is provided, the side surface of the conductor 240, especially the side surface of the conductor 240a, can be protected so as not to be excessively oxidized.

For example, even when the heat treatment or the microwave treatment is performed in an oxygen-containing atmosphere as described above, the insulator 221 provided in contact with the side surface of the conductor 240 in advance can inhibit excessive oxidation of the side surface of the conductor 240. In particular, even when a metal such as tungsten is used for the conductor 240a, formation of an excess metal oxide on the side surface of the conductor 240a can be prevented. This can prevent oxidation of the conductor 240a and an increase in sheet resistance; thus, the conductor 240a can adequately function as the wiring electrically connected to one of the source electrode and the drain electrode. Accordingly, the electrical characteristics such as the on-state current, the field-effect mobility, the S value, and the frequency characteristics of the transistor 200 can be improved.

As illustrated in FIG. 12A, the upper portion of the side surface of the insulator 221 has a tapered shape in some cases. Furthermore, the upper portion of the insulator 221 has a curved surface in some cases. The oxide semiconductor 230 is sometimes in contact with the tapered upper portion of the insulator 221. When the upper portion of the insulator 221 has a curved surface in that case, the oxide semiconductor 230 can be formed with good coverage. Note that the upper portion of the conductor 240b also has a tapered shape successively from the tapered portion of the insulator 221 in some cases.

In the case where a depressed portion overlapping with the opening portion 290 is formed on the top surface of the conductor 220 as illustrated in FIG. 12A, part of the insulator 221 is formed in the depressed portion in some cases.

Although FIG. 12A illustrates a structure in which the upper end portion of the insulator 221 is aligned or substantially aligned with the top surface of the conductor 240b, the present invention is not limited thereto. For example, as illustrated in FIG. 12B, the level of the upper end portion of the insulator 221 can be lower than that of the top surface of the conductor 240b. Also in that case, the side surface of the conductor 240a on the opening portion 290 side is preferably covered with the insulator 221. In other words, at least part of the insulator 221 is preferably in contact with the side surface of the conductor 240b on the opening portion 290 side. With such a structure, the side surface of the conductor 240a formed using a metal that is relatively easily oxidized can be protected by the insulator 221. In that case, part of the side surface of the conductor 240b formed using a metal oxide is exposed to an oxidizing atmosphere in some cases. However, since the conductor 240b is a metal oxide, deterioration due to oxidation of the conductor 240b is smaller than that of the conductor 240a.

Although FIG. 12A illustrates a structure in which the lower end portion of the insulator 221 and the bottom surface of the oxide semiconductor 230 are level or substantially level with each other, the present invention is not limited thereto. For example, as illustrated in FIG. 12B, the level of the lower end portion of the insulator 221 is sometimes higher than that of the bottom surface of the oxide semiconductor 230. In that case, the depressed portion of the top surface of the conductor 220 can be regarded as being formed in a step-like shape.

In the case where silicon nitride is used for the insulator 221, the thickness of the insulator 221 (e.g., the width of the insulator 221 in the A1-A2 direction) is preferably greater than or equal to 0.5 nm, further preferably greater than or equal to 2 nm. Although there is no particular limitation on the upper limit of the thickness of the insulator 221, for scaling down or high integration of the semiconductor device, increased productivity of the semiconductor device, and the like, the thickness of the insulator 221 is preferably less than or equal to 20 nm, less than or equal to 10 nm, or less than or equal to 8 nm. Thus, the insulator 221 preferably includes a region where the thickness is greater than or equal to 0.5 nm and less than or equal to 20 nm, further preferably includes a region where the thickness is greater than or equal to 2 nm and less than or equal to 8 nm.

Furthermore, the insulator 221 preferably has a barrier insulating property against hydrogen. For example, silicon nitride is used for the insulator 221. Thus, the oxide semiconductor 230 can be sandwiched between barrier insulators against hydrogen. With this structure, diffusion of hydrogen into the oxide semiconductor 230 can be inhibited and the hydrogen concentration in the oxide semiconductor 230 can be further reduced.

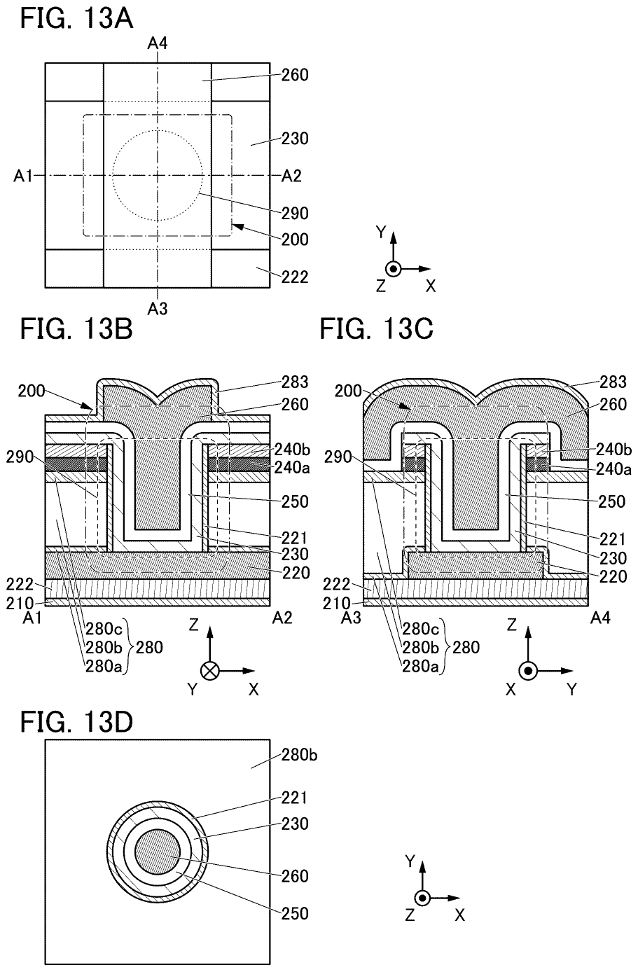

FIG. 13A to FIG. 13D illustrate a structure similar to that in FIG. 11A to FIG. 11D. FIG. 13A to FIG. 13D correspond to FIG. 11A to FIG. 11D, respectively.

The structure illustrated in FIG. 13A to FIG. 13D is different from the structure illustrated in FIG. 11A to FIG. 11D in that the side end portion of the oxide semiconductor 230 and the side end portion of the conductor 240 are aligned with each other. The side end portion of the oxide semiconductor 230, the side end portion of the conductor 240a, and the side end portion of the conductor 240b can be aligned with each other when the oxide semiconductor 230, the conductor 240a, and the conductor 240b are processed using the same mask in the step illustrated in FIG. 4C, for example. In the structure illustrated in FIG. 13A to FIG. 13D, the conductor 220 extends in the X direction like the conductor 240. In that case, the conductor 220 can function as a wiring extending in the X direction.

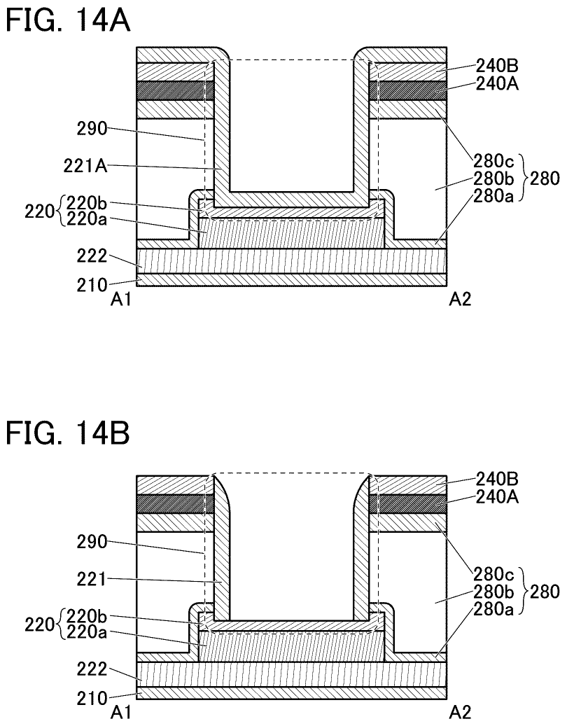

Next, a fabrication process of the transistor illustrated in FIG. 11A to FIG. 11D will be described with reference to FIG. 14A and FIG. 14B. Note that steps in FIG. 14A and FIG. 14B are performed between the step in FIG. 4B and the step in FIG. 4C among the steps illustrated in FIG. 4A to FIG. 4E. Thus, the above description can be referred to for the details of the steps in FIG. 4A to FIG. 4E.

After the opening portion 290 is formed in the step in FIG. 4B, an insulating film 221A is formed in contact with the top surface of the conductor 220, the side surface of the insulator 280, the side surface of the conductive film 240A, and the top surface and the side surface of the conductive film 240B (see FIG. 14A). The insulating film 221A is preferably formed to cover the side surface of the conductor 240, especially the conductive film 240A, at least in the opening portion 290. The insulating film 221A is an insulating film to be the insulator 221 in a later step, and any of the insulators described above can be used. The insulating film 221A can be formed by a sputtering method, a CVD method, an MBE method, a PLD method, or an ALD method, for example.

The insulating film 221A preferably has good coverage because it is formed along the sidewall and the bottom surface of the opening portion 290. Thus, the insulating film 221A is preferably formed by an ALD method or the like that offers good coverage. For example, a silicon nitride film is preferably formed by a PEALD method as the insulating film 221A.

Next, part of the insulating film 221A is removed by anisotropic etching, so that the sidewall-shaped insulator 221 is formed in contact with the sidewall of the opening (see FIG. 14B). Thus, the insulator 221 is formed in contact with the side surface of the insulator 280, the side surface of the conductor 240a, and the side surface of the conductor 240b. As described above, the insulator 221 is preferably formed to cover at least the side surface of the conductor 240a.

As the anisotropic etching, reactive ion etching is preferably performed by a dry etching method. Note that the above description can be referred to for the conditions and an apparatus for a dry etching method. For example, in the case where silicon nitride is used for the insulating film 221A, etching treatment can be performed with a DF-CCP etching apparatus using CH₂F₂, O₂, and Ar as etching gases.

In the etching of the insulating film 221A, the generated ions may collide with a corner portion of the edge of the opening of the insulator 221. Thus, as illustrated in FIG. 12A and the like, the corner portion is polished to have a tapered shape in some cases. The corner portion is easily removed when a gas that is easily ionized, such as argon, is contained in the etching gas or a bias voltage is applied to an electrode on the substrate side, for example. At this time, the upper end portion of the insulator 221 is etched so that the level of the upper end portion of the insulator 221 is lower than that of the top surface of the conductive film 240B in some cases as illustrated in FIG. 12B.

Part of the top surface of the conductor 220 is sometimes removed by this etching treatment. In that case, the insulator 221 functions as a mask; thus, the thickness of a portion of the conductor 220 that overlaps with the insulator 221 is larger than that of a portion of the conductor 220 that does not overlap with the insulator 221. That is, a step-like depressed portion is formed on the top surface of the conductor 220. In this manner, the transistor 200 in which the level of the lower end portion of the insulator 221 is higher than that of the bottom surface of the oxide semiconductor 230 is formed as illustrated in FIG. 12B.

In order to remove impurities and the like attached to the opening portion 290 in the step of forming the insulator 221, cleaning treatment is preferably performed. As a cleaning method, wet cleaning or the like can be employed as in the cleaning treatment after the formation of the opening portion 290. The wet cleaning can also be performed by the above-described method. For example, the wet cleaning is performed using diluted hydrofluoric acid obtained by diluting hydrofluoric acid with pure water. Part of the top surface of the conductor 220 is sometimes removed by the wet cleaning.

The heat treatment in an oxygen-containing atmosphere and the microwave treatment in an oxygen-containing atmosphere after the formation of the opening portion 290 that are described in <Method for fabricating semiconductor device> are preferably performed after the formation of the insulator 221. Accordingly, the heat treatment and the microwave treatment can be performed in the state where the side surface of the conductor 240 is protected by the insulator 221. This can prevent excessive oxidation of the side surface of the conductor 240 even when a metal such as tungsten is used for the conductor 240a.

Note that part of the insulator 221 is oxidized by the heat treatment and the microwave treatment in some cases. In other words, the insulator 221 might contain oxygen. In that case, a region of the insulator 221 that has a high oxygen concentration is observed through composition analysis performed on the insulator 221 by SIMS or the like. After oxidation of the insulator 221 proceeds and the transistor 200 is formed, part of the insulator 221 becomes silicon oxynitride or silicon nitride oxide in some cases.

When part of the insulator 221 is oxidized in this manner, the use of a film from which oxygen is released by heating for the insulator 280b enables oxygen to be supplied to the oxide semiconductor 230 in some cases. For example, oxygen is released from the insulator 280b by heat treatment performed after the formation of the insulator 283, and oxygen is supplied to the oxide semiconductor 230 through part of the insulator 221 in some cases. Supply of oxygen from the insulator 280b to the oxide semiconductor 230, particularly to the channel formation region of the oxide semiconductor 230, can reduce oxygen vacancies and VoH in the oxide semiconductor 230, so that the transistor can have excellent electrical characteristics and high reliability.

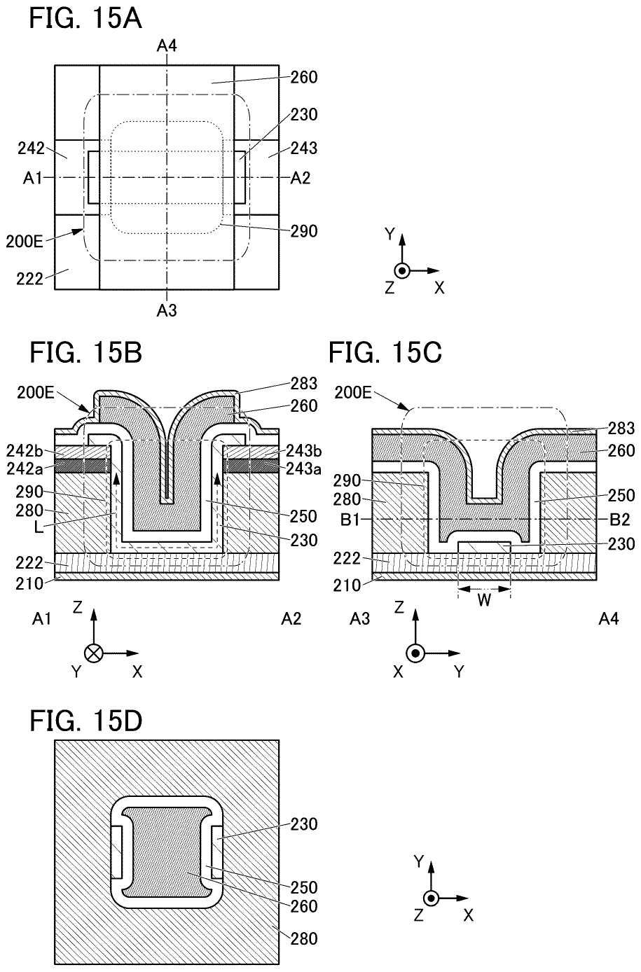

Another example of the semiconductor device of one embodiment of the present invention is described with reference to FIG. 15A to FIG. 15D. FIG. 15A to FIG. 15D are a plan view and cross-sectional views of the semiconductor device including a transistor 200E. FIG. 15A is the plan view of the semiconductor device. FIG. 15B to FIG. 15D are the cross-sectional views of the semiconductor device. Here, FIG. 15B is a cross-sectional view of a portion indicated by the dashed-dotted line A1-A2 in FIG. 15A. FIG. 15C is a cross-sectional view of a portion indicated by the dashed-dotted line A3-A4 in FIG. 15A. FIG. 15D is a cross-sectional view along the XY plane including the insulator 280. Note that for clarity of the drawing, some components are not illustrated in the plan view of FIG. 15A.

The semiconductor device illustrated in FIG. 15A to FIG. 15D includes the insulator 210 over a substrate (not illustrated), the insulator 222 over the insulator 210, the transistor 200E over the insulator 222, the insulator 280 over the insulator 210, and the insulator 283 over the transistor 200E.

The transistor 200E includes a conductor 242 and a conductor 243 over the insulator 280, the oxide semiconductor 230, the insulator 250 over the oxide semiconductor 230, and the conductor 260 over the insulator 250.

The semiconductor device illustrated in FIG. 15A to FIG. 15D is different from the semiconductor device illustrated in FIG. 8A to FIG. 8D in the shape of the oxide semiconductor 230. The semiconductor device illustrated in FIG. 15A to FIG. 15D is different from the semiconductor device illustrated in FIG. 8A to FIG. 8D in that the conductor 220 is not provided and the conductor 242 and the conductor 243 are provided instead of the conductor 240. Differences from the description with reference to FIG. 8A to FIG. 8D are mainly described below; the description is referred to for the same portions, and the description of the same portions is omitted in some cases.

The oxide semiconductor 230, the insulator 250, and the conductor 260 are provided in the opening portion 290 of the insulator 280. In the opening portion 290, the side surface of the insulator 280 includes a region in contact with the oxide semiconductor 230 and a region in contact with the insulator 250. In the case where the insulator 250 has a stacked-layer structure of the insulator 250a and the insulator 250b as in FIG. 3A and the like, part of the side surface of the insulator 280 is in contact with the insulator 250a having a function of capturing or fixing hydrogen.

As illustrated in FIG. 15B and FIG. 15C, the oxide semiconductor 230 includes a region in contact with the bottom portion of the opening portion 290. In other words, the bottom surface of the oxide semiconductor 230 in the opening portion 290 is in contact with the insulator 222.

The conductor 242 and the conductor 243 are separated by the opening portion 290. The conductor 242 includes a conductor 242a and a conductor 242b over the conductor 242a. The conductor 243 includes a conductor 243a and a conductor 243b over the conductor 243a. The conductor 242a and the conductor 243a can each have a structure similar to that of the above-described conductor 240a. The conductor 242b and the conductor 243b can each have a structure similar to that of the above-described conductor 240b.

In the transistor 200E, the oxide semiconductor 230 functions as a semiconductor layer, the conductor 260 functions as a gate electrode, the insulator 250 functions as a gate insulator, the conductor 242 functions as one of a source electrode and a drain electrode, and the conductor 243 functions as the other of the source electrode and the drain electrode.

The semiconductor device illustrated in FIG. 15A to FIG. 15D has a structure in which the oxide semiconductor 230, the insulator 250, and the conductor 260 are provided in this order in the opening portion of the insulator 280.

The oxide semiconductor 230 is provided to be at least partly positioned in the opening portion 290. The transistor 200E has a structure in which current flows from one of the source electrode and the drain electrode (e.g., the conductor 242) to the other of the source electrode and the drain electrode (e.g., the conductor 243). That is, the channel length of the transistor 200E (the length L indicated by a double-headed arrow in FIG. 15B) is the sum of the double of the length of the sidewall of the opening portion 290 and the length of the bottom portion of the opening portion 290. Note that the length of the sidewall of the opening portion 290 corresponds to the depth of the opening portion 290. The length of the bottom portion of the opening portion 290 is, for example, the shortest distance between the conductor 242 and the conductor 243. As described here, the channel length (the length L) of the transistor 200E can be adjusted with the depth of the opening portion 290 and the length of the bottom portion of the opening portion 290. For example, in the case where the channel length is increased while scaling down or high integration of the semiconductor device is achieved, the depth of the opening portion 290 is preferably made large.

The channel width of the transistor 200E (a length W indicated by a double-headed arrow in FIG. 15C) corresponds to the width of the oxide semiconductor 230 in the Y direction in a plan view. Thus, the channel width of the transistor 200E is preferably smaller than the width of the bottom portion of the opening portion 290.

Note that FIG. 15A and FIG. 15D illustrate an example in which the opening portion of the insulator 280 has a quadrangular shape with rounded corners in a plan view. In that case, the maximum width of the opening portion may be calculated as appropriate in accordance with the shape of the uppermost portion of the opening portion. For example, in the case where the opening portion has a quadrangular shape with rounded corners in a plan view, the maximum width of the opening portion may be the length of a diagonal line or the distance between opposite sides of the uppermost portion of the opening portion, assuming it to be a rectangle. Note that the present invention is not limited thereto. For example, the opening portion 290 in a plan view may have a circular shape, an almost circular shape such as an elliptical shape, a polygonal shape, or a polygonal shape with rounded corners.

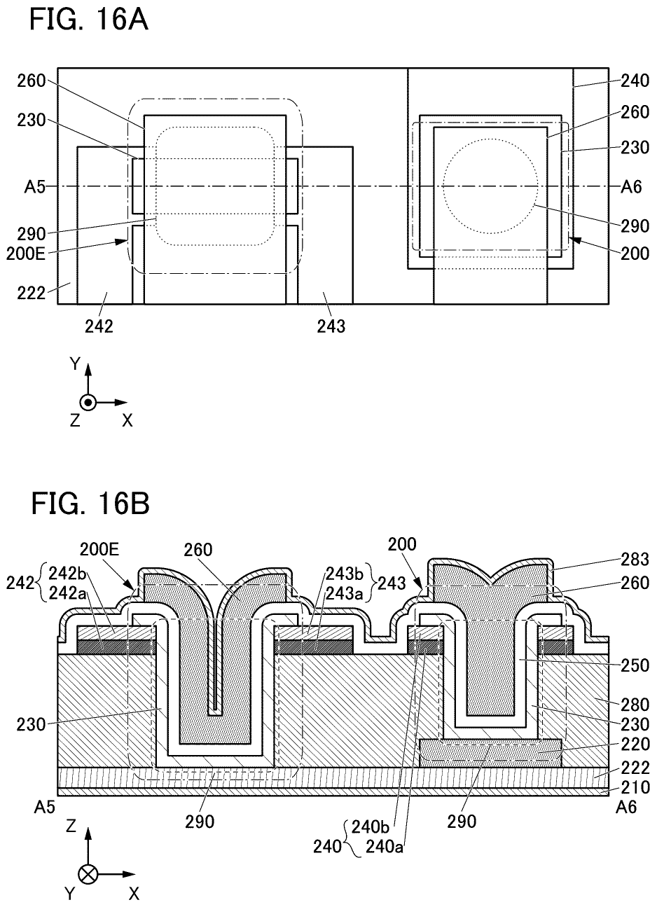

As illustrated in FIG. 16A and FIG. 16B, the transistor 200E illustrated in FIG. 15A to FIG. 15D and the transistor 200 illustrated in FIG. 8A to FIG. 8D can be fabricated over the same layer (here, the insulator 222). That is, the transistor 200E can be fabricated in parallel with the fabrication process of the transistor 200. Thus, two transistors with different channel lengths and different channel widths can be provided over the same layer. As described above, the semiconductor device of one embodiment of the present invention offers such an excellent effect that transistors with different channel lengths over the same layer can be freely designed in accordance with the thickness of an insulating layer and patterning. FIG. 16A is a plan view of the semiconductor device. FIG. 16B is a cross-sectional view of the semiconductor device, and is a cross-sectional view of a portion indicated by the dashed-dotted line A5-A6 in FIG. 16A.

### <Materials for Semiconductor Device>

Materials that can be used for the semiconductor device will be described below.

### [Substrate]

As a substrate where a transistor is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### [Insulator]

Examples of an insulator include an insulating oxide, an insulating nitride, an insulating oxynitride, an insulating nitride oxide, an insulating metal oxide, an insulating metal oxynitride, and an insulating metal nitride oxide.

As scaling down and high integration of transistors progress, for example, a problem such as leakage current may arise because of a thinner gate insulator. When a high-k material is used for an insulator functioning as a gate insulator, the voltage at the time of the operation of the transistor can be reduced while the physical thickness is maintained. In addition, the equivalent oxide thickness (EOT) of the insulator functioning as the gate insulator can be reduced. By contrast, when a material with a low relative dielectric constant is used for an insulator functioning as an interlayer film, the parasitic capacitance generated between wirings can be reduced. Thus, a material is preferably selected in accordance with the function of the insulator. Note that the material with a low relative dielectric constant is a material with high dielectric strength.

Examples of the material with a high relative dielectric constant (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low relative dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with a low relative dielectric constant include silicon oxide to which fluorine is added, silicon oxide to which carbon is added, and silicon oxide to which carbon and nitrogen are added. Another example is porous silicon oxide. These silicon oxides may contain nitrogen.

A material that can have ferroelectricity may be used for the insulator. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

When a transistor using a metal oxide is surrounded by an insulator having a function of inhibiting passage of oxygen and impurities, the transistor can have stable electrical characteristics. As the insulator having a function of inhibiting passage of oxygen and impurities, a single layer or stacked layers including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of oxygen and impurities, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor or provided in the vicinity of a semiconductor layer, such as a gate insulator, preferably includes a region containing oxygen released by heating (hereinafter, sometimes referred to as excess oxygen). For example, when an insulator including a region containing excess oxygen is in contact with a semiconductor layer or provided in the vicinity of the semiconductor layer, oxygen vacancies in the semiconductor layer can be reduced. Examples of an insulator in which a region containing excess oxygen is easily formed include silicon oxide, silicon oxynitride, and porous silicon oxide.

Examples of a barrier insulator against oxygen include an oxide containing one or both of aluminum and hafnium, an oxide containing hafnium and silicon (hafnium silicate), magnesium oxide, gallium oxide, gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

The description in Embodiment 1 can be referred to for a barrier insulator against hydrogen.

A barrier insulator against oxygen and a barrier insulator against hydrogen can each be regarded as a barrier insulator against one or both of oxygen and hydrogen.

The description in Embodiment 1 can be referred to for an insulator having a function of capturing or fixing hydrogen.

### [Conductor]

As a conductor, it is preferable to use a metal element selected from aluminum, chromium, copper, silver, gold, platinum, tantalum, nickel, cobalt, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements as its component; an alloy containing a combination of the above metal elements; or the like. As the alloy containing any of the above metal elements as its component, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may also be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting diffusion of oxygen, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. A stacked-layer structure combining a material containing the above metal element and a conductive material containing nitrogen may be employed. A stacked-layer structure combining a material containing the above metal element, a conductive material containing oxygen, and a conductive material containing nitrogen may be employed.

In the case where a metal oxide is used for a channel formation region of a transistor, a conductor functioning as a gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide where a channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide sometimes includes a lattice defect. Examples of a lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects for a semiconductor layer of a transistor may cause unstable electrical characteristics of the transistor. Hence, a metal oxide used for a semiconductor layer of a transistor preferably has a small number of lattice defects.

The kind of a lattice defect that is likely to be present in a metal oxide and the number of lattice defects that are present vary depending on the structure of the metal oxide, a method for forming the metal oxide, or the like.

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure.

A metal oxide having an a-like structure and a metal oxide having an amorphous structure each include a void or a low-density region. That is, the metal oxide having the a-like structure and the metal oxide having the amorphous structure have lower crystallinity than a metal oxide having an nc structure and a metal oxide having a CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, a metal oxide with high crystallinity is preferably used for a semiconductor layer of a transistor. For example, it is preferable to use the metal oxide having the CAAC structure or the metal oxide having the single crystal structure. The use of such a metal oxide for a transistor enables the transistor to have excellent electrical characteristics. In addition, a transistor with high reliability can be achieved.

For a channel formation region of a transistor, a metal oxide that increases the on-state current of the transistor is preferably used. To increase the on-state current of the transistor, the carrier mobility of the metal oxide used for the transistor is preferably increased. To increase the carrier mobility of the metal oxide, the transfer of carriers (electrons in the case of an n-channel transistor) needs to be facilitated or scattering factors that affect the carrier transfer need to be reduced. The carriers flow from the source to the drain through the channel formation region. Hence, the on-state current of the transistor can be increased by providing a channel formation region through which carriers can easily flow in the channel length direction.

Here, it is preferable to use a metal oxide with high crystallinity as a metal oxide including a channel formation region. The crystal preferably has a crystal structure in which a plurality of layers (e.g., a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS.

The c-axis of the above crystal is preferably aligned in the normal direction with respect to the formation surface or the film surface of the metal oxide. This enables the plurality of layers to be placed parallel or substantially parallel to the formation surface or the film surface of the metal oxide. That is, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal include a YbFe₂O₄ type structure, a Yb₂Fe₃O₇ type structure, and variant structures of these structures.

Each of the first layer to the third layer is preferably composed of oxygen and one metal element or a plurality of metal elements with the same valence. The valences of the one or plurality of metal elements included in the first layer are preferably equal to the valences of the one or plurality of metal elements included in the second layer. The first layer and the second layer may include the same metal element. The valences of the one or plurality of metal elements included in the first layer are preferably different from the valences of the one or plurality of metal elements included in the third layer.

The above structure can increase the crystallinity of the metal oxide, which leads to an increase in the carrier mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three elements selected from indium, the element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may include a metalloid element.

For example, as the metal oxide of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide; also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table of the elements. Alternatively, the metal oxide may contain, in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be increased.

By increasing the proportion of the number of In atoms in the total number of atoms of all the metal elements contained in the metal oxide, the transistor can have a high on-state current and high frequency characteristics.

In the description of this embodiment, In—Ga—Zn oxide is sometimes taken as an example of the metal oxide.

For the formation of a metal oxide having the layered crystal structure, atomic layers are preferably deposited one by one. Since an ALD method is employed as the film formation method of the metal oxide of one embodiment of the present invention, a metal oxide having the layered crystal structure is easily formed.

### [[Transistor Including Metal Oxide]]

Next, the case where a metal oxide (oxide semiconductor) is used for a transistor will be described. Hereinafter, a transistor using an oxide semiconductor for a semiconductor layer is sometimes referred to as an OS transistor, and a transistor using silicon for a semiconductor layer is sometimes referred to as a Si transistor.

When a metal oxide (oxide semiconductor) of one embodiment of the present invention is used for a transistor, the transistor can have high field-effect mobility. In addition, the transistor can have high reliability. Furthermore, the transistor can be scaled down or highly integrated. For example, the transistor with a channel length greater than or equal to 2 nm and less than or equal to 30 nm can be fabricated.

An oxide semiconductor having a low carrier concentration is preferably used for a channel formation region of a transistor. For example, the carrier concentration in a channel formation region of an oxide semiconductor is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1×10¹¹ cm³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With the use of an oxide semiconductor having a larger band gap than silicon, the off-state current (also referred to as Ioff) of the transistor can be reduced.

In a Si transistor, a short-channel effect (also referred to as SCE) appears as scaling down of the transistor proceeds. For this reason, it is difficult to scale down the Si transistor. One factor that causes the short-channel effect is a small band gap of silicon. By contrast, the OS transistor includes an oxide semiconductor that is a semiconductor material having a large band gap, and thus the short-channel effect can be suppressed. In other words, the OS transistor is a transistor in which the short-channel effect does not appear or the short-channel effect hardly appears.

Note that the short-channel effect refers to degradation of electrical characteristics which becomes apparent along with scaling down (a decrease in channel length) of a transistor. Specific examples of the short-channel effect include a decrease in threshold voltage, an increase in a subthreshold swing value (sometimes referred to as an S value), and an increase in leakage current. Here, the S value means the amount of change in gate voltage in the subthreshold region when the drain voltage keeps constant and the drain current changes by one order of magnitude.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Thus, the OS transistor has higher resistance to the short-channel effect than the Si transistor. That is, in the case where a transistor with a short channel length is to be fabricated, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region may decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions.

The above-described structure enables the OS transistor to have excellent electrical characteristics even when the OS transistor is scaled down or highly integrated. For example, excellent electrical characteristics can be obtained even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, the OS transistor can be used as a transistor having a short channel length more suitably than the Si transistor. Note that the gate length refers to the length of a gate electrode in a direction in which carriers move inside a channel formation region during an operation of the transistor.

Scaling down of the OS transistor can improve the high-frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

The above comparison of the OS transistor with the Si transistor demonstrates that the OS transistor is advantageous over the Si transistor in that the off-state current is low and a transistor having a short channel length can be fabricated.

[[Impurity in metal oxide]]

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³.

When the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, stable electrical characteristics can be given.

### [Other Semiconductor Materials]

The oxide semiconductor 230 can be rephrased as a semiconductor layer including a channel formation region of a transistor. A semiconductor material that can be used for the semiconductor layer is not limited to the above metal oxides. A semiconductor material that has a band gap (a semiconductor material that is not a zero-gap semiconductor) may be used for the semiconductor layer. For example, a single element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon atoms, nitrogen atoms, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For the semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a semiconductor device with a high on-state current to be provided.

This embodiment can be combined with the other embodiments and examples as appropriate. In this specification, in the case where a plurality of structure examples are shown in one embodiment, the structure examples can be combined as appropriate.

### Embodiment 2

In this embodiment, a semiconductor device 900 of one embodiment of the present invention will be described. The semiconductor device 900 can function as a memory device.

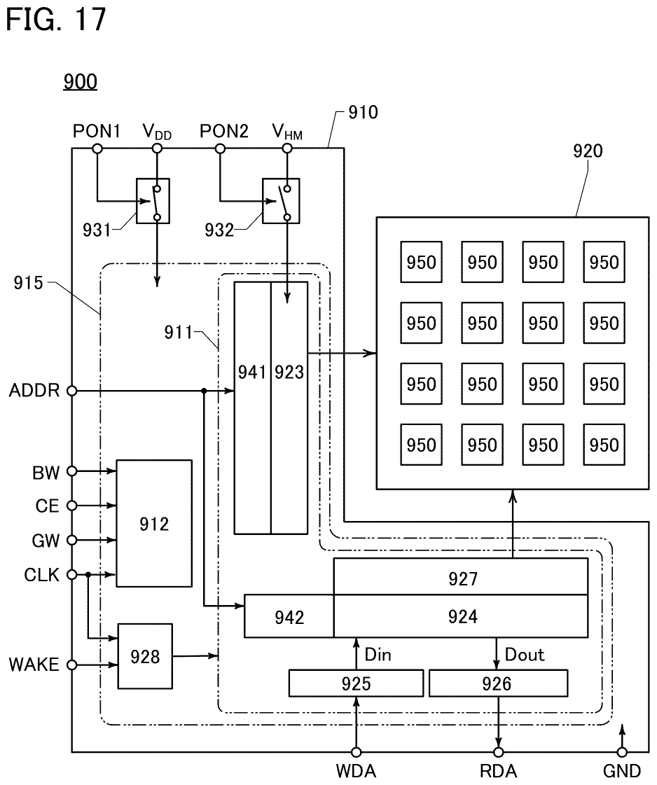

FIG. 17 illustrates a block diagram illustrating a structure example of the semiconductor device 900. The semiconductor device 900 illustrated in FIG. 17 includes a driver circuit 910 and a memory array 920. The memory array 920 includes one or more memory cells 950. FIG. 17 illustrates an example in which the memory array 920 includes the plurality of memory cells 950 arranged in a matrix.

The transistor exemplified in the above embodiment can be used for the memory cell 950. With the use of the transistor, the memory device can be scaled down and highly integrated. In addition, the capacity per area of the memory device can be increased.

The driver circuit 910 includes a PSW 931 (a power switch), a PSW 932, and a peripheral circuit 915. The peripheral circuit 915 includes a peripheral circuit 911, a control circuit 912, and a voltage generator circuit 928.

In the semiconductor device 900, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine the operating mode (e.g., writing operation or reading operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is supplied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925 (Input Cir.), an output circuit 926 (Output Cir.), and a sense amplifier 927.

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting the row specified by the row decoder 941. The column driver 924 has functions of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (ground potential). In addition, V_{HM} is a high power supply voltage used to set a word line at a high level and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 17 but can be more than one. In that case, a power switch is provided for each power domain.

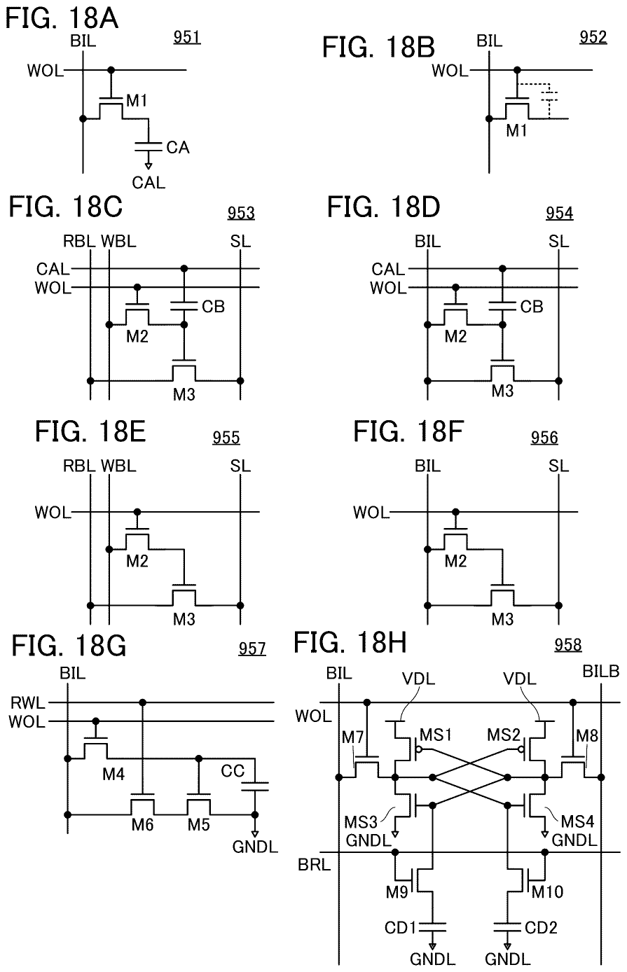

Structure examples of other memory cells each of which can be used as the memory cell 950 will be described with reference to FIG. 18A to FIG. 18H.

### [DOSRAM]

FIG. 18A illustrates a circuit structure example of a memory cell for a DRAM. In this specification and the like, a DRAM using an OS transistor is referred to as a DOSRAM (Dynamic Oxide Semiconductor Random Access Memory). A memory cell 951 includes a transistor M1 and a capacitor CA.

Note that the transistor M1 may include a front gate (simply referred to as a gate in some cases) and a back gate. In that case, the back gate may be connected to a wiring supplied with a constant potential or a signal, and the front gate and the back gate may be connected to each other.

A first terminal of the transistor M1 is connected to a first terminal of the capacitor CA, a second terminal of the transistor M1 is connected to a wiring BIL, and the gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (sometimes referred to as a reference potential) is preferably applied to the wiring CAL.

Data writing and reading are performed as follows: a high-level potential is applied to the wiring WOL to turn on the transistor M1 so that the wiring BIL is connected to the first terminal of the capacitor CA.

The memory cell that can be used as the memory cell 950 is not limited to the memory cell 951, and the circuit structure can be changed. For example, the structure of a memory cell 952 illustrated in FIG. 18B can be employed. The memory cell 952 is an example of the case where neither the capacitor CA nor the wiring CAL is provided. The first terminal of the transistor M1 is in an electrically floating state.

In the memory cell 952, a potential written through the transistor MI is retained in a capacitor (also referred to as parasitic capacitance) between the first terminal and the gate, which is shown by a dashed line. With such a structure, the structure of the memory cell can be greatly simplified.

Note that the OS transistor described in the above embodiment is preferably used as the transistor M1. The use of the OS transistor described in the above embodiment enables a reduction in the area occupied by the memory cell. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be unnecessary. In addition, owing to an extremely low leakage current, multilevel data or analog data can be retained in the memory cell 951 and the memory cell 952.

### [NOSRAM]

FIG. 18C illustrates a circuit structure example of a gain memory cell including two transistors and one capacitor. A memory cell 953 includes a transistor M2, a transistor M3, and a capacitor CB. In this specification and the like, a memory device including a gain memory cell using an OS transistor as the transistor M2 is referred to as a NOSRAM (Nonvolatile Oxide Semiconductor RAM).

A first terminal of the transistor M2 is connected to a first terminal of the capacitor CB, a second terminal of the transistor M2 is connected to a wiring WBL, and a gate of the transistor M2 is connected to the wiring WOL. A second terminal of the capacitor CB is connected to the wiring CAL. A first terminal of the transistor M3 is connected to a wiring RBL, a second terminal of the transistor M3 is connected to a wiring SL, and a gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a reference potential) is preferably applied to the wiring CAL.

Data writing is performed as follows: a high-level potential is applied to the wiring WOL to turn on the transistor M2 so that the wiring WBL is connected to the first terminal of the capacitor CB. Specifically, when the transistor M2 is in an on state, a potential corresponding to information to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. Current flowing between the source and the drain of the transistor M3 and the potential of the first terminal of the transistor M3 are determined by the potential of the gate of the transistor M3 and the potential of the second terminal of the transistor M3; thus, by reading a potential of the wiring RBL connected to the first terminal of the transistor M3, a potential retained at the first terminal of the capacitor CB (or the gate of the transistor M3) can be read. That is, information written to the memory cell can be read on the basis of the potential retained at the first terminal of the capacitor CB (or the gate of the transistor M3).

For another example, the wiring WBL and the wiring RBL may be combined into one wiring BIL. A circuit structure example of the memory cell is illustrated in FIG. 18D. In a memory cell 954, one wiring BIL corresponds to the wiring WBL and the wiring RBL in the memory cell 953, and the second terminal of the transistor M2 and the first terminal of the transistor M3 are connected to the wiring BIL. That is, one wiring BIL operates as a write bit line and a read bit line in the memory cell 954.

A memory cell 955 illustrated in FIG. 18E is an example of the case where the capacitor CB and the wiring CAL in the memory cell 953 are omitted. A memory cell 956 illustrated in FIG. 18F is an example of the case where the capacitor CB and the wiring CAL in the memory cell 954 are omitted. Such structures enable high integration of memory cells.

Note that the OS transistor described in the above embodiment is preferably used as at least the transistor M2. In particular, the OS transistor described in the above embodiment is preferably used as each of the transistor M2 and the transistor M3. The use of the OS transistor described in the above embodiment enables a reduction in the area occupied by the memory cell.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be unnecessary. In addition, owing to an extremely low leakage current, multilevel data or analog data can be retained in the memory cell 953, the memory cell 954, the memory cell 955, and the memory cell 956.

The memory cell 953, the memory cell 954, the memory cell 955, and the memory cell 956 each using the OS transistor as the transistor M2 are embodiments of a NOSRAM.

Note that a Si transistor may be used as the transistor M3. The Si transistor can have high field-effect mobility and can be a p-channel transistor, so that circuit design flexibility can be increased.

In the case where the OS transistor is used as the transistor M3, the memory cell can be composed of a single-polarity circuit.

FIG. 18G illustrates a gain memory cell 957 including three transistors and one capacitor. The memory cell 957 includes a transistor M4 to a transistor M6 and a capacitor CC.

A first terminal of the transistor M4 is connected to a first terminal of the capacitor CC, a second terminal of the transistor M4 is connected to the wiring BIL, and a gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6, and a gate of the transistor M5 is connected to the first terminal of the capacitor CC. A second terminal of the transistor M6 is connected to the wiring BIL, and a gate of the transistor M6 is connected to a wiring RWL.

The wiring BIL functions as a bit line, the wiring WOL functions as a write word line, and the wiring RWL functions as a read word line. The wiring GNDL is a wiring for supplying a low-level potential.

Data writing is performed as follows: a high-level potential is applied to the wiring WOL to turn on the transistor M4 so that the wiring BIL is connected to the first terminal of the capacitor CC. Specifically, when the transistor M4 is in an on state, a potential corresponding to information to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed as follows: the wiring BIL is precharged to a predetermined potential, the wiring BIL is brought into an electrically floating state, and a high-level potential is applied to the wiring RWL. Since the wiring RWL has the high-level potential, the transistor M6 is turned on, so that the wiring BIL is electrically connected to the second terminal of the transistor M5. At this time, the potential of the wiring BIL is applied to the second terminal of the transistor M5; the potential of the second terminal of the transistor M5 and the potential of the wiring BIL change in accordance with the potential retained at the first terminal of the capacitor CC (or the gate of the transistor M5). Here, the potential retained at the first terminal of the capacitor CC (or the gate of the transistor M5) can be read by reading the potential of the wiring BIL. That is, information written to the memory cell can be read on the basis of the potential retained at the first terminal of the capacitor CC (or the gate of the transistor M5).

Note that the OS transistor described in the above embodiment is preferably used as at least the transistor M4. The use of the OS transistor described in the above embodiment enables a reduction in the area occupied by the memory cell.

Note that Si transistors may be used as the transistors M5 and M6. As described above, a Si transistor may have higher field-effect mobility than the OS transistor depending on the crystal state of silicon used in a semiconductor layer, for example.

In the case where OS transistors are used as the transistors M5 and M6, the memory cell can be composed of a single-polarity circuit.

### [OS-SRAM]

FIG. 18H illustrates an example of an SRAM (Static Random Access Memory) using an OS transistor. In this specification and the like, an SRAM using an OS transistor is referred to as an OS-SRAM (Oxide Semiconductor-SRAM). A memory cell 958 illustrated in FIG. 18H is a memory cell of an SRAM capable of backup operation.

The memory cell 958 includes a transistor M7 to a transistor M10, a transistor MS1 to a transistor MS4, a capacitor CD1, and a capacitor CD2. Note that the transistor MS1 and the transistor MS2 are p-channel transistors, and the transistor MS3 and the transistor MS4 are n-channel transistors.

A first terminal of the transistor M7 is connected to the wiring BIL, and a second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB, and a second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is electrically connected to a wiring VDL. A second terminal of the transistor MS2 is electrically connected to the wiring VDL. A second terminal of the transistor MS3 is electrically connected to the wiring GNDL. A second terminal of the transistor MS4 is electrically connected to the wiring GNDL.

A second terminal of the transistor M9 is connected to a first terminal of the capacitor CD1, and a gate of the transistor M9 is connected to a wiring BRL. A second terminal of the transistor M10 is connected to a first terminal of the capacitor CD2, and a gate of the transistor M10 is connected to the wiring BRL.

A second terminal of the capacitor CD1 is connected to the wiring GNDL, and a second terminal of the capacitor CD2 is connected to the wiring GNDL.

The wiring BIL and the wiring BILB function as bit lines, the wiring WOL functions as a word line, and the wiring BRL is a wiring that controls the on state and the off state of the transistor M9 and the transistor M10.

The wiring VDL is a wiring supplying a high-level potential, and the wiring GNDL is a wiring supplying a low-level potential.

Data writing is performed by applying a high-level potential to the wiring WOL and applying a high-level potential to the wiring BRL. Specifically, when the transistor M10 is in an on state, a potential corresponding to information to be stored is applied to the wiring BIL, and the potential is written to the second terminal side of the transistor M10.

In the memory cell 958, the transistor MS1 to the transistor MS2 form an inverter loop; hence, an inversion signal of a data signal corresponding to the potential is input to the second terminal side of the transistor M8. Since the transistor M8 is in an on state, an inversion signal of the potential applied to the wiring BIL, i.e., the signal input to the wiring BIL, is output to the wiring BILB. Since the transistor M9 and the transistor M10 are in an on state, the potential of the second terminal of the transistor M7 is retained at the first terminal of the capacitor CD2, and the potential of the second terminal of the transistor M8 is retained at the first terminal of the capacitor CD1. After that, a low-level potential is applied to the wiring WOL and a low-level potential is applied to the wiring BRL to turn off the transistor M7 to the transistor M10, whereby the potentials of the first terminal of the capacitor CD1 and the first terminal of the capacitor CD2 are retained.

Data reading is performed as follows: the wiring BIL and the wiring BILB are precharged to a predetermined potential in advance and then a high-level potential is applied to the wiring WOL and a high-level potential is applied to the wiring BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potential of the first terminal of the capacitor CD2 and the potential of the first terminal of the capacitor CD1, respectively, the potential retained in the memory cell can be read on the basis of the potential of the wiring BIL or the wiring BILB.

Note that OS transistors are preferably used as the transistor M7 to the transistor M10. Thus, with the use of the transistor M7 to the transistor M10, written data can be retained for a long time; hence, the frequency of refresh operation for the memory cell can be decreased. Alternatively, refresh operation for the memory cell can be unnecessary. The use of the OS transistors described in the above embodiment as the transistor M7 to the transistor M10 enables a reduction in the area occupied by the memory cell.

Note that Si transistors may be used as the transistor MS1 to the transistor MS4.

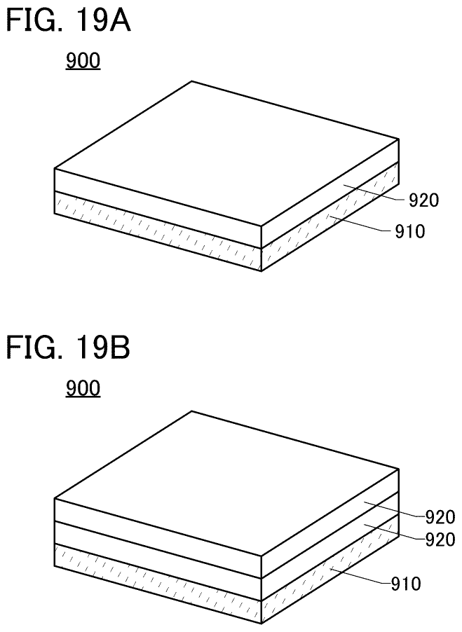

The driver circuit 910 and the memory array 920 included in the semiconductor device 900 may be provided on the same plane. Alternatively, as illustrated in FIG. 19A, the driver circuit 910 and the memory array 920 may be provided to overlap with each other. When the driver circuit 910 and the memory array 920 are provided to overlap with each other, the signal transmission distance can be shortened. As illustrated in FIG. 19B, a plurality of the memory arrays 920 may be stacked over the driver circuit 910.

Next, description is made on an example of an arithmetic processing device that can include a semiconductor device such as the memory device described above.

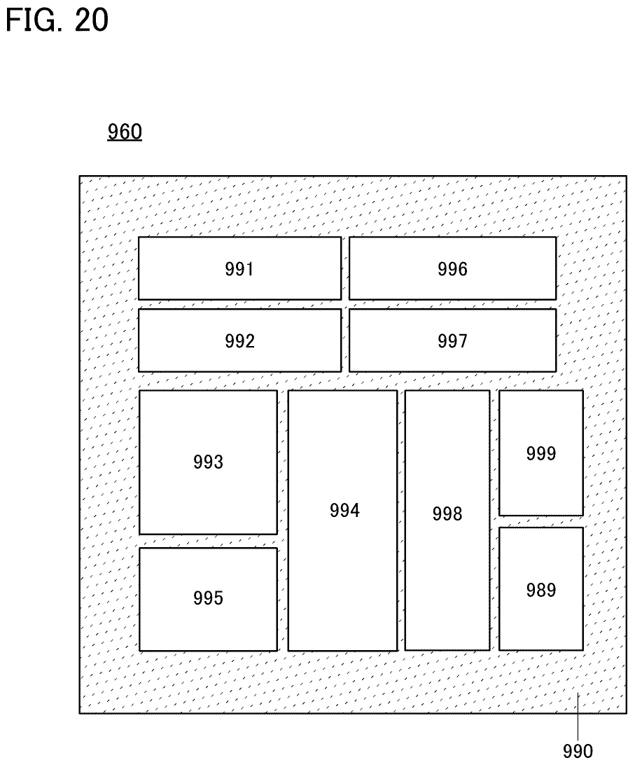

FIG. 20 illustrates a block diagram of an arithmetic device 960. The arithmetic device 960 illustrated in FIG. 20 can be used for a CPU, for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic device 960 illustrated in FIG. 20 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. A rewritable ROM and a ROM interface may be included. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. In that case, the cache interface 989 may have a function of supplying data retained in the memory array 920 to the cache 999. Moreover, in that case, the driver circuit 910 is preferably included in part of the cache interface 989.

Note that it is also possible that the cache 999 is not provided and only the memory array 920 is used as a cache.

The arithmetic device 960 illustrated in FIG. 20 is only an example with a simplified structure, and the actual arithmetic device 960 has a variety of structures depending on the application. For example, it is preferable to employ what is called a multicore structure in which a plurality of cores each including the arithmetic device 960 illustrated in FIG. 20 operate in parallel. The larger number of cores can further enhance the arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, which is then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads or writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 illustrated in FIG. 20, the register controller 997 selects a retention operation in the register 996 in accordance with an instruction from the ALU 991. That is, the register controller 997 selects whether data is retained by a flip-flop or by a capacitor in a memory cell included in the register 996. When data retention by the flip-flop is selected, a power supply voltage is supplied to the memory cell in the register 996. When data retention by the capacitor is selected, the data is rewritten into the capacitor, and supply of the power supply voltage to the memory cell in the register 996 can be stopped.

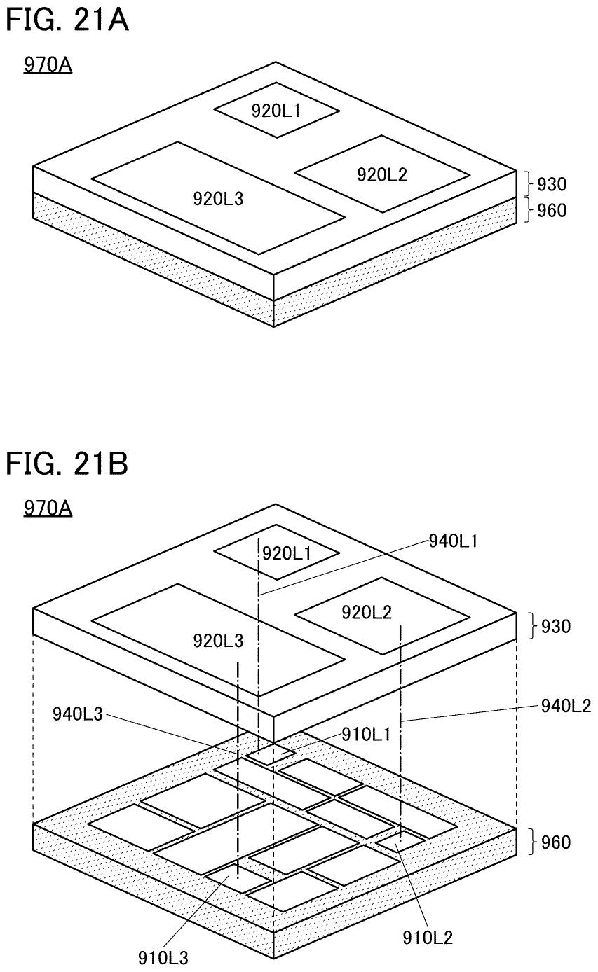

The memory array 920 and the arithmetic device 960 can be provided to overlap with each other. FIG. 21A and FIG. 21B are perspective views of a semiconductor device 970A. The semiconductor device 970A includes, over the arithmetic device 960, a layer 930 provided with memory arrays. A memory array 920L1, a memory array 920L2, and a memory array 920L3 are provided in the layer 930. The arithmetic device 960 and each of the memory arrays include an overlapping region. For easy understanding of the structure of the semiconductor device 970A, the arithmetic device 960 and the layer 930 are separately illustrated in FIG. 21B.

Providing the arithmetic device 960 and the layer 930 including the memory arrays to overlap with each other can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960 (also referred to as monolithic stacking) and a method in which the arithmetic device 960 and the layer 930 are formed over different substrates, the two substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the fabrication cost can be reduced.

Here, it is possible that the arithmetic device 960 does not include the cache 999 and the memory arrays 920L1, 920L2, and 920L3 provided in the layer 930 are each used as a cache. In that case, for example, the memory array 920L1 can be used as an L1 cache (also referred to as a level 1 cache), the memory array 920L2 can be used as an L2 cache (also referred to as a level 2 cache), and the memory array 920L3 can be used as an L3 cache (also referred to as a level 3 cache). Among the three memory arrays, the memory array 920L3 has the highest capacity and the lowest access frequency. The memory array 920L1 has the lowest capacity and the highest access frequency.

In the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 21B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that the case where the number of memory arrays functioning as caches is three is described here; however, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or be connected to the cache interface 989.

Whether the memory array 920 functions as the cache or the main memory is determined by the control circuit 912 included in each of the driver circuits 910. The control circuit 912 can make some of the plurality of memory cells 950 included in the semiconductor device 900 function as RAM in accordance with a signal supplied from the arithmetic device 960.

In the semiconductor device 900, some of the plurality of memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

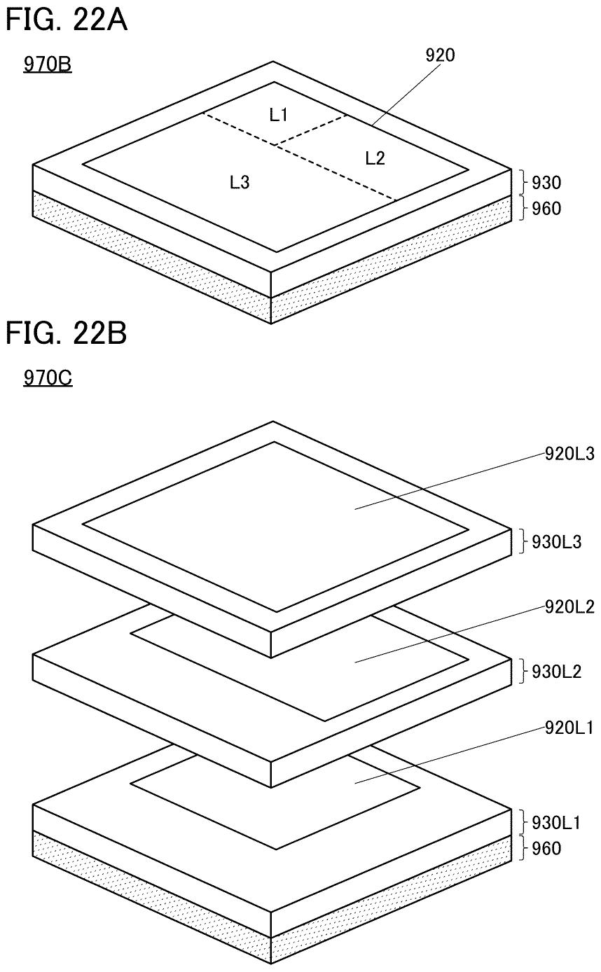

The layer 930 including one memory array 920 may be provided to overlap with the arithmetic device 960. FIG. 22A is a perspective view of a semiconductor device 970B.

In the semiconductor device 970B, one memory array 920 can be divided into a plurality of areas having different functions. FIG. 22A illustrates an example of the case where a region L1, a region L2, and a region L3 are used as the L1 cache, the L2 cache, and the L3 cache, respectively.

In the semiconductor device 970B, the capacity of each of the region LI to the region L3 can be changed depending on circumstances. For example, the capacity of the L1 cache can be increased by increasing the area of the region L1. With such a structure, the arithmetic processing efficiency can be improved and the processing speed can be increased.

Alternatively, a plurality of memory arrays may be stacked. FIG. 22B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L 1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

Note that this embodiment can be combined with other embodiments and examples in this specification as appropriate.

### Embodiment 3

In this embodiment, application examples of the memory device of one embodiment of the present invention will be described.

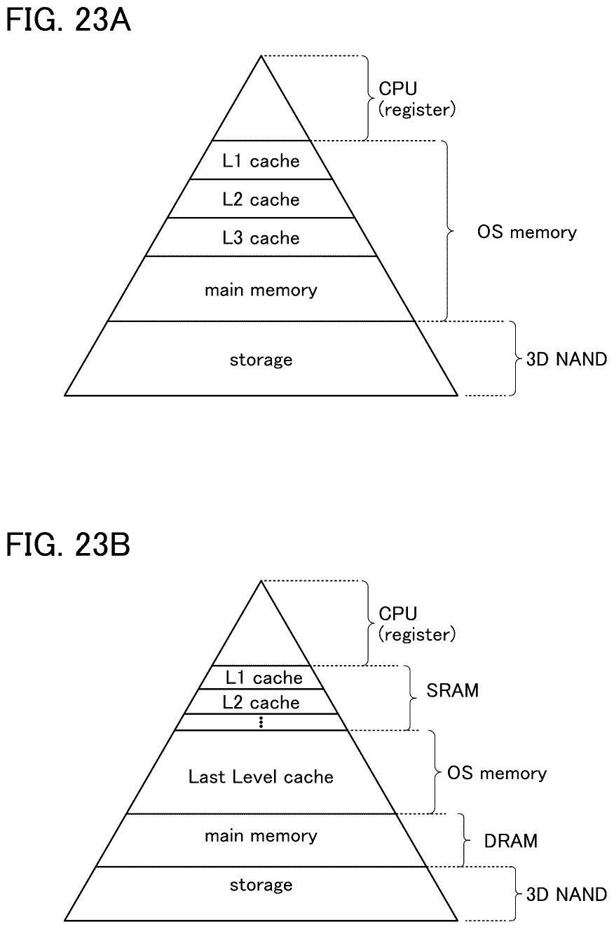

In general, a variety of memory devices are used in semiconductor devices such as computers in accordance with the intended use. FIG. 23A shows the hierarchy of various memory devices used in semiconductor devices. The memory devices at the upper levels require higher operating speed, whereas the memory devices at the lower levels require higher memory capacity and higher memory density. FIG. 23A shows, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may further be included.

A memory included as a register in an arithmetic processing device such as a CPU is used for temporary storage of arithmetic operation results, for example, and thus is very frequently accessed by the arithmetic processing device. Accordingly, high operating speed is required rather than memory capacity. The register also has a function of retaining setting information of the arithmetic processing device, for example.

The cache has a function of duplicating and retaining part of data retained in the main memory. Duplicating frequently used data and retaining the duplicated data in the cache facilitate rapid data access. The cache requires a lower memory capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be stored for a long time and a variety of programs used in the arithmetic processing device, for example. Therefore, the storage needs to have a high memory capacity and a high memory density rather than operating speed. For example, a high-capacity nonvolatile memory device such as a 3D NAND can be used.

The memory device using an oxide semiconductor (the OS memory) of one embodiment of the present invention operates at high speed and can retain data for a long time. Thus, as shown in FIG. 23A, the memory device of one embodiment of the present invention can be suitably used for devices at both the level including the cache and the level including the main memory. The memory device of one embodiment of the present invention can also be used at the level including the storage.

FIG. 23B shows an example of the case where an SRAM is used as some of the caches and the OS memory of one embodiment of the present invention is used as the other cache.

Among the caches, the lowest-level cache can be referred to as an LLC (Last Level Cache). The LLC does not require a higher operating speed than a higher-level cache, but desirably has a high memory capacity. The OS memory of one embodiment of the present invention operates at high speed and can retain data for a long time, and thus can be suitably used as the LLC. Note that the OS memory of one embodiment of the present invention can also be used as an FLC (Final Level Cache).

For example, as shown in FIG. 23B, an SRAM can be used as the higher-level caches (the L1 cache, the L2 cache, and the like), and the OS memory of one embodiment of the present invention can be used as the LLC. Moreover, not only the OS memory but also a DRAM can be used as the main memory as shown in FIG. 23B.

Note that this embodiment can be combined with other embodiments and examples in this specification as appropriate.

### Embodiment 4

This embodiment will describe an electronic component, an electronic device, a large computer, space equipment, and a data center (also referred to as a DC) in which the semiconductor device described in the above embodiment can be used. An electronic device, a large computer, space equipment, and a data center in which the semiconductor device of one embodiment of the present invention is used are effective in improving performance, e.g., reducing power consumption.

### [Electronic Device]

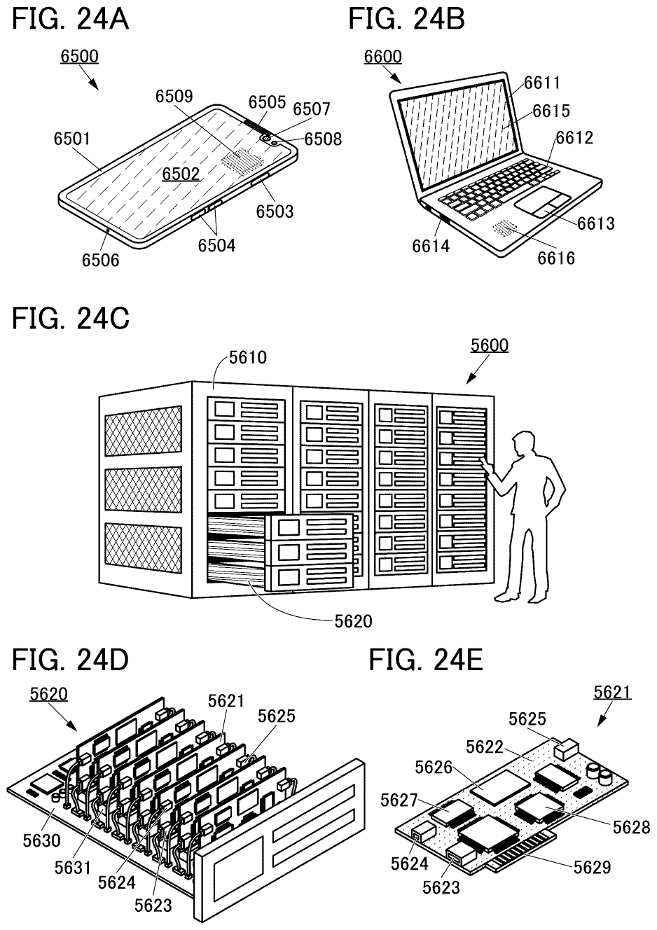

Next, FIG. 24A is a perspective view of an electronic device 6500. The electronic device 6500 illustrated in FIG. 24A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are provided as the control device 6509, for example. The semiconductor device of one embodiment of the present invention can be used for the display portion 6502, the control device 6509, and the like.

An electronic device 6600 illustrated in FIG. 24B is an information terminal that can be used as a laptop personal computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 24C is a perspective view of a large computer 5600. In the large computer 5600 illustrated in FIG. 24C, a plurality of rack mount computers 5620 are stored in a rack 5610. Note that the large computer 5600 may be referred to as a supercomputer.

The computer 5620 can have a structure in a perspective view of FIG. 24D, for example. In FIG. 24D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 24E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 24E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include USB, SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

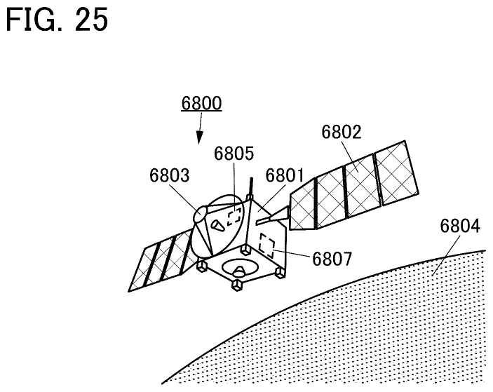

FIG. 25 illustrates an artificial satellite 6800 as an example of space equipment. The artificial satellite 6800 includes a body 6801, a solar panel 6802, an antenna 6803, a secondary battery 6805, and a control device 6807. FIG. 25 illustrates a planet 6804 in outer space, for example. Note that outer space refers to, for example, space at an altitude greater than or equal to 100 km, and outer space in this specification also includes thermosphere, mesosphere, and stratosphere in some cases.

Although not illustrated in FIG. 25, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed using one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. For example, the semiconductor device of one embodiment of the present invention can be suitably used for space equipment such as a spacecraft, a space capsule, or a space probe.

As described above, the OS transistor has advantageous effects over the Si transistor, such as a wide memory bandwidth and high radiation resistance.

### [Data Center]

The semiconductor device of one embodiment of the present invention can be suitably used for a storage system in a data center or the like, for example. Long-term data management, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, or the like.

With the use of the semiconductor device of one embodiment of the present invention for the storage system used in the data center, electric power required for data retention can be reduced and a semiconductor device retaining data can be downsized. Thus, downsizing of the storage system, downsizing of a power source for data retention, downscaling of the cooling equipment, and the like can be achieved. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

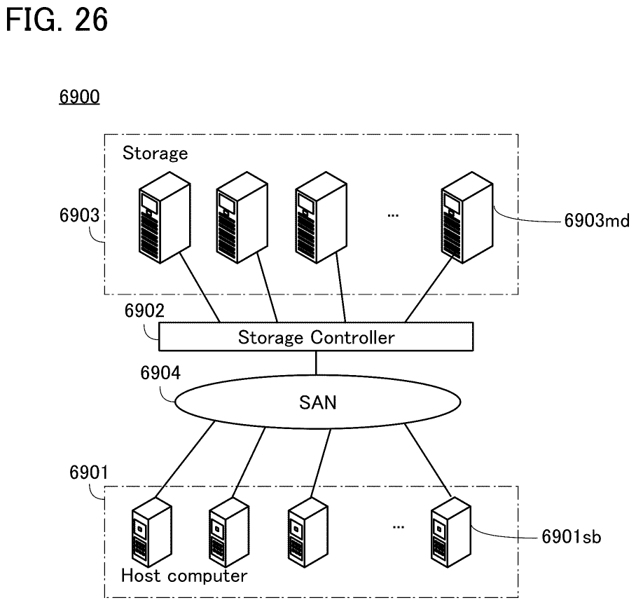

FIG. 26 illustrates a storage system that can be used in a data center. A storage system 6900 illustrated in FIG. 26 includes a plurality of servers 6901 sb as a host 6901 (indicated as “Host Computer” in the diagram). The storage system 6900 includes a plurality of memory devices 6903md as a storage 6903 (indicated as “Storage” in the diagram). In the illustrated mode, the host 6901 and the storage 6903 are connected to each other through a storage area network 6904 (indicated as “SAN” in the diagram) and a storage control circuit 6902 (indicated as “Storage Controller” in the diagram).

The host 6901 corresponds to a computer that accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in a storage. In the storage system, in order to solve the problem of low access speed of the storage 6903, a cache memory is normally provided in the storage to shorten the time required for data storage and output.

The above-described cache memory is used in the storage control circuit 6902 and the storage 6903. Data transmitted between the host 6901 and the storage 6903 is stored in the cache memory in the storage control circuit 6902 and the storage 6903 and then output to the host 6901 or the storage 6903.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

The configuration, structure, method, or the like described in this embodiment can be used in combination with the configuration, structure, method, or the like described in the other embodiments, examples, and the like as appropriate.

### Embodiment 5

This embodiment will describe structure examples of a display device that can use the transistor of one embodiment of the present invention.

Since the transistor of one embodiment of the present invention can be extremely minute, a display device using the transistor of one embodiment of the present invention can have an extremely high resolution. For example, a display device of one embodiment of the present invention can be used for display portions of information terminals (wearable devices) such as watch-type and bracelet-type information terminals and display portions of devices capable of being worn on a head, such as VR devices like head-mounted displays (HMDs) and glasses-type AR devices.

### [Display Module]

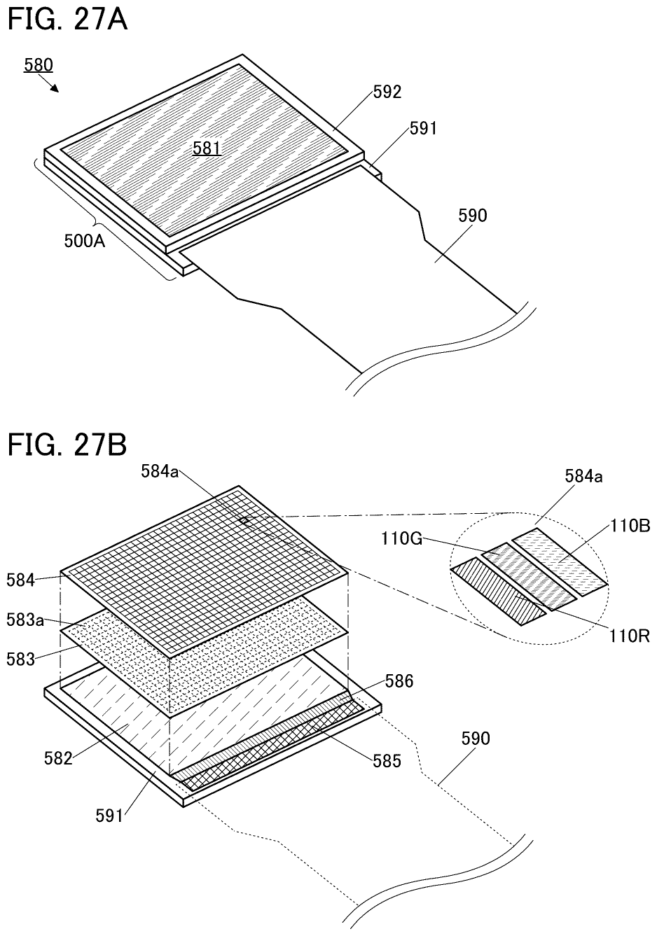

FIG. 27A is a perspective view of a display module 580. The display module 580 includes a display device 500A and an FPC 590. Note that a display panel included in the display module 580 is not limited to the display device 500A and may be a display device 500C described later.

The display module 580 includes a substrate 591 and a substrate 592. The display module 580 includes a display portion 581. The display portion 581 is a region where an image is displayed.

FIG. 27B is a perspective view schematically illustrating a structure on the substrate 591 side. Over the substrate 591, a circuit portion 582, a pixel circuit portion 583 over the circuit portion 582, and a pixel portion 584 over the pixel circuit portion 583 are stacked. A terminal portion 585 to be connected to the FPC 590 is provided over the substrate 591 in a portion that does not overlap with the pixel portion 584. The terminal portion 585 and the circuit portion 582 are electrically connected to each other through a wiring portion 586 formed of a plurality of wirings.

The pixel portion 584 includes a plurality of pixels 584a arranged periodically. An enlarged view of one pixel 584a is illustrated on the right side in FIG. 27B. The pixel 584a includes a light-emitting element 110R that emits red light, a light-emitting element 110G that emits green light, and a light-emitting element 110B that emits blue light.

The pixel circuit portion 583 includes a plurality of pixel circuits 583a arranged periodically. One pixel circuit 583a is a circuit for controlling light emission of three light-emitting devices included in one pixel 584a. One pixel circuit 583a may be provided with three circuits each controlling light emission of one light-emitting device. For example, the pixel circuit 583a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is achieved.

The circuit portion 582 includes a circuit for driving the pixel circuits 583a in the pixel circuit portion 583. For example, the circuit portion 582 preferably includes one or both of a gate line driver circuit and a source line driver circuit. The circuit portion 582 may also include at least one of an arithmetic circuit, a memory circuit, a power supply circuit, and the like. In addition, a transistor provided in the circuit portion 582 may constitute part of the pixel circuit 583a. That is, the pixel circuit 583a may be constituted by a transistor included in the pixel circuit portion 583 and a transistor included in the circuit portion 582.

The FPC 590 functions as a wiring for supplying a video signal, a power supply potential, and the like to the circuit portion 582 from the outside. An IC may be mounted on the FPC 590.

The display module 580 can have a structure in which one or both of the pixel circuit portion 583 and the circuit portion 582 are provided to be stacked below the pixel portion 584; thus, the aperture ratio (effective display area ratio) of the display portion 581 can be significantly high. For example, the aperture ratio of the display portion 581 can be greater than or equal to 40 % and less than 100%, preferably greater than or equal to 50% and less than or equal to 95%, further preferably greater than or equal to 60% and less than or equal to 95%. Furthermore, the pixels 584a can be arranged extremely densely and thus the display portion 581 can have an extremely high resolution. For example, the pixels 584a are preferably arranged in the display portion 581 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 580 has an extremely high resolution, and thus can be suitably used for a VR device such as a head-mounted display or a glasses-type AR device. For example, even with a structure in which the display portion of the display module 580 is seen through a lens, pixels of the extremely-high-resolution display portion 581 included in the display module 580 are prevented from being recognized when the display portion is magnified by the lens, so that display providing a high sense of immersion can be performed. Without being limited thereto, the display module 580 can be suitably used for electronic devices including a relatively small display portion. For example, the display module 580 can be suitably used for a display portion of a wearable electronic device such as a wristwatch.

[Display Device 500a]

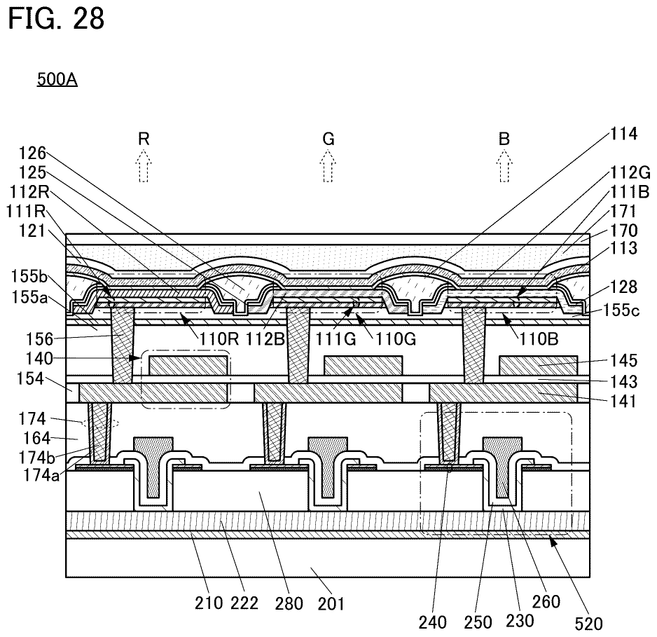

The display device 500A illustrated in FIG. 28 includes a substrate 201, the light-emitting element 110R, the light-emitting element 110G, the light-emitting element 110B, a capacitor 140, and a transistor 520.

The substrate 201 corresponds to the substrate 591 in FIG. 27A.

The transistor 520 is a vertical-channel transistor using an oxide semiconductor in a semiconductor layer where a channel is formed. The transistor 520 includes the oxide semiconductor 230, the insulator 250, the conductor 260, the conductor 240, and the like.

As the transistor 520, a variety of transistors exemplified in Embodiment 2 can be used. For example, as illustrated in FIG. 28, the transistor 200E illustrated in FIG. 15A to FIG. 15D can be used as the transistor 520. As illustrated in FIG. 16A and FIG. 16B, the transistor 200 may be further provided in the same layer.

The insulator 210 is provided over the substrate 201. The insulator 210 functions as a barrier layer that prevents diffusion of impurities such as water and hydrogen from the substrate 201 into the transistor 520 and release of oxygen from the oxide semiconductor 230 to the insulator 210 side. As the insulator 210, for example, a film in which hydrogen or oxygen is less likely to diffuse than in a silicon oxide film, such as an aluminum oxide film, a hafnium oxide film, or a silicon nitride film, can be used.

The insulator 222 is provided over the insulator 210. The insulator 222 functions as an insulating film that captures or fixes hydrogen contained in the insulator 280, the oxide semiconductor 230, and the like. As the insulator 222, a hafnium silicate film or the like can be used, for example.

The insulator 280 is provided over the insulator 222, and the conductor 240 is provided over the insulator 280. An opening is provided in the insulator 280, and the oxide semiconductor 230, the insulator 250, and the conductor 260 are provided in the opening. An insulating layer 164 is provided to cover the conductor 260.

The insulating layer 164 functions as an interlayer insulating layer. A barrier layer that prevents diffusion of impurities such as water and hydrogen from the insulating layer 164 or the like into the transistor 520 may be provided between the insulating layer 164 and an insulating layer 154. As the barrier layer, an insulating film similar to the insulator 210 can be used.

A plug 174 electrically connected to one of the conductors 240 is provided to be embedded in the insulating layer 164. Here, the plug 174 preferably includes a conductive layer 174a that covers the side surface of the opening in the insulating layer 164 and part of the top surface of the conductor 240, and a conductive layer 174b in contact with the top surface of the conductive layer 174a. In that case, for the conductive layer 174a, a conductive material that does not easily allow diffusion of hydrogen and oxygen is preferably used.

The capacitor 140 is provided over the insulating layer 164. The capacitor 140 includes a conductive layer 141, a conductive layer 145, and an insulating layer 143 positioned therebetween. The conductive layer 141 functions as one electrode of the capacitor 140, the conductive layer 145 functions as the other electrode of the capacitor 140, and the insulating layer 143 functions as a dielectric of the capacitor 140.

The conductive layer 141 is provided over the insulating layer 164 and is embedded in the insulating layer 154. The conductive layer 141 is electrically connected to the conductor 240 in the transistor 520 through the plug 174. The insulating layer 143 is provided to cover the conductive layer 141. The conductive layer 145 is provided in a region overlapping with the conductive layer 141 with the insulating layer 143 therebetween.

An insulating layer 155a is provided to cover the capacitor 140, an insulating layer 155b is provided over the insulating layer 155a, and an insulating layer 155c is provided over the insulating layer 155b.

An inorganic insulating film can be suitably used as each of the insulating layer 155a, the insulating layer 155b, and the insulating layer 155c. For example, it is preferable that a silicon oxide film be used as each of the insulating layer 155a and the insulating layer 155c and that a silicon nitride film be used as the insulating layer 155b. This enables the insulating layer 155b to function as an etching protective film. Although this embodiment describes an example in which the insulating layer 155c is partly etched and a depressed portion is formed, the depressed portion is not necessarily provided in the insulating layer 155c.

The light-emitting element 110R, the light-emitting element 110G, and the light-emitting element 110B are provided over the insulating layer 155c.

The light-emitting element 110R includes a pixel electrode 111R, an organic layer 112R, a common layer 114, and a common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting organic compound (a light-emitting layer).

Since the light-emitting devices of different colors are separately formed in the display device 500A, a difference in chromaticity between light emission at low luminance and light emission at high luminance is small. Furthermore, since the organic layers 112R, 112G, and 112B are apart from each other, crosstalk generated between adjacent subpixels can be inhibited even when the display panel has a high resolution. It is thus possible to achieve a display panel that has a high resolution and high display quality.

In a region between adjacent light-emitting elements, an insulating layer 125, a resin layer 126, and a layer 128 are provided.

The pixel electrode 111R, the pixel electrode 111G, and the pixel electrode 111B of the light-emitting elements are each electrically connected to the conductor 240 in the transistor 520 through a plug 156 that is embedded in the insulating layer 155a, the insulating layer 155b, and the insulating layer 155c, the conductive layer 141 that is embedded in the insulating layer 154, and the plug 174. The top surface of the insulating layer 155c and the top surface of the plug 156 are level with or substantially level with each other. A variety of conductive materials can be used for the plugs.

A protective layer 121 is provided over the light-emitting elements 110R, 110G, and 110B. A substrate 170 is attached onto the protective layer 121 with an adhesive layer 171.

An insulating layer covering the end portion of the top surface of the pixel electrode 111 is not provided between two adjacent pixel electrodes 111. Thus, the distance between adjacent light-emitting elements can be extremely short. Accordingly, the display device can have a high resolution or a high definition.

[Display Device 500c]

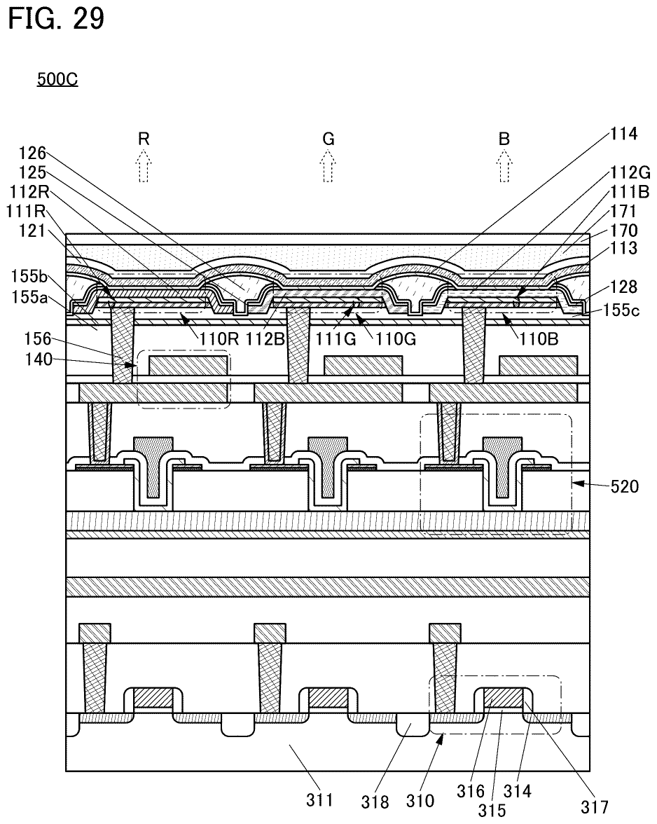

The display device 500C illustrated in FIG. 29 has a structure in which a transistor 310 whose channel is formed in a semiconductor substrate and the transistor 520 that is a vertical-channel transistor are stacked.

The transistor 310 is a transistor including a channel formation region in a substrate 311. As the substrate 311, a semiconductor substrate such as a single crystal silicon substrate can be used, for example. The transistor 310 includes part of the substrate 311, a conductor 316, low-resistance regions 314, an insulator 315, and an insulator 317. The conductor 316 functions as a gate electrode. The insulator 315 is positioned between the substrate 311 and the conductor 316 and functions as a gate insulating layer. The low-resistance region 314 is a region where the substrate 311 is doped with an impurity, and functions as one of a source and a drain. The insulator 317 is provided to cover the side surface of the conductor 316.

An element isolation layer 318 is provided between two adjacent transistors 310 to be embedded in the substrate 311.

At least part of this embodiment can be implemented in combination with the other embodiments and examples described in this specification as appropriate.

### Embodiment 6

This embodiment will describe structure examples of a display device that can be used as a display device fabricated using the transistor of one embodiment of the present invention. The display device exemplified below can be used for the pixel portion 584 in Embodiment 5, for example.

One embodiment of the present invention is a display device including a light-emitting element (also referred to as a light-emitting device). The display device includes two or more pixels of different emission colors. The pixels include light-emitting elements. The light-emitting elements each include a pair of electrodes and an EL layer therebetween. The light-emitting elements are preferably organic EL elements (organic electroluminescent elements). Two or more light-emitting elements of different emission colors include EL layers including different light-emitting materials. For example, when three kinds of light-emitting elements that emit red (R), green (G), and blue (B) light are included, a full-color display device can be achieved.

In the case of fabricating a display device including a plurality of light-emitting elements of different emission colors, at least layers containing light-emitting materials (light-emitting layers) each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a formed film due to vapor scattering, for example; accordingly, it is difficult to achieve a high resolution and a high aperture ratio of the display device. In addition, the outline of the layer might blur during evaporation, so that the thickness of an end portion might be reduced. That is, the thickness of an island-shaped light-emitting layer might vary from place to place. In addition, in the case of fabricating a display device with a large size, a high definition, or a high resolution, the manufacturing yield might be reduced because of low dimensional accuracy of the metal mask and deformation due to heat or the like. Thus, measures have been taken for a pseudo increase in resolution (also referred to as pixel density) by employing unique pixel arrangement such as PenTile arrangement.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by photolithography without using a shadow mask such as an FMM (Fine Metal Mask). Accordingly, it is possible to achieve a display device with a high resolution and a high aperture ratio, which has been difficult to achieve so far. Moreover, since the EL layers can be formed separately, it is possible to achieve a display device that performs extremely clear display with high contrast and high display quality. Note that fine patterning of the EL layers may be performed using both a metal mask and photolithography, for example.

In addition, part or the whole of the EL layer can be physically divided. This can inhibit leakage current flowing between adjacent light-emitting elements through a layer shared by the light-emitting elements (also referred to as a common layer). This can prevent unintended light emission due to crosstalk, so that a display device with extremely high contrast can be obtained. Specifically, a display device having high current efficiency at low luminance can be obtained.

In one embodiment of the present invention, the display device can also be obtained by combining a light-emitting element that emits white light with a color filter. In that case, light-emitting elements having the same structure can be used as light-emitting elements provided in pixels (subpixels) that emit light of different colors, which allows all the layers to be common layers. In addition, part or the whole of each EL layer may be divided by photolithography. Thus, leakage current through the common layer is inhibited; accordingly, a display device with high contrast can be achieved. In particular, when an element has a tandem structure in which a plurality of light-emitting layers are stacked with a highly conductive intermediate layer therebetween, leakage current through the intermediate layer can be effectively prevented, so that a display device with high luminance, a high resolution, and high contrast can be achieved.

In the case where the EL layer is processed by a photolithography method, part of the light-emitting layer is sometimes exposed to cause deterioration. Thus, an insulating layer covering at least the side surface of the island-shaped light-emitting layer is preferably provided. The insulating layer may cover part of the top surface of the island-shaped EL layer. For the insulating layer, a material having a barrier property against water and oxygen is preferably used. For example, an inorganic insulating film that is less likely to diffuse water or oxygen can be used. This can inhibit deterioration of the EL layer and can achieve a highly reliable display device.

Moreover, between two adjacent light-emitting elements, there is a region (a depressed portion) where none of the EL layers of the light-emitting elements is provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a structure is preferably employed in which a local gap positioned between two adjacent light-emitting elements is filled with a resin layer functioning as a planarization film (also referred to as LFP: Local Filling Planarization). The resin layer has a function of a planarization film. This structure can inhibit disconnection of the common layer or the common electrode and can achieve a highly reliable display device.

More specific structure examples of the display device of one embodiment of the present invention will be described below with reference to drawings.

### Structure Example 1

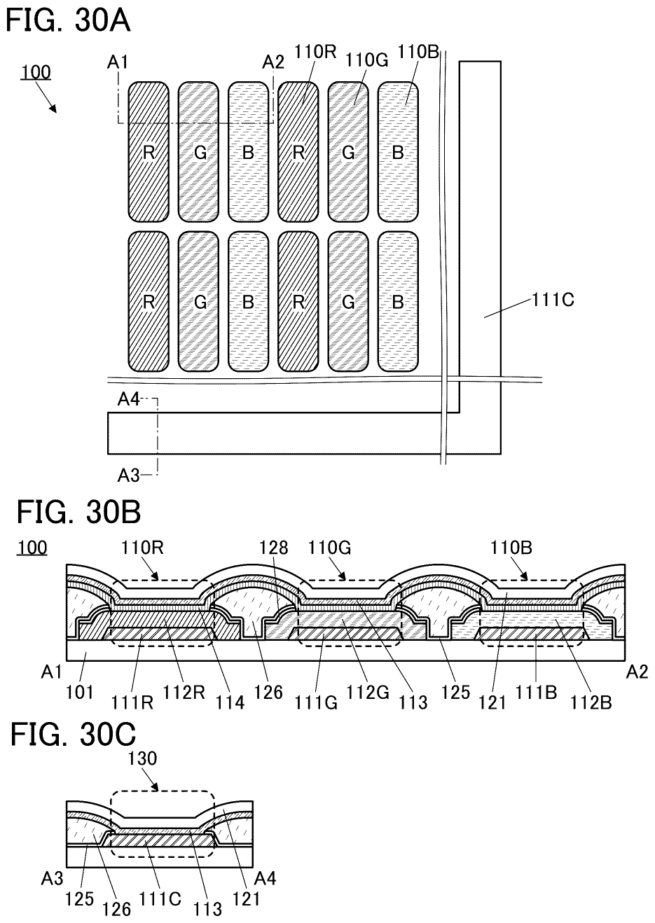

FIG. 30A is a schematic top view of a display device 100 of one embodiment of the present invention. The display device 100 includes, over a substrate 101, a plurality of the light-emitting elements 110R exhibiting red, a plurality of the light-emitting elements 110G exhibiting green, and a plurality of the light-emitting elements 110B exhibiting blue. In FIG. 30A, light-emitting regions of the light-emitting elements are denoted by R, G, and B to easily differentiate the light-emitting elements.

The light-emitting elements 110R, the light-emitting elements 110G, and the light-emitting elements 110B are arranged in a matrix. FIG. 30A illustrates what is called stripe arrangement, in which the light-emitting elements of the same color are arranged in one direction. Note that an arrangement method of the light-emitting elements is not limited thereto; an arrangement method such as S-stripe arrangement, delta arrangement, Bayer arrangement, or zigzag arrangement may be employed, or PenTile arrangement, diamond arrangement, or the like can also be used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. Examples of a light-emitting substance contained in the EL element include a substance that emits fluorescent light (a fluorescent material), a substance that emits phosphorescent light (a phosphorescent material), and a substance that exhibits thermally activated delayed fluorescence (a thermally activated delayed fluorescent (TADF) material). As the light-emitting substance contained in the EL element, not only an organic compound but also an inorganic compound (a quantum dot material or the like) can be used.

FIG. 30A also illustrates a connection electrode 111C electrically connected to the common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region, or the connection electrode 111C may be provided along two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrangular shape, or the like.

FIG. 30B and FIG. 30C are schematic cross-sectional views corresponding to the dashed-dotted line A1-A2 and the dashed-dotted line A3-A4 in FIG. 30A. FIG. 30B is a schematic cross-sectional view of the light-emitting element 110R, the light-emitting element 110G, and the light-emitting element 110B, and FIG. 30C is a schematic cross-sectional view of a connection portion 130 where the connection electrode 111C and the common electrode 113 are connected to each other.

The light-emitting element 110R includes the pixel electrode 111R, the organic layer 112R, the common layer 114, and the common electrode 113. The light-emitting element 110G includes the pixel electrode 111G, the organic layer 112G, the common layer 114, and the common electrode 113. The light-emitting element 110B includes the pixel electrode 111B, the organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 has a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. The common electrode 113 and the common layer 114 are each provided as one continuous layer shared by the light-emitting elements. A conductive film having a light-transmitting property with respect to visible light is used for either the pixel electrodes or the common electrode 113, and a conductive film having a reflective property is used for the other. When the pixel electrodes have a light-transmitting property and the common electrode 113 has a reflective property, a bottom-emission display device can be obtained. By contrast, when the pixel electrodes have a reflective property and the common electrode 113 has a light-transmitting property, a top-emission display device can be obtained. Note that when both the pixel electrodes and the common electrode 113 have a light-transmitting property, a dual-emission display device can be obtained.

The protective layer 121 is provided over the common electrode 113 to cover the light-emitting elements 110. The protective layer 121 has a function of preventing diffusion of impurities such as water into the light-emitting elements from the above.

The end portion of the pixel electrode 111 preferably has a tapered shape. In the case where the end portion of the pixel electrode 111 has a tapered shape, the organic layer 112 provided along the end portion of the pixel electrode 111 can also have a tapered shape. When the end portion of the pixel electrode 111 has a tapered shape, coverage with the organic layer 112 provided beyond the end portion of the pixel electrode 111 can be increased. The side surface of the pixel electrode 111 preferably has a tapered shape, in which case a foreign matter (also referred to as dust or particles, for example) in the fabrication process is easily removed by processing such as cleaning.

The organic layer 112 is processed into an island shape by a photolithography method. Thus, an angle formed between the top surface and the side surface of the end portion of the organic layer 112 is approximately 90°. By contrast, an organic film formed using an FMM or the like has a thickness that tends to gradually decrease with decreasing distance to the end portion, and has a top surface forming a slope in an area extending greater than or equal to 1 μm and less than or equal to 10 μm to the end portion, for example; thus, such an organic film has a shape whose top surface and side surface are difficult to distinguish from each other.

The insulating layer 125, the resin layer 126, and the layer 128 are included between two adjacent light-emitting elements.

Between two adjacent light-emitting elements, the side surfaces of the organic layers 112 are provided to face each other with the resin layer 126 therebetween. The resin layer 126 is positioned between the two adjacent light-emitting elements and is provided to bury the end portions of the organic layers 112 and a region between the two organic layers 112. The resin layer 126 has a top surface with a smooth protruding shape, and the common layer 114 and the common electrode 113 are provided to cover the top surface of the resin layer 126.

The resin layer 126 functions as a planarization film that fills a step positioned between two adjacent light-emitting elements. Providing the resin layer 126 can prevent disconnection of the common electrode 113 due to a step at an end portion of the organic layer 112 from occurring and the common electrode over the organic layer 112 from being insulated. Here, the resin layer 126 functions as an LFP.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used as the photosensitive resin. As the photosensitive resin, a material of positive type or a material of negative type can be used.

The resin layer 126 may include a material absorbing visible light. For example, the resin layer 126 itself may be made of a material absorbing visible light, or the resin layer 126 may include a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surface of the organic layer 112. In addition, the insulating layer 125 is provided to cover an upper end portion of the organic layer 112. Furthermore, part of the insulating layer 125 is provided in contact with the top surface of the substrate 101.

The insulating layer 125 is positioned between the resin layer 126 and the organic layer 112 and functions as a protective film for preventing the resin layer 126 from being in contact with the organic layer 112. When the organic layer 112 and the resin layer 126 are in contact with each other, the organic layer 112 might be dissolved by an organic solvent or the like used at the time of forming the resin layer 126. Thus, providing the insulating layer 125 between the organic layer 112 and the resin layer 126 can protect the side surface of the organic layer 112.

An insulating layer including an inorganic material can be used as the insulating layer 125. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is used for the insulating layer 125, it is possible to form the insulating layer 125 that has a small number of pinholes and has an excellent function of protecting the EL layer.

In this specification and the like, oxynitride refers to a material having a composition in which the oxygen content is higher than the nitrogen content, and nitride oxide refers to a material having a composition in which the nitrogen content is higher than the oxygen content. For example, silicon oxynitride refers to a material having a composition in which the oxygen content is higher than the nitrogen content, and silicon nitride oxide refers to a material having a composition in which the nitrogen content is higher than the oxygen content.

The insulating layer 125 can be formed by a sputtering method, a CVD method, a PLD method, an ALD method, or the like. The insulating layer 125 is preferably formed by an ALD method that provides good coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, any of the materials that can be used for the insulating layer 125 can be used. It is particularly preferable to use the same material for the layer 128 and the insulating layer 125, in which case an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked film of an inorganic insulating film and an organic insulating film can be used. For example, a structure in which an organic insulating film is sandwiched between a pair of inorganic insulating films is preferable. Furthermore, the organic insulating film preferably functions as a planarization film. In that case, the top surface of the organic insulating film can be flat, whereby the coverage thereof with the inorganic insulating film can be improved to achieve higher barrier properties. The top surface of the protective layer 121 is flat, which is preferable because the influence of an uneven shape due to a component below the protective layer 121 can be reduced in the case where a component (e.g., a color filter, an electrode of a touch sensor, or a lens array) is provided above the protective layer 121.

FIG. 30C illustrates the connection portion 130 in which the connection electrode 111C and the common electrode 113 are electrically connected to each other. In the connection portion 130, an opening portion is provided in the insulating layer 125 and the resin layer 126 over the connection electrode 111C. The connection electrode 111C and the common electrode 113 are electrically connected to each other in the opening portion.

Although FIG. 30C illustrates the connection portion 130 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin; thus, problems do not arise in many cases even when the common layer 114 is positioned in the connection portion 130. Accordingly, the common electrode 113 and the common layer 114 can be formed with the use of the same shielding mask, so that manufacturing cost can be reduced.

### Structure Example 2

A display device having a structure partly different from that in Structure example 1 described above will be described below. Note that the above description is referred to for portions common to those in Structure example 1, and the description is omitted in some cases.

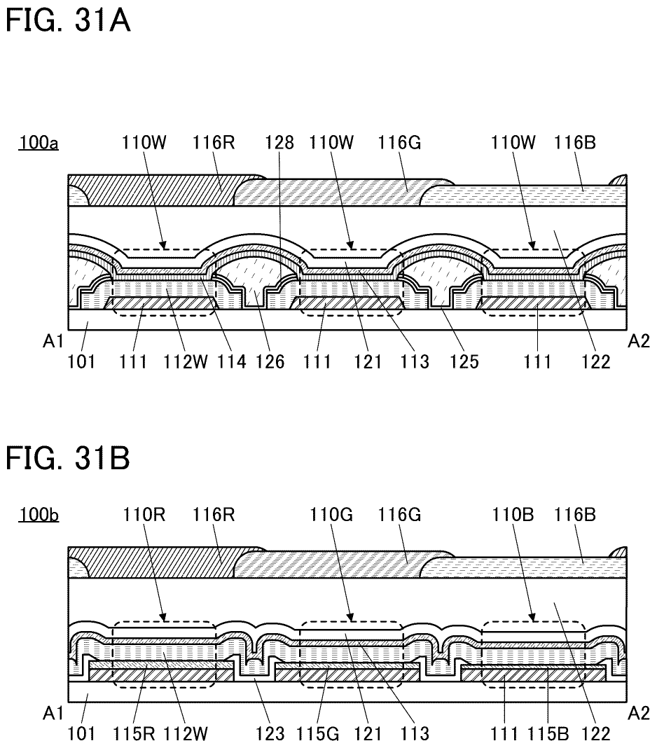

FIG. 31A is a schematic cross-sectional view of a display device 100a. The display device 100a is different from the above-described display device 100 mainly in the structure of the light-emitting element and including a coloring layer.

The display device 100a includes a light-emitting element 110W that emits white light. The light-emitting element 110W includes the pixel electrode 111, an organic layer 112W, the common layer 114, and the common electrode 113. The organic layer 112W emits white light. For example, the organic layer 112W can include two or more kinds of light-emitting materials whose emission colors are complementary colors. For example, the organic layer 112W can include a light-emitting organic compound that emits red light, a light-emitting organic compound that emits green light, and a light-emitting organic compound that emits blue light. Alternatively, the organic layer 112W may include a light-emitting organic compound that emits blue light and a light-emitting organic compound that emits yellow light.

The organic layer 112W is divided between two adjacent light-emitting elements 110W. Thus, leakage current flowing between the adjacent light-emitting elements 110W through the organic layer 112W can be inhibited and crosstalk due to the leakage current can be inhibited. Accordingly, the display device can have high contrast and high color reproducibility.

An insulating layer 122 functioning as a planarization film is provided over the protective layer 121, and a coloring layer 116R, a coloring layer 116G, and a coloring layer 116B are provided over the insulating layer 122.

An organic resin film or an inorganic insulating film with a flat top surface can be used as the insulating layer 122. The insulating layer 122 serves as a formation surface of the coloring layer 116R, the coloring layer 116G, and the coloring layer 116B; thus, with a flat top surface of the insulating layer 122, the thicknesses of the coloring layer 116R and the like can be uniform and color purity can be increased. Note that when the thicknesses of the coloring layer 116R and the like are not uniform, the amount of light absorption varies from place to place in the coloring layer 116R, which might decrease the color purity.

### Structure Example 3

FIG. 31B is a schematic cross-sectional view of a display device 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film that reflects visible light is used for the pixel electrode 111 and a film having properties of reflecting and transmitting visible light is used for the common electrode 113, so that a micro resonator (microcavity) structure can be achieved. At this time, by adjusting the thicknesses of the conductive layer 115R, the conductive layer 115G, and the conductive layer 115B to obtain optimal optical path lengths, light obtained from the light-emitting element 110R, the light-emitting element 110G, and the light-emitting element 110B can be intensified light with different wavelengths even in the case where the organic layer 112 exhibiting white light emission is used.

Furthermore, the coloring layer 116R, the coloring layer 116G, and the coloring layer 116B are provided on the optical paths of the light-emitting element 110R, the light-emitting element 110G, and the light-emitting element 110B, respectively, whereby light with high color purity can be obtained.

An insulating layer 123 that covers the end portions of the pixel electrode 111 and the conductive layer 115 is provided. The end portion of the insulating layer 123 preferably has a tapered shape. When the insulating layer 123 is provided, coverage with the organic layer 112W, the common electrode 113, the protective layer 121, and the like formed over the insulating layer 123 can be increased.

The organic layer 112W and the common electrode 113 are each provided as one continuous film shared by the light-emitting elements. Such a structure is preferable because the fabrication process of the display device can be greatly simplified.

Here, the end portion of the pixel electrode 111 preferably has a substantially vertical shape. Accordingly, a steep portion can be formed on the surface of the insulating layer 123, and thus a thin portion can be formed in part of the organic layer 112W that covers the steep portion or part of the organic layer 112W can be divided. Consequently, leakage current generated between adjacent light-emitting elements through the organic layer 112W can be inhibited without processing the organic layer 112W by a photolithography method or the like.

The above is the description of the structure examples of the display devices.

At least part of this embodiment can be implemented in combination with the other embodiments and examples described in this specification as appropriate.

### Embodiment 7

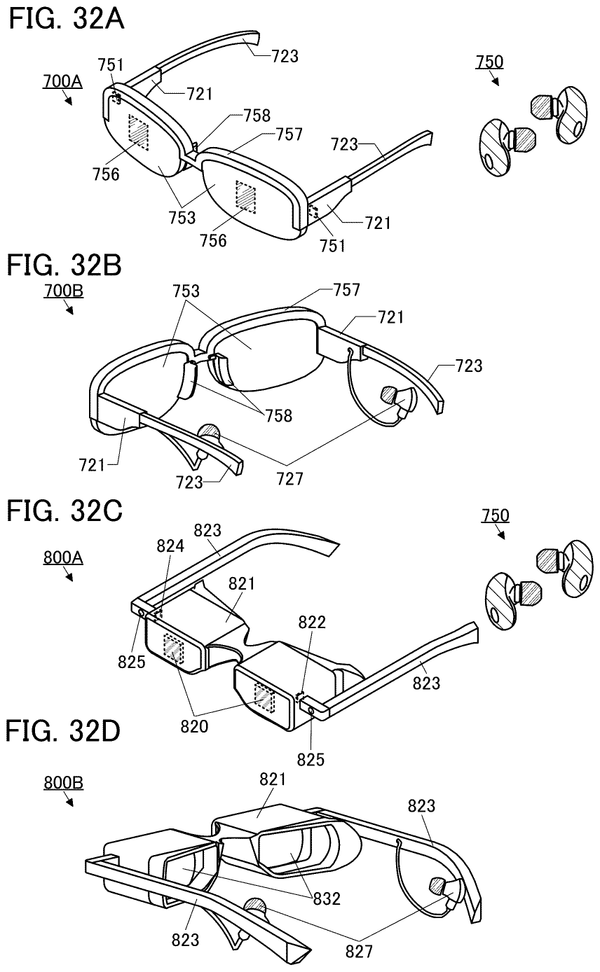

In this embodiment, electronic devices of one embodiment of the present invention will be described with reference to FIG. 32A to FIG. 34G.

Electronic devices in this embodiment each include a display panel (display device) employing the transistor of one embodiment of the present invention in a display portion. The display device of one embodiment of the present invention can easily achieve higher resolution and higher definition and can achieve high display quality. Thus, the display device of one embodiment of the present invention can be used for display portions of a variety of electronic devices.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display panel of one embodiment of the present invention can have higher resolution and thus can be suitably used for an electronic device having a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display panel of one embodiment of the present invention is preferably as high as HD (pixel count: 1280×720), FHD (pixel count: 1920×1080), WQHD (pixel count: 2560×1440), WQXGA (pixel count: 2560×1600), 4K (pixel count: 3840×2160), or 8K (pixel count: 7680×4320). In particular, a definition of 4K, 8K, or higher is preferable. In addition, the pixel density (resolution) of the display panel of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display panel having one or both of high definition and high resolution, realistic sensation, sense of depth, and the like can be further increased. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic device in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, electric power, radiation, a flow rate, humidity, a gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on a head will be described with reference to FIG. 32A to FIG. 32D. These wearable devices have one or both of a function of displaying AR contents and a function of displaying VR contents. Note that the wearable devices may have a function of displaying SR or MR contents, in addition to AR and VR contents. The electronic device having a function of displaying contents of at least one of AR, VR, SR, MR, and the like enables the user to reach a higher level of immersion.

An electronic device 700A illustrated in FIG. 32A and an electronic device 700B illustrated in FIG. 32B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be used as the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

In addition, each of the electronic device 700A and the electronic device 700B is provided with a battery so that charging can be performed wirelessly and/or by wire.

A touch sensor module may be provided in the housing 721. The touch sensor module has a function of detecting touch on the outer surface of the housing 721. A tap operation, a slide operation, or the like by the user can be detected with the touch sensor module, whereby a variety of processing can be executed. For example, processing such as a pause or a restart of a moving image can be executed by a tap operation, and processing such as fast forward or fast rewind can be executed by a slide operation. When the touch sensor module is provided in each of the two housings 721, the range of the operation can be increased.

Various touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 32C and an electronic device 800B illustrated in FIG. 32D each include a pair of display portions 820, a housing 821, a communication portion 822, a pair of wearing portions 823, a control portion 824, a pair of image capturing portions 825, and a pair of lenses 832.

The display panel of one embodiment of the present invention can be used for the display portions 820. Thus, the electronic device can perform display with extremely high resolution. This enables a user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 32C and the like illustrate examples in which the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided to cover a plurality of fields of view, such as a telescope field of view and a wide field of view.

Although an example in which the image capturing portion 825 is provided is illustrated here, a range sensor (hereinafter, also referred to as a sensing portion) capable of measuring a distance to an object just needs to be provided. That is, the image capturing portion 825 is one embodiment of the sensing portion. For the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy a video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 32A has a function of transmitting information to the earphones 750 with the wireless communication function. For another example, the electronic device 800A illustrated in FIG. 32C has a function of transmitting information to the earphones 750 with the wireless communication function.

The electronic device may include earphone portions. The electronic device 700B illustrated in FIG. 32B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic device 800B illustrated in FIG. 32D includes earphone portions 827. For example, a structure in which the earphone portions 827 and the control portion 824 are connected to each other by wire can be employed. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are suitable as the electronic device of one embodiment of the present invention.

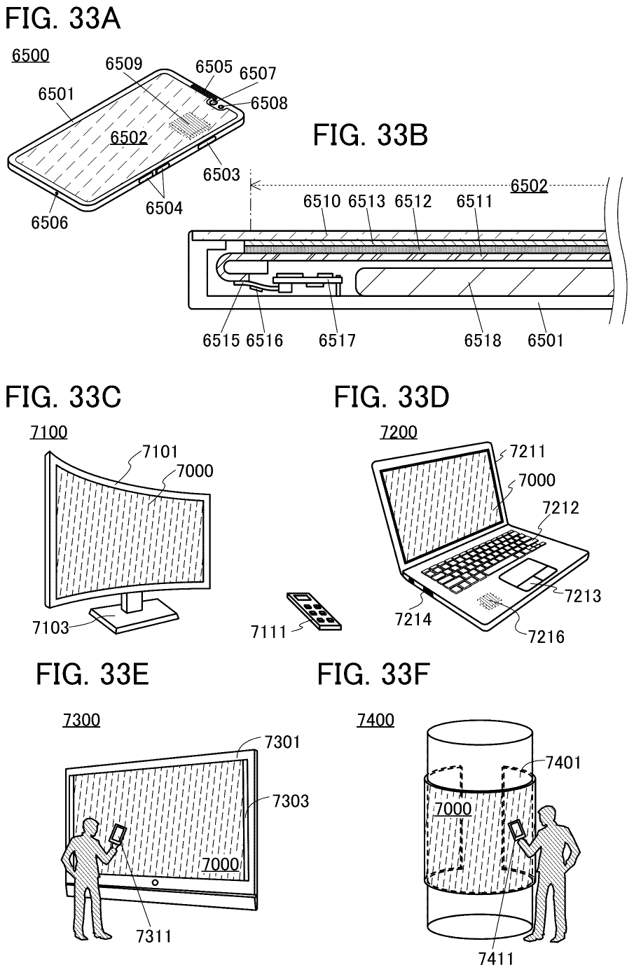

The electronic device 6500 illustrated in FIG. 33A is a portable information terminal that can be used as a smartphone.

The electronic device 6500 includes the housing 6501, the display portion 6502, the power button 6503, the buttons 6504, the speaker 6505, the microphone 6506, the camera 6507, the light source 6508, the control device 6509, and the like. The display portion 6502 has a touch panel function. Note that as the control device 6509, for example, one or more selected from a CPU, a GPU, and a memory device are included. The semiconductor device of one embodiment of the present invention can be used for the display portion 6502, the control device 6509, and the like. The semiconductor device of one embodiment of the present invention is preferably used for the control device 6509, in which case power consumption can be reduced.

The display panel of one embodiment of the present invention can be used for the display portion 6502.

FIG. 33B is a schematic cross-sectional view including the end portion of the housing 6501 on the microphone 6506 side.

A protection member 6510 having a light-transmitting property is provided on the display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used for the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back such that a connection portion with the FPC 6515 is provided on the back side of a pixel portion, whereby an electronic device with a narrow bezel can be achieved.

FIG. 33C illustrates an example of a television device. In a television device 7100, a display portion 7000 is incorporated in a housing 7101. Here, the housing 7101 is supported by a stand 7103.

Operation of the television device 7100 illustrated in FIG. 33C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 33D illustrates an example of a laptop personal computer. A laptop personal computer 7200 includes a housing 7211, a keyboard 7212, a pointing device 7213, an external connection port 7214, a control device 7216, and the like. In the housing 7211, the display portion 7000 is incorporated. As the control device 7216, for example, one or more selected from a CPU, a GPU, and a memory device are included. The semiconductor device of one embodiment of the present invention can be used for the display portion 7000, the control device 7216, and the like. The semiconductor device of one embodiment of the present invention is preferably used for the control device 7216, in which case power consumption can be reduced.

FIG. 33E and FIG. 33F illustrate examples of digital signage.

Digital signage 7300 illustrated in FIG. 33E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 33F illustrates digital signage 7400 attached to a cylindrical pillar 7401. The digital signage 7400 includes the display portion 7000 provided along a curved surface of the pillar 7401.

The larger display portion 7000 can provide a larger amount of information at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 33E and FIG. 33F, it is preferable that the digital signage 7300 or the digital signage 7400 be capable of working with an information terminal 7311 or an information terminal 7411, such as a smartphone a user has, through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is also possible to make the digital signage 7300 or the digital signage 7400 execute a game with the use of the screen of the information terminal 7311 or the information terminal 7411 as an operation means (a controller). Thus, an unspecified number of users can join in and enjoy the game concurrently.

The display panel of one embodiment of the present invention can be used for the display portion 7000 in each of FIG. 33C to FIG. 33F.

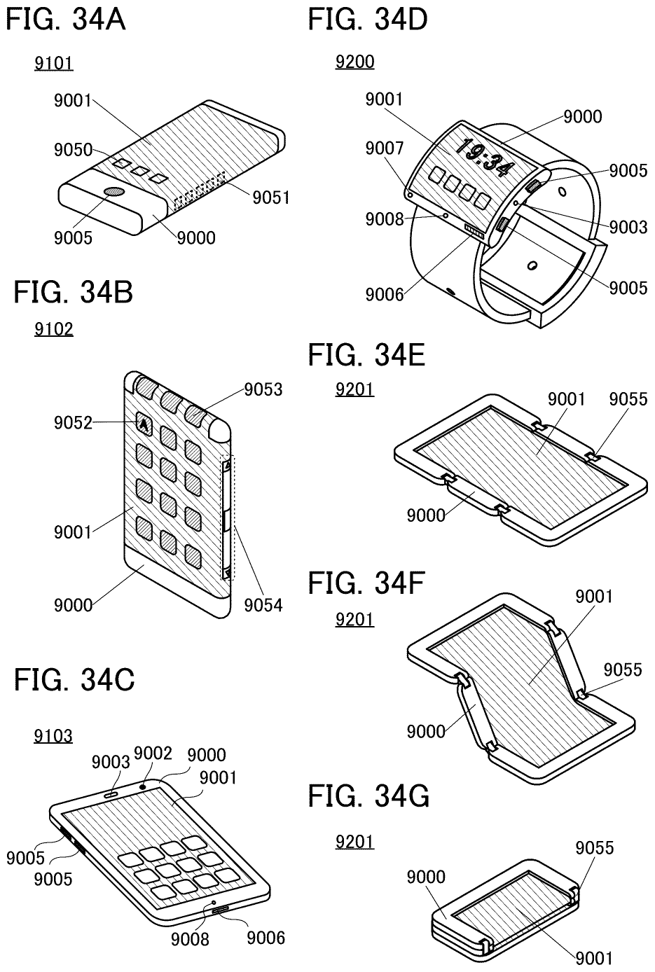

Electronic devices illustrated in FIG. 34A to FIG. 34G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, electric power, radiation, a flow rate, humidity, a gradient, oscillation, odor, or infrared rays), a microphone 9008, and the like.

The electronic devices illustrated in FIG. 34A to FIG. 34G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. In addition, the electronic devices may each be provided with a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 34A to FIG. 34G are described below.

FIG. 34A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display text and image information on its plurality of surfaces. FIG. 34A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 34B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 34C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface.

FIG. 34D is a perspective view illustrating a watch-type portable information terminal 9200. The portable information terminal 9200 can be used as a Smartwatch (registered trademark), for example. The display surface of the display portion 9001 is curved, and display can be performed on the curved display surface. Furthermore, mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 34E to FIG. 34G are perspective views illustrating a foldable portable information terminal 9201. FIG. 34E is a perspective view of an opened state of the portable information terminal 9201, FIG. 34G is a perspective view of a folded state thereof, and FIG. 34F is a perspective view of a state in the middle of change from one of FIG. 34E and FIG. 34G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of this embodiment can be implemented in combination with the other embodiments and examples described in this specification as appropriate.

### Example 1

In this example, the contact resistance between a wiring containing ruthenium and a wiring containing an oxide semiconductor was estimated. Specifically, a sample in which a wiring containing ruthenium and a wiring containing an oxide semiconductor were in contact with each other was fabricated, and the contact resistance was measured by a four-terminal method.

First, structures and fabrication methods of Sample 1A and Sample 1B in this example will be described.

Sample 1A and Sample 1B each included an element in which a first wiring with a width of 5 μm and a second wiring with a width of 5 μm over the first wiring were provided. The second wiring was provided to extend in the direction orthogonal to the first wiring. The top surface of the first wiring and the bottom surface of the second wiring were in contact with each other at an intersection portion, and the area of the intersection portion was 5 μm×5 μm=25μm². Note that 36 elements each including the first wiring and the second wiring were provided in each of Sample 1A and Sample 1B.

The first wiring of Sample 1A was a stacked-layer film (referred to as a W\ITSO film) of a tungsten film (referred to as a W film) and an indium tin oxide film to which silicon was added (referred to as an ITSO film) over the W film.

The W film was formed to have a thickness of 50 nm by a sputtering method using a tungsten target. The film formation conditions were as follows: an Ar gas at 10 sccm was used as a film formation gas, the pressure was 0.4 Pa, the film formation power was 1000 W with a DC power source, and the substrate temperature was 130 ° C.

The ITSO film was formed to have a thickness of 10 nm by a sputtering method using an indium tin oxide target containing SiO₂. Here, the indium tin oxide target containing SiO₂ contained 5 wt % SiO₂, 10 wt % SnO₂, and 85 wt % In₂O₃. The film formation conditions were as follows: an Ar gas at 50 sccm and an O₂ gas at 1.5 sccm were used as film formation gases, the pressure was 0.4 Pa, the film formation power was 1000 W with a DC power source, and the substrate temperature was room temperature.

The second wiring of Sample 1A was a stacked-layer film (referred to as an IGZO\W film) of an In—Ga—Zn oxide film (referred to as an IGZO film) and a W film over the IGZO film. The W film was formed under the same conditions as that in the first wiring.

The IGZO film was formed to have a thickness of 20 nm by a sputtering method using an oxide target with In:Ga:Zn=1:1:1.2 [atomic ratio]. The film formation conditions were as follows: an Ar gas at 10 sccm and an O₂ gas at 90 sccm were used as film formation gases, the pressure was 0.5 Pa, the film formation power was 2000 W with an RF power source, and the substrate temperature was 250 ° C.

The first wiring of Sample 1B was a stacked-layer film (referred to as a Ru\ITSO film) of a ruthenium film (referred to as a Ru film) and an ITSO film over the Ru film. The ITSO film was formed under the same conditions as that in the first wiring of Sample 1A.

The Ru film was formed to have a thickness of 20 nm by a sputtering method using a ruthenium target. The film formation conditions were as follows: an Ar gas at 50 sccm was used as a film formation gas, the pressure was 0.4 Pa, the film formation power was 500 W with a DC power source, and the substrate temperature was room temperature.

The second wiring of Sample 1B was formed under the same conditions as the second wiring of Sample 1A. Thus, in each of Sample 1A and Sample 1B, the ITSO film and the IGZO film were in contact with each other at the intersection portion of the first wiring and the second wiring.

Through the above steps, Sample 1A and Sample 1B were fabricated.

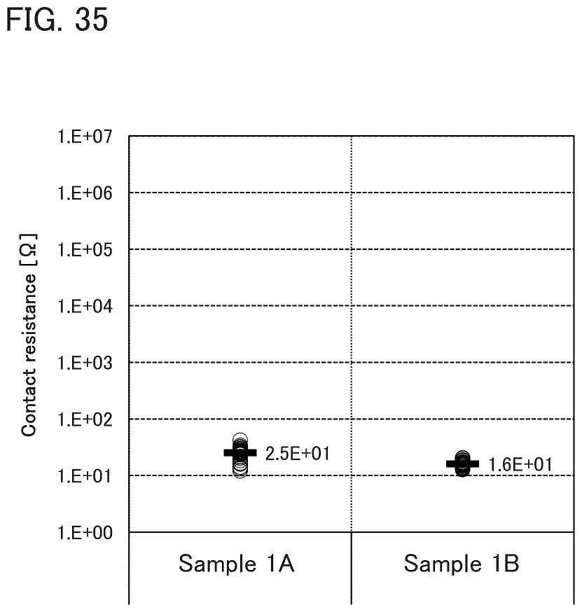

FIG. 35 shows the results of measuring the contact resistances of Sample 1A and Sample 1B by a four-terminal method. In FIG. 35, the vertical axis represents the contact resistance [Ω]. FIG. 35 shows the contact resistance values (indicated by white circles) of the 36 elements in each of Sample 1A and Sample 1B and the median contact resistance value (indicated by a line segment) of the 36 elements in each of Sample 1A and Sample 1B. In the measurement by a four-terminal method, the contact resistance values were calculated by applying a voltage of 0.01 V between one end portion of the first wiring and one end portion of the second wiring.

As shown in FIG. 35, the median contact resistance value of Sample 1A is 25Ω, and the median contact resistance value of Sample 1B is 16Ω. That is, the contact resistance of Sample 1B is lower than or equal to that of Sample 1A.

The above results demonstrate that selecting a metal oxide film such as an ITSO film as a wiring in contact with an IGZO film offers favorable contact resistance. It is also found that even when a ruthenium film is provided below the metal oxide film, the contact resistance is lower than or equal to that of the case where a tungsten film is provided.

### Example 2

In this example, the structure body having the opening in FIG. 4B was fabricated, and the results of cross-sectional SEM observation will be described.

In this example, Sample 2A in which a first conductive film, an interlayer film, a second conductive film, and an SOG film were stacked in this order over a silicon substrate where a silicon oxide film was formed was prepared, and an opening reaching the first conductive film of Sample 2A was formed. In addition, Sample 2B which had a structure similar to that of Sample 2A and in which a tungsten film (referred to as a W film) was further provided between the second conductive film and the SOG film was prepared, and an opening reaching the first conductive film of Sample 2B was formed. The diameter of the opening in each of Sample 2A and Sample 2B was 60 nm.

The first conductive film corresponds to the conductor 220 illustrated in FIG. 4B, the interlayer film corresponds to the insulator 280 illustrated therein, the second conductive film corresponds to the conductive film 240A and the conductive film 240B illustrated therein, the SOG film corresponds to the coating film 277 illustrated in FIG. 5A to FIG. 5D and FIG. 7A to FIG. 7D, and the W film corresponds to the inorganic film 276 illustrated in FIG. 7A to FIG. 7D.

Next, methods for fabricating Sample 2A and Sample 2B each including the above-described structure body will be described. Sample 2A was fabricated by the method in FIG. 5A to FIG. 5D, and Sample 2B was fabricated by the method in FIG. 7A to FIG. 7D. The fabrication method of Sample 2B was the same as the fabrication method of Sample 2A except for the step of forming the W film. The fabrication methods of Sample 2A and Sample 2B will be described below in parallel.

First, the silicon substrate where the silicon oxide film was formed was prepared, and the first conductive film was formed over the silicon substrate. The first conductive film was a stacked-layer film (referred to as a W\ITSO film) of a tungsten film (referred to as a W film) and an indium tin oxide film to which silicon was added (referred to as an ITSO film). The W film was formed to have a thickness of 20 nm by a sputtering method using a tungsten target. The ITSO film was formed to have a thickness of 10 nm by a sputtering method using an indium tin oxide target containing SiO₂. The indium tin oxide target containing SiO₂ contained 5 wt % SiO₂, 10 wt % SnO₂, and 85 wt % In₂O₃.

Next, the interlayer film was formed over the first conductive film. The interlayer film was a stacked-layer film of three layers of a silicon nitride film (referred to as a SiNx film), a silicon oxide film (referred to as a SiOx film), and a SiNx film, as in FIG. 10B. The SiNx film in the first layer was formed to have a thickness of 5 nm by a PEALD method. The SiOx film in the second layer was formed to have a thickness of 20 nm by a sputtering method using a silicon target. The SiNx film in the third layer was formed to have a thickness of 10 nm by a sputtering method using a silicon target.

Next, the second conductive film was formed over the interlayer film. The second conductive film was a stacked-layer film (referred to as a Ru\ITSO film) of a ruthenium film (referred to as a Ru film) and an indium tin oxide film to which silicon was added (referred to as an ITSO film). The Ru film was formed to have a thickness of 15 nm by a sputtering method using a ruthenium target. The ITSO film was formed to have a thickness of 10 nm under the same conditions as the above-described ITSO film.

Next, for Sample 2B, a W film was formed over the second conductive film. The W film was formed to have a thickness of 10 nm by a sputtering method using a tungsten target.

Next, an SOG film was formed over each of Sample 2A and Sample 2B by a spin coating method.

As in FIG. 5A and FIG. 7A, a positive resist film was formed over each of Sample 2A and Sample 2B fabricated in the above manner. The resist film was irradiated with an electron beam, so that an opening with a diameter of 60 nm was formed.

Next, dry etching treatment corresponding to FIG. 5B to FIG. 5D and FIG. 7B to FIG. 7D was performed using the resist mask having the opening.

First, the SOG film was etched as in FIG. 5B and FIG. 7B. The SOG film was etched with a DF-CCP etching apparatus. A CHF₃ gas at 67 sccm and an O₂ gas at 13 sccm were used as etching gases. The upper electrode was supplied with 550 W with a 60-MHz RF power source, and the lower electrode was supplied with 350 W with a 2-MHz RF power source. The other conditions were as follows: the distance between the electrodes was 40 mm, the pressure was 5.3 Pa, and the lower electrode temperature was 20 ° C.

Furthermore, in Sample 2B, the W film was etched as in FIG. 7B. The W film was etched with a DF-CCP etching apparatus. A Cl₂ gas at 11 sccm, an O₂ gas at 22 sccm, and a CF₄ gas at 22 sccm were used as etching gases. The upper electrode was supplied with 1000 W with a 60-MHz RF power source, and the lower electrode was supplied with 25 W with a 13.56-MHz RF power source. The other conditions were as follows: the distance between the electrodes was 80 mm, the pressure was 0.6 Pa, and the lower electrode temperature was 20 ° C.

Next, the ITSO film was etched as in FIG. 5C and FIG. 7C. The ITSO film was etched with a DF-CCP etching apparatus. A CH₄ gas at 18 sccm and an Ar gas at 42 sccm were used as etching gases. The upper electrode was supplied with 1000 W with a 60-MHz RF power source, and the lower electrode was supplied with 200 W with a 13.56-MHz RF power source. The other conditions were as follows: the distance between the electrodes was 120 mm, the pressure was 1.2 Pa, and the lower electrode temperature was 60 ° C.

Then, the Ru film was etched as in FIG. 5D and FIG. 7C. The Ru film was etched with an ICP etching apparatus. A Cl₂ gas at 25 sccm and an O₂ gas at 175 sccm were used as etching gases. The upper electrode (antenna coil) was supplied with 3000 W with a 13.56-MHz RF power source, and the lower electrode was supplied with 200 W with a 3.2-MHz RF power source. The other conditions were as follows: the distance between the electrodes was 200 mm, the pressure was 0.67 Pa, and the lower electrode temperature was 40 ° C.

Subsequently, the interlayer film was etched as in FIG. 4B and FIG. 7D. The interlayer film was etched with a DF-CCP etching apparatus. A CH₂F₂ gas at 16 sccm, an O₂ gas at 20 sccm, a CHF₃ gas at 30 sccm, a CF₄ gas at 30 sccm, and an Ar gas at 300 sccm were used as etching gases. The lower electrode was supplied with 300 W with a 40-MHz RF power source concurrently with 600 W with a 13-MHz RF power source. The other conditions were as follows: the distance between the electrodes was 40 mm, the pressure was 4.6 Pa, and the lower electrode temperature was 30 ° C.

Furthermore, in Sample 2B, the W film was etched to remove the W film functioning as a hard mask. The W film was etched with a DF-CCP etching apparatus. The etching conditions of the W film were the same as the above-described conditions.

Cross-sectional SEM images of Sample 2A and Sample 2B fabricated in the above manner were taken. The cross-sectional SEM images were taken at an acceleration voltage of 5 kV using “SU8030” manufactured by Hitachi High-Tech Corporation.

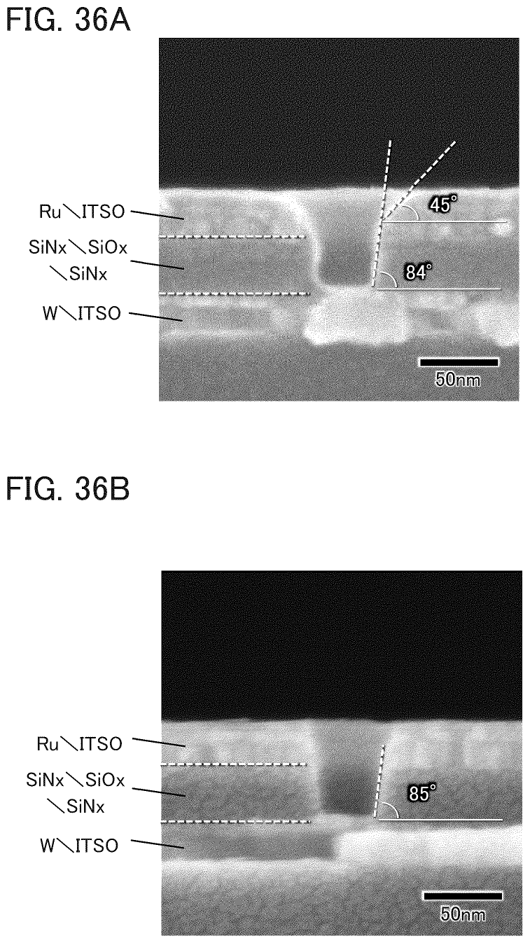

FIG. 36A and FIG. 36B show the cross-sectional SEM images of Sample 2A and Sample 2B. The taper angle of the opening sidewall of the interlayer film is 84° in Sample 2A, and the taper angle of the opening sidewall of the interlayer film is 85° in Sample 2B. The taper angle of the side surface of the ITSO film in the second conductive film is 45° in Sample 2A, which is similar to the shape of the structure illustrated in FIG. 6A. In Sample 2B, the taper angle of the side surface of the ITSO film in the second conductive film is substantially equal to the taper angle of the opening sidewall of the interlayer film.

As described above, the opening whose sidewall was substantially vertical was able to be formed in the interlayer film in each of Sample 2A and Sample 2B. This is because the Ru film and the W film over the interlayer film function as hard masks in the dry etching treatment of the interlayer film. Furthermore, in Sample 2B, the side surface of the ITSO film in the second conductive film was also able to be substantially vertical. This is because the W film over the second conductive film functions as a hard mask in the dry etching treatment of the second conductive film. These results reveal that a metal film functioning as a hard mask is preferably provided in a conductive layer functioning as a source electrode or a drain electrode over an interlayer film as described in the above embodiment.

This example can be combined with the embodiments and the other examples as appropriate.

### Example 3

In this example, an oxide semiconductor film formed over a metal oxide film was observed with STEM (Scanning Transmission Electron Microscopy).

First, fabrication methods of Sample 3A and Sample 3B in this example will be described.

Sample 3A and Sample 3B each had a structure in which a metal oxide film and an oxide semiconductor film over the metal oxide film were formed over a silicon substrate where a thermal oxide film was formed. For Sample 3A, an indium tin oxide film to which silicon was added (referred to as an ITSO film) was formed as the metal oxide film. For Sample 3B, an indium tin oxide film (referred to as an ITO film) was formed as the metal oxide film. For each of Sample 3A and Sample 3B, an In—Ga—Zn oxide film (referred to as an IGZO film) was formed as the oxide semiconductor film.

The ITSO film was formed to have a thickness of 10 nm by a sputtering method using an indium tin oxide target containing SiO₂. Here, the indium tin oxide target containing SiO₂ contained 5 wt % SiO₂, 10 wt % SnO₂, and 85 wt % In₂O₃. The film formation conditions were as follows: an Ar gas at 50 sccm and an O₂ gas at 1.5 sccm were used as film formation gases, the pressure was 0.4 Pa, the film formation power was 1000 W with a DC power source, and the substrate temperature was room temperature.

The ITO film was formed to have a thickness of 10 nm by a sputtering method using an indium tin oxide target. Here, the indium tin oxide target contained 10 wt % SnO 2 and 90 wt % In₂O₃. The film formation conditions were as follows: an Ar gas at 50 sccm and an O₂ gas at 1 sccm were used as film formation gases, the pressure was 0.7 Pa, the film formation power was 500 W with a DC power source, and the substrate temperature was room temperature.

The IGZO film was formed to have a thickness of 10 nm by a sputtering method using an oxide target with In:Ga:Zn=1:1:1.2 [atomic ratio]. The film formation conditions were as follows: an Ar gas at 10 sccm and an O₂ gas at 90 sccm were used as film formation gases, the pressure was 0.5 Pa, the film formation power was 2000 W with an RF power source, and the substrate temperature was 250 ° C.

Through the above steps, Sample 3A and Sample 3B were fabricated.

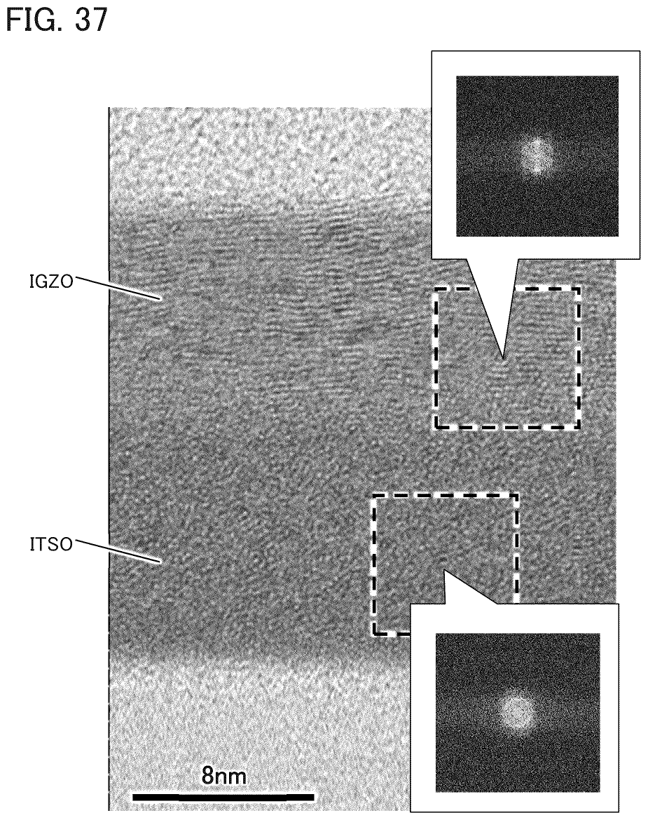

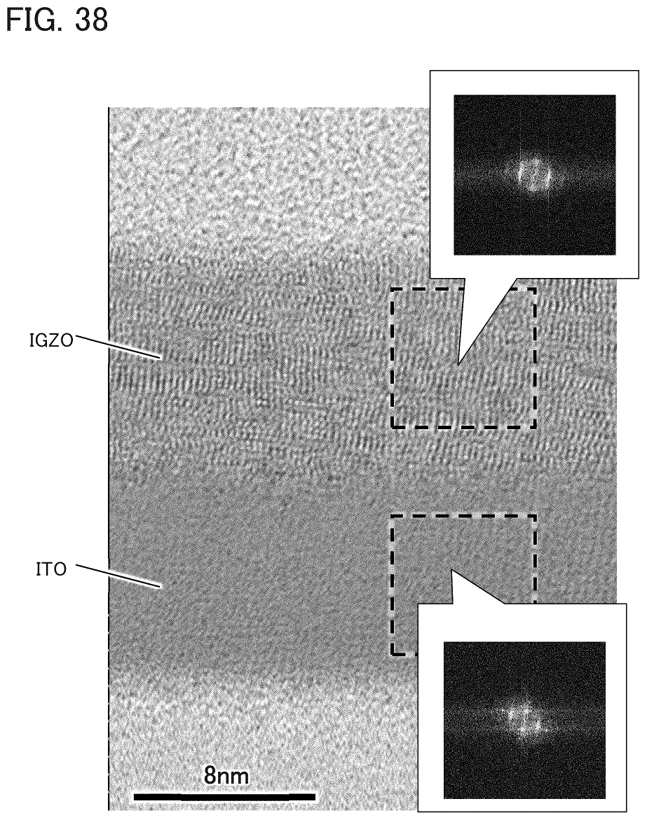

Cross-sectional STEM images of Sample 3A and Sample 3B fabricated above were taken with “HD-2700” manufactured by Hitachi High-Tech Corporation at an acceleration voltage of 200 kV. FIG. 37 shows the cross-sectional STEM image of Sample 3A, and FIG. 38 shows the cross-sectional STEM image of Sample 3B.

It is confirmed from the cross-sectional STEM images in FIG. 37 and FIG. 38 that the IGZO film in each of Sample 3A and Sample 3B has a crystal structure. The IGZO film over the ITSO film in Sample 3A includes a large number of layered crystal regions parallel to the formation surface. By contrast, a large number of crystal grains extending in the direction perpendicular to the formation surface are observed in the IGZO film over the ITO film in Sample 3B.

FIG. 37 and FIG. 38 also show FFT (Fast Fourier Transform) images of the ITSO film, the ITO film, and the IGZO films of the samples. The FFT images are obtained by performing FFT analysis on the cross-sectional STEM images in FIG. 37 and FIG. 38 and have patterns reflecting reciprocal lattice space information like an electron diffraction pattern.

It is confirmed from the FFT images in FIG. 37 that the IGZO film of Sample 3A has two spots. In the case of a cross-sectional TEM image of a CAAC-OS taken from the direction perpendicular to the c-axis, two spots having high intensity are observed in an FFT image in some cases. The angle of a line segment connecting these two spots represents crystal alignment of the CAAC-OS. Thus, the IGZO film of Sample 3A probably becomes a CAAC-OS. By contrast, no clear spot is observed in the ITSO film. Hence, the ITSO film is probably amorphous.

Here, XPS measurement was performed on a sample having a stacked-layer structure similar to that of Sample 3A, so that the band offset AEc was as small as 0.04 eV. The band offset AEc is a difference between the energy of the conduction band minimum of the ITSO film and the energy of the conduction band minimum of the IGZO film. In the XPS measurement, the energy of the conduction band minimum of the IGZO film was higher than that of the ITSO film. The band offset AEc was calculated by measuring the energy of the valence band maximum of the ITSO film and the energy of the valence band maximum of the IGZO film by the XPS measurement. As described here, the band offset between the ITSO film and the IGZO film was extremely small. Thus, it can be considered that an ohmic contact is almost made between the ITSO film and the IGZO film. That is, it can be considered that an ohmic contact is almost made between the ITSO film having an amorphous structure and the IGZO film having a CAAC-OS structure in Sample 3A.

It is confirmed from the FFT images in FIG. 38 that the ITO film and the IGZO film of Sample 3B each have a plurality of spots. Thus, it can be considered that the ITO film and the IGZO film of Sample 3B are each polycrystallized.

As described above, an oxide semiconductor film formed over a metal oxide film can have crystallinity. Thus, as described in the above embodiment, when metal oxide films are provided as upper layers of a source electrode and a drain electrode, an oxide semiconductor film in contact with the upper layers of the source electrode and the drain electrode can have crystallinity.

When an oxide semiconductor film is formed over a metal oxide film having an amorphous structure, a CAAC-OS film with few crystal grain boundaries can be formed. Thus, as described in the above embodiment, when metal oxide films having an amorphous structure, such as an ITSO film, are provided as upper layers of a source electrode and a drain electrode, an oxide semiconductor film in contact with the upper layers of the source electrode and the drain electrode can be a CAAC-OS film. The oxide semiconductor film has an ohmic contact with the source electrode and the drain electrode at this time, so that a transistor having excellent electrical characteristics can be provided.

This example can be combined with the embodiments and the other examples as appropriate.

### Example 4

In this example, the structure body in which the sidewall-shaped insulator was provided in the opening portion in FIG. 14B was fabricated, and the results of cross-sectional STEM observation will be described.

In this example, Sample 4A in which a first conductive film, an interlayer film, a second conductive film, an SOC film, and an SOG film were stacked in this order over a silicon substrate where a silicon oxide film was formed was prepared, an opening portion reaching the first conductive film of Sample 4A was formed, and a sidewall-shaped insulator was further formed. The diameter of the opening portion in Sample 4A was 60 nm.

The first conductive film corresponds to the conductor 220 illustrated in FIG. 14B, the interlayer film corresponds to the insulator 280 illustrated therein, the second conductive film corresponds to the conductive film 240A and the conductive film 240B illustrated therein, and the SOC film and the SOG film correspond to the coating film 277 illustrated in FIG. 5A to FIG. 5D.

Next, a method for fabricating Sample 4A including the above-described structure body will be described. Sample 4A was fabricated by the methods in FIG. 5A to FIG. 5D and FIG. 14A and FIG. 14B.

First, the silicon substrate where the silicon oxide film was formed was prepared, and the first conductive film was formed over the silicon substrate. The first conductive film was a stacked-layer film (referred to as a W\TSO film) of a tungsten film (referred to as a W film) and an indium tin oxide film to which silicon was added (referred to as an ITSO film). The W film was formed to have a thickness of 20 nm by a sputtering method using a tungsten target. The ITSO film was formed to have a thickness of 20 nm by a sputtering method using an indium tin oxide target containing SiO₂. The indium tin oxide target containing SiO₂ contained 5 wt % SiO₂, 10 wt % SnO₂, and 85 wt % In₂O₃.

Next, the interlayer film was formed over the first conductive film. The interlayer film was a stacked-layer film of three layers of a silicon nitride film (referred to as a SiNx film), a silicon oxide film (referred to as a SiOx film), and a SiNx film, as in FIG. 14A. The SiNx film in the first layer was formed to have a thickness of 5 nm by a PEALD method. The SiOx film in the second layer was formed to have a thickness of 20 nm by a sputtering method using a silicon target. The SiNx film in the third layer was formed to have a thickness of 10 nm by a sputtering method using a silicon target.

Next, the second conductive film was formed over the interlayer film. The second conductive film was a stacked-layer film (referred to as a W\ITSO film) of a W film and an ITSO film. The W film was formed to have a thickness of 15 nm, and the ITSO film was formed to have a thickness of 10 nm. The W\ITSO film was formed under the same conditions as the W\ITSO film of the first conductive film.

Next, an SOC film was formed over Sample 4A by a spin coating method, and an SOG film was formed thereover.

As in FIG. 5A, a positive resist film was formed over Sample 4A fabricated in the above manner. The resist film was irradiated with an electron beam and the portion irradiated with the electron beam was removed using a developing solution, so that an opening portion with a diameter of 60 nm was formed in the resist film.

Next, dry etching treatment corresponding to FIG. 5B to FIG. 5D was performed using the resist mask having the opening portion.

First, the SOG film and the SOC film were etched as in FIG. 5B. The SOG film and the SOC film were etched with a DF-CCP etching apparatus.

In the etching of the SOG film, a CHF₃ gas at 67 sccm and an O₂ gas at 13 sccm were used as etching gases. The upper electrode was supplied with 550 W with a 60-MHz RF power source, and the lower electrode was supplied with 350 W with a 2-MHz RF power source. The other conditions were as follows: the distance between the electrodes was 40 mm, the pressure was 5.3 Pa, and the lower electrode temperature was 20 ° C.

In the etching of the SOC film, an H₃ gas at 500 sccm and an N₂ gas at 150 sccm were used as etching gases. The upper electrode was supplied with 1000 W with a 60-MHz RF power source, and the lower electrode was supplied with 200 W with a 2-MHz RF power source. The other conditions were as follows: the distance between the electrodes was 25 mm, the pressure was 6.6 Pa, and the lower electrode temperature was 20 ° C.

Next, the ITSO film was etched as in FIG. 5C. The ITSO film was etched with a DF-CCP etching apparatus. A CH₄ gas at 18 sccm and an Ar gas at 42 sccm were used as etching gases. The upper electrode was supplied with 1000 W with a 60-MHz RF power source, and the lower electrode was supplied with 600 W with a 13.56-MHz RF power source. The other conditions were as follows: the distance between the electrodes was 120 mm, the pressure was 1.2 Pa, and the lower electrode temperature was 60 ° C.

In order to remove a reaction product formed by the etching of the ITSO film, wet cleaning was performed using diluted hydrofluoric acid.

Next, the W film was etched as in FIG. 5D. The W film was etched with a DF-CCP etching apparatus. A Cl₂ gas at 11 sccm, an O₂ gas at 22 sccm, and a CF₄ gas at 22 sccm were used as etching gases. The upper electrode was supplied with 1000 W with a 60-MHz RF power source, and the lower electrode was supplied with 25 W with a 13.56-MHz RF power source. The other conditions were as follows: the distance between the electrodes was 80 mm, the pressure was 1.3 Pa, and the lower electrode temperature was 20 ° C.

Subsequently, the interlayer film was etched. The interlayer film was etched with a DF-CCP etching apparatus. A CH₂F₂ gas at 16 sccm, an O₂ gas at 20 sccm, a CHF₃ gas at 30 sccm, a CF₄ gas at 30 sccm, and an Ar gas at 300 sccm were used as etching gases. The lower electrode was supplied with 300 W with a 40-MHz RF power source concurrently with 600 W with a 13-MHz RF power source. The other conditions were as follows: the distance between the electrodes was 40 mm, the pressure was 4.6 Pa, and the lower electrode temperature was 30 ° C.

After the opening portion was formed in the above manner, wet cleaning was performed using diluted hydrofluoric acid.

Next, as in FIG. 14A, an insulating film to be a sidewall-shaped insulator in a later step was formed. The insulating film was a 5-nm-thick SiNx film formed by a PEALD method.

Then, the SiNx film was subjected to anisotropic etching as in FIG. 14B. The SiNx film was etched with a DF-CCP etching apparatus. A CH₂F₂ gas at 25 sccm, an O₂ gas at 5 sccm, and an Ar gas at 600 sccm were used as etching gases. The lower electrode was supplied with 100 W with a 40-MHz RF power source concurrently with 50 W with a 13-MHz RF power source. The other conditions were as follows: the distance between the electrodes was 40 mm, the pressure was 6.6 Pa, and the lower electrode temperature was 30 ° C.

In the above manner, Sample 4A having the opening portion and the sidewall-shaped insulator was fabricated.

A cross-sectional STEM image of Sample 4A fabricated in the above manner was taken. The cross-sectional STEM image was taken at an acceleration voltage of 200 k V using “HD-2700” manufactured by Hitachi High-Tech Corporation.

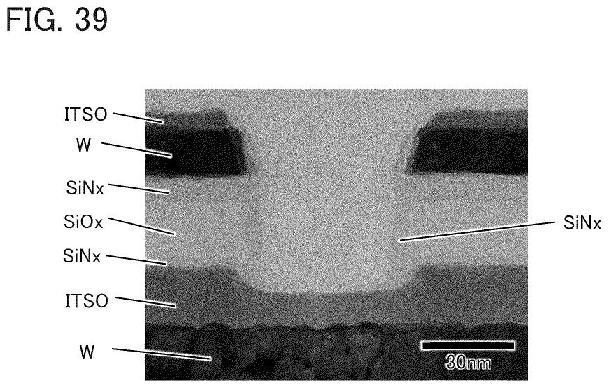

FIG. 39 shows the cross-sectional STEM image of Sample 4A. It can be confirmed from FIG. 39 that the SiNx film is formed in contact with the sidewall of the opening portion. It can also be confirmed that the SiNx film is not formed in the vicinity of the center portion of the bottom surface of the opening portion or on the top surface of the ITSO film in the second conductive film. The SiNx film is formed in contact with the ITSO film and the W film in the second conductive film. In particular, the side surface of the W film in the second conductive film is covered with the SiNx film up to its upper end portion. A depressed portion is formed in the ITSO film in the second conductive film to overlap with the opening portion, and part of the sidewall-shaped SiNx film is formed in the depressed portion.

As described above, the opening and the sidewall-shaped insulator in contact with the sidewall of the opening were able to be formed in Sample 4A. When a sidewall-shaped insulator is provided in contact with the side surface of an upper electrode functioning as a source or a drain in a vertical transistor, the side surface of the electrode can be prevented from being in contact with an oxide semiconductor and from being oxidized. This can inhibit a reduction in conductivity of the upper electrode functioning as the source or the drain, enabling the transistor to have a high on-state current, high field-effect mobility, a favorable S value, excellent frequency characteristics, and the like.

### REFERENCE NUMERALS

100a: display device, 100b: display device, 100: display device, 101: substrate, 110B: light-emitting element, 110G: light-emitting element, 110R: light-emitting element, 110W: light-emitting element, 110: light-emitting element, 111B: pixel electrode, 111C: connection electrode, 111G: pixel electrode, 111R: pixel electrode, 111: pixel electrode, 112B: organic layer, 112G: organic layer, 112R: organic layer, 112W: organic layer, 112: organic layer, 113: common electrode, 114: common layer, 115B: conductive layer, 115G: conductive layer, 115R: conductive layer, 115: conductive layer, 116B: coloring layer, 116G: coloring layer, 116R: coloring layer, 121: protective layer, 122: insulating layer, 123: insulating layer, 125: insulating layer, 126: resin layer, 128: layer, 130: connection portion, 140: capacitor, 141: conductive layer, 143: insulating layer, 145: conductive layer, 154: insulating layer, 155a: insulating layer, 155b: insulating layer, 155c: insulating layer, 156: plug, 164: insulating layer, 170: substrate, 171: adhesive layer, 174a: conductive layer, 174b: conductive layer, 174: plug, 200E: transistor, 200: transistor, 201: substrate, 210: insulator, 220a: conductor, 220b: conductor, 220: conductor, 221: insulator, 222: insulator, 223: insulator, 230a: oxide semiconductor, 230b: oxide semiconductor, 230c: oxide semiconductor, 230: oxide semiconductor, 231: crystal part, 240a: conductor, 240A: conductive film, 240b: conductor, 240B: conductive film, 240: conductor, 242a: conductor, 242b: conductor, 242: conductor, 243a: conductor, 243b: conductor, 243: conductor, 250a: insulator, 250b: insulator, 250: insulator, 260a: conductor, 260b: conductor, 260: conductor, 276: inorganic film, 277: coating film, 279: resist mask, 280a: insulator, 280b: insulator, 280c: insulator, 280: insulator, 283a: insulator, 283b: insulator, 283: insulator, 290A: opening portion, 290B: opening portion, 290: opening portion, 310: transistor, 311: substrate, 314: low-resistance region, 315: insulator, 316: conductor, 317: insulator, 318: element isolation layer, 500A: display device, 500C: display device, 520: transistor, 580: display module, 581: display portion, 582: circuit portion, 583a: pixel circuit, 583: pixel circuit portion, 584a: pixel, 584: pixel portion, 585: terminal portion, 586: wiring portion, 590: FPC, 591: substrate, 592: substrate, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 900: semiconductor device, 910: driver circuit, 911: peripheral circuit, 912: control circuit, 915: peripheral circuit, 920: memory array, 923: row driver, 924: column driver, 925: input circuit, 926: output circuit, 927: sense amplifier, 928: voltage generator, 930: layer, 931: PSW, 932: PSW, 941: row decoder, 942: column decoder, 950: memory cell, 951: memory cell, 952: memory cell, 953: memory cell, 954: memory cell, 955: memory cell, 956: memory cell, 957: memory cell, 958: memory cell, 960: arithmetic device, 970A: semiconductor device, 970B: semiconductor device, 970C: semiconductor device, 989: cache interface, 990: substrate, 991: ALU, 992: ALU controller, 993: instruction decoder, 994: interrupt controller, 995: timing controller, 996: register, 997: register controller, 998: bus interface, 999: cache, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6510: protection member, 6511: display panel, 6512: optical member, 6513: touch sensor panel, 6515: FPC, 6516: IC, 6517: printed circuit board, 6518: battery, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 6900: storage system, 6901sb: server, 6901: host, 6902: storage control circuit, 6903md: memory device, 6903: storage, 7000: display portion, 7100: television device, 7101: housing, 7103: stand, 7111: remote controller, 7200: laptop personal computer, 7211: housing, 7212: keyboard, 7213: pointing device, 7214: external connection port, 7216: control device, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a transistor, a first insulator, a second insulator, and a third insulator,
wherein the second insulator is over the first insulator,
wherein the third insulator is over the second insulator,
wherein the transistor comprises a first conductor over the second insulator, a second conductor over the third insulator, an oxide semiconductor, a fourth insulator, and a third conductor,
wherein an opening portion reaching the first conductor is provided in the third insulator and the second conductor,
wherein the oxide semiconductor is in contact with a top surface of the first conductor and a top surface and a side surface of the second conductor,
wherein the fourth insulator is over the oxide semiconductor at least partly in the opening portion,
wherein the third conductor is over the fourth insulator at least partly the opening portion,
wherein the second conductor comprises a first layer and a second layer over the first layer,
wherein the first layer has higher conductivity than the second layer, and
wherein the second layer comprises a metal oxide.

2. The semiconductor device according to claim 1,
wherein the first layer comprises ruthenium or tungsten.

3. The semiconductor device according to claim 2,
wherein the second layer comprises indium.

4. The semiconductor device according to claim 3,
wherein the second layer comprises tin and silicon, and
wherein the second layer has an amorphous structure.

5. The semiconductor device according to claim 1,
wherein the first insulator and the third insulator each have a barrier property against hydrogen.

6. The semiconductor device according to claim 5,
wherein the second insulator comprises hafnium, silicon, and oxygen.

7. The semiconductor device according to claim 6,
wherein the first insulator and the third insulator each comprise silicon and nitrogen.

8. The semiconductor device according to claim 5,
wherein the first conductor comprises a third layer and a fourth layer over the third layer,
wherein the third layer has higher conductivity than the fourth layer, and
wherein the fourth layer comprises a metal oxide.

9. The semiconductor device according to claim 8,
wherein the third layer comprises tungsten.

10. The semiconductor device according to claim 9,
wherein the fourth layer comprises indium.

11. The semiconductor device according to claim 10,
wherein the fourth layer comprises tin and silicon, and
wherein the fourth layer has an amorphous structure.

12. A semiconductor device comprising:
a transistor, a first insulator, and a second insulator,
wherein the transistor comprises a first conductor, a second conductor over the first conductor and the first insulator, an oxide semiconductor, a third insulator, and a third conductor,
wherein an opening portion reaching the first conductor is provided in the third insulator and the second conductor,
wherein the oxide semiconductor is in contact with a top surface of the first conductor and a top surface of the second conductor,
wherein the third insulator is over the oxide semiconductor at least partly in the opening portion,
wherein the third conductor is over the third insulator at least partly in the opening portion,
wherein the second insulator is between the oxide semiconductor and each of the first insulator and the second conductor in the opening portion,
wherein the second conductor comprises a first layer and a second layer over the first layer,
wherein the first layer has higher conductivity than the second layer,
wherein the second layer comprises a metal oxide, and
wherein one side surface of the second insulator is in contact with at least a side surface of the first layer.

13. The semiconductor device according to claim 12,
wherein the first layer comprises ruthenium or tungsten.

14. The semiconductor device according to claim 12,
wherein the second layer comprises indium.

15. The semiconductor device according to claim 14,
wherein the second layer comprises tin and silicon, and
wherein the second layer has an amorphous structure.

16. The semiconductor device according to claim 12,
wherein a level of an upper end portion of the second insulator is lower than a level of a top surface of the second layer.

17. The semiconductor device according to claim 12,
wherein the one side surface of the second insulator is in contact with the first insulator, and
wherein the other side surface of the second insulator is in contact with the oxide semiconductor.

18. The semiconductor device according to claim 12,
wherein the second insulator comprises silicon and nitrogen.

19. The semiconductor device according to claim 1, wherein the second insulator is configured to capture or fix hydrogen.
